(19) United States
(12) Patent Application Publication
(10) Pub. No.: US 2025/0194361 A1
(43) Pub. Date: Jun. 12, 2025

(54) WIRING BOARD, MODULE, AND IMAGE DISPLAY DEVICE

(71) Applicant: DAI NIPPON PRINTING CO., LTD., Tokyo-to (JP)

(72) Inventors: Seiji TAKE, Tokyo-to (JP); Keita IIMURA, Tokyo-to (JP); Mitsumasa KOIWA, Tokyo-to (JP); Hiroshi YAMAMOTO, Tokyo-to (JP); Hidetoshi IIOKA, Tokyo-to (JP); Koichi NAKANO, Tokyo-to (JP); Yuya MARUYAMA, Tokyo-to (JP); Kenta KOBAYASHI, Tokyo-to (JP); Eriko KAI, Tokyo-to (JP); Kanari AONO, Tokyo-to (JP)

(73) Assignee: DAI NIPPON PRINTING CO., LTD., Tokyo-to (JP)

(21) Appl. No.: 18/856,192

(22) PCT Filed: Apr. 10, 2023
(86) PCT No.: PCT/JP2023/014524

§ 371 Date: Oct. 11, 2024

(30) Foreign Application Priority Data
Apr. 13, 2022 (JP) 2022-066480
Jun. 10, 2022 (JP) 2022-094724

(51) Int. Cl. H10K 59/131; H10H 29/49

(52) U.S. Cl. CPC H10K 59/131; H10H 29/49

(57) ABSTRACT

A wiring board includes a substrate that includes a first face, and a second face situated on an opposite side from the first face, a plurality of mesh wiring portions that are disposed on the first face of substrate, and that are distanced from each other, and power supply units that are electrically connected to the mesh wiring portions. The wiring board has an electromagnetic wave transmission/reception function. The substrate has transparency. The mesh wiring portions are configured as antennas. A plurality of first notch portions that extend linearly are formed in the power supply units.

### TECHNICAL FIELD

An embodiment according to the present disclosure relates to a wiring board, a module, and an image display device.

### BACKGROUND ART

Increased performance, reduction in size, reduction in thickness, and reduction in weight are currently advancing for mobile terminal equipment, such as smartphones, tablets, smart glasses (AR, MR, etc.) and so forth. Such mobile terminal equipment uses a plurality of communication bands, and accordingly, a plurality of antennas are required in accordance with the communication bands. For example, mobile terminal equipment is equipped with a plurality of antennas, such as an antenna for telephone, an antenna for WiFi (Wireless Fidelity), an antenna for 3G (Generation), an antenna for 4G (Generation), an antenna for 5G (Generation), an antenna for LTE (Long Term Evolution), an antenna for Bluetooth (registered trademark), an antenna for NFC (Near Field Communication), and so forth. However, due to reduction in size of mobile terminal equipment, space for installing antennas is limited, and degree in freedom for antenna design is becoming narrower. Also, antennas are built into limited space, and accordingly radio wave sensitivity is not necessarily satisfactory.

Accordingly, film antennas that can be installed in display regions of mobile terminal equipment have been developed. Such film antennas have an antenna pattern formed on a transparent base material. The antenna pattern is formed of a mesh-like conductor mesh layer made up of a conductor portion serving as a formation portion of a non-transparent conductor layer, and a great number of openings serving as a non-formation portion.

### CITATION LIST

### Patent Literature

Patent Literature 1: Japanese Unexamined Patent Application Publication No. 2011-66610
Patent Literature 2: International Publication No. 2019/163087

Now, in film antennas, power supply lines are connected to a power supply unit for electrically connecting the conductor mesh layer to external equipment. In this case, there is demand for improved connectivity of the power supply unit and the power supply lines.

Also, depending on a relation between a peripheral shape of the conductor mesh layer and a pitch of wiring, wiring situated on a perimeter of the conductor mesh layer may conceivably be severed partway along. In this case, there is concern that electrical characteristics of the antenna, for example, may deteriorate on the perimeter of the conductor mesh layer. Conversely, wiring serving as a boundary line can conceivably be provided on the perimeter of the conductor mesh layer (e.g., see Patent Literature 2). In this case, the electrical characteristics of the antenna, for example, are maintained, but there is concern that the wiring situated on the perimeter of the conductor mesh layer may become conspicuous, and be readily visually recognized.

It is an object of the present embodiment to provide a wiring board, a module, and an image display device, in which connectability between a power supply line and a power supply unit can be improved.

The present embodiment provides a wiring board and an image display device, in which presence of wiring situated at a perimeter of a mesh wiring portion can be made to be less visually recognizable, while suppressing deterioration in electrical characteristics of the mesh wiring portion.

### SUMMARY OF INVENTION

An embodiment according to the present disclosure relate to the following [1] to [32].

[1] A wiring board includes a substrate that includes a first face, and a second face situated on an opposite side from the first face two or more mesh wiring portions that are disposed on the first face of the substrate, and that are distanced from each other, and two or more power supply units that are electrically connected to the mesh wiring portions. The wiring board has an electromagnetic wave transmission/reception function, the substrate has transparency, the mesh wiring portions are configured as antennas, each of the mesh wiring portions and each of the power supply units are individually connected, and two or more first notch portions that extend linearly are formed in the power supply units.

[2] With the wiring board according to [1], the wiring board has a millimeter wave transmission/reception function, and the mesh wiring portions are configured as array antennas.

[3] With the wiring board according to [1] or [2], the power supply units have a first end portion that connects to the mesh wiring portions, and a second end portion on an opposite side from the first end portion, and the first notch portions extend from the second end portion along a direction from the second end portion toward the first end portion.

[4] The wiring board according to any one of [1] to [3] further includes a ground portion that is disposed on the first face of the substrate. Two or more second notch portions that extend linearly are formed in the ground portion.

[5] With the wiring board according to any one of [1] to [4], a separating portion that separates the first notch portions is formed in the first notch portions.

[6] With the wiring board according to any one of [1] to [5], a distance between the mesh wiring portions is 1 mm or more and 5 mm or less.

[7] With the wiring board according to any one of [1] to [6], a dummy wiring portion that is electrically isolated from the mesh wiring portions is provided around the mesh wiring portions.

[8] With the wiring board according to [7], two or more of the dummy wiring portions are provided, and an aperture ratio of the mesh wiring portions and the dummy wiring portions becomes larger stepwise from the mesh wiring portions toward the dummy wiring portions that are far from the mesh wiring portions.

[9] A module includes the wiring board according to any one of [1] to [8], and a power supply line that is electrically connected to the power supply units of the wiring board.

With the module according to [9], the power supply line has a base material and a metal wiring portion that is laminated on the base material, two or more third notch portions that extend linearly are formed in the metal wiring portion, a width of the third notch portions is a width of the first notch portions or less, and in plan view the third notch portions extend along the first notch portions and also overlap the first notch portions.

With the module according to [9] or [10], the power supply line is electrically connected to the power supply units via an anisotropic conductive film that contains conductive particles, and the width of the first notch portions is 0.5 times or more and 1 times or less an average particle size of the conductive particles.

An image display device includes the module according to any one of [9] to [11], and a display device that is laminated on the wiring board of the module.

A wiring board includes a substrate that has transparency, and a mesh wiring portion that has conductivity and that is disposed on the substrate. The mesh wiring portion includes two or more first-direction wiring lines and two or more second-direction wiring lines, the two or more first-direction wiring lines are parallel to a first direction, and the two or more second-direction wiring lines are parallel to a second direction. With a perimeter of a region in which the mesh wiring portion is disposed as an imaginary peripheral line, the imaginary peripheral line is made up of two or more straight-line-like sides, and the imaginary peripheral line forms a closed shape, at least part of the imaginary peripheral line extends along a third direction, the first direction and the second direction are non-parallel to the third direction, and an end portion of the first-direction wiring lines and an end portion of the second-direction wiring lines are interconnected by end-portion interconnecting wiring lines at part of the imaginary peripheral line. With a total length of one side of the imaginary peripheral line in the third direction as Lₐ₁, and a summed length between both ends of the end-portion interconnecting wiring lines included in the total length Lₐ₁ as Lp, a relation of 0.1 Lₐ₁≤Lp≤0.5 Lₐ₁ holds.

With the wiring board according to [13], two or more of the end-portion interconnecting wiring lines are disposed in a form of a dotted line along the third direction.

With the wiring board according to [13] or [14], the end-portion interconnecting wiring lines extend in a straight line.

With the wiring board according to [13] or [14], the end-portion interconnecting wiring lines have a crooked line shape or a curved line shape.

With the wiring board according to any one of [13] to [16], a line width of the end-portion interconnecting wiring lines is smaller than a line width of the first-direction wiring lines and a line width of the second-direction wiring lines.

With the wiring board according to any one of [13] to [17], a pitch of the two or more first-direction wiring lines and a pitch of the two or more second-direction wiring lines is 0.01 mm or more and 1 mm or less.

With the wiring board according to any one of [13] to [18], a line width of the first-direction wiring lines and a line width of the second-direction wiring lines is 0.1 μm or more and 5.0 μm or less.

With the wiring board according to any one of [13] to [19], a dummy wiring portion that is electrically isolated from the mesh wiring portion is provided around the mesh wiring portion.

With the wiring board according to any one of [13] to [20], the mesh wiring portion functions as a millimeter wave antenna.

A wiring board includes a substrate that has transparency, and a mesh wiring portion that has conductivity and that is disposed on the substrate. The mesh wiring portion includes two or more closed shapes that are disposed with regularity, each closed shape is surrounded by wiring lines of two or more directions, and the closed shapes that are situated on a perimeter of the mesh wiring portion have shapes in which part or an entirety of the closed shapes situated other than on the perimeter of the mesh wiring portion is enlarged or reduced.

With the wiring board according to [22], two to five of the closed shapes from a perimeter side of the mesh wiring portion have shapes in which the entirety of the closed shapes situated other than on the perimeter of the mesh wiring portion is enlarged or reduced.

With the wiring board according to [22] or [23], the closed shapes are polygons.

With the wiring board according to any one of [22] to [24], a line width of the wiring lines is 0.1 μm or more and 5.0 μm or less.

With the wiring board according to any one of [22] to [25], a dummy wiring portion that is electrically isolated from the mesh wiring portion is provided around the mesh wiring portion.

With the wiring board according to any one of [22] to [26], the mesh wiring portion functions as a millimeter wave antenna.

A wiring board includes a substrate that has transparency, and a mesh wiring portion that has conductivity and that is disposed on the substrate. The mesh wiring portion includes two or more closed shapes that are disposed with irregularity, each closed shape is surrounded by wiring lines of two or more directions, and the closed shapes that are situated on a perimeter of the mesh wiring portion are situated on an inner side from the perimeter of the mesh wiring portion.

With the wiring board according to [28], a line width of the wiring lines is 0.1 μm or more and 5.0 μm or less.

With the wiring board according to [28] or [29], a dummy wiring portion that is electrically isolated from the mesh wiring portion is provided around the mesh wiring portion.

With the wiring board according to any one of [28] to [30], the mesh wiring portion functions as a millimeter wave antenna.

An image display device includes the wiring board according to any one of [13] to [31], and a display device laminated on the wiring board.

According to embodiments of the present disclosure, connectability between the power supply line and the power supply unit can be improved.

According to embodiments of the present disclosure, presence of wiring situated at a perimeter of a mesh wiring portion can be made to be less visually recognizable, while suppressing deterioration in electrical characteristics of the mesh wiring portion.

### BRIEF DESCRIPTION OF DRAWINGS

FIG. 1 is a plan view illustrating an image display device according to a first embodiment.

FIG. 2 is a cross-sectional view (cross-sectional view along line II-II in FIG. 1) illustrating the image display device according to the first embodiment.

FIG. 3 is a plan view illustrating a wiring board according to the first embodiment.

FIG. 4 is an enlarged plan view illustrating the wiring board according to the first embodiment.

FIG. 5 is a cross-sectional view (cross-sectional view along line V-V in FIG. 4) illustrating the wiring board according to the first embodiment.

FIG. 6 is a cross-sectional view (cross-sectional view along line VI-VI in FIG. 4) illustrating the wiring board according to the first embodiment.

FIG. 7 is a plan view illustrating a module according to the first embodiment.

FIG. 8 is a cross-sectional view (cross-sectional view along line VIII-VIII in FIG. 7) illustrating the module according to the first embodiment.

FIG. 9 is an exploded perspective view of the module according to the first embodiment.

FIG. 10A is a cross-sectional view illustrating a manufacturing method of the wiring board according to the first embodiment.

FIG. 10B is a cross-sectional view illustrating the manufacturing method of the wiring board according to the first embodiment.

FIG. 10C is a cross-sectional view illustrating the manufacturing method of the wiring board according to the first embodiment.

FIG. 10D is a cross-sectional view illustrating the manufacturing method of the wiring board according to the first embodiment.

FIG. 10E is a cross-sectional view illustrating the manufacturing method of the wiring board according to the first embodiment.

FIG. 10F is a cross-sectional view illustrating the manufacturing method of the wiring board according to the first embodiment.

FIG. 11A is a cross-sectional view illustrating a manufacturing method of the module according to the first embodiment.

FIG. 11B is a cross-sectional view illustrating the manufacturing method of the module according to the first embodiment.

FIG. 11C is a cross-sectional view illustrating the manufacturing method of the module according to the first embodiment.

FIG. 12A is a cross-sectional view illustrating a manufacturing method of the image display device according to the first embodiment.

FIG. 12B is a cross-sectional view illustrating the manufacturing method of the image display device according to the first embodiment.

FIG. 12C is a cross-sectional view illustrating the manufacturing method of the image display device according to the first embodiment.

FIG. 13 is a plan view illustrating a wiring board according to a first modification.

FIG. 14 is an enlarged plan view illustrating a wiring board according to a second modification.

FIG. 15 is a plan view illustrating a wiring board according to a third modification.

FIG. 16 is an enlarged plan view illustrating the wiring board according to the third modification.

FIG. 17 is a plan view illustrating a wiring board according to a fourth modification.

FIG. 18 is an enlarged plan view illustrating the wiring board according to the fourth modification.

FIG. 19 is a plan view illustrating a wiring board according to a fifth modification.

FIG. 20 is a plan view illustrating an image display device according to a second embodiment.

FIG. 21 is a plan view illustrating a wiring board according to the second embodiment.

FIG. 22 is an enlarged plan view illustrating a perimeter of a mesh wiring portion according to the second embodiment.

FIG. 23 is a cross-sectional view (cross-sectional view along line XXIII-XXIII in FIG. 22) illustrating the wiring board according to the second embodiment.

FIG. 24 is a cross-sectional view (cross-sectional view along line XXIV-XXIV in FIG. 22) illustrating the wiring board according to the second embodiment.

FIG. 25A is a cross-sectional view illustrating a manufacturing method of the wiring board according to the second embodiment.

FIG. 25B is a cross-sectional view illustrating the manufacturing method of the wiring board according to the second embodiment.

FIG. 25C is a cross-sectional view illustrating the manufacturing method of the wiring board according to the second embodiment.

FIG. 25D is a cross-sectional view illustrating the manufacturing method of the wiring board according to the second embodiment.

FIG. 25E is a cross-sectional view illustrating the manufacturing method of the wiring board according to the second embodiment.

FIG. 25F is a cross-sectional view illustrating the manufacturing method of the wiring board according to the second embodiment.

FIG. 26 is an enlarged plan view illustrating a perimeter of a mesh wiring portion according to a first modification of the second embodiment.

FIG. 27 is an enlarged plan view illustrating the perimeter of the mesh wiring portion according to the first modification of the second embodiment.

FIG. 28 is a plan view illustrating a wiring board according to a second modification of the second embodiment.

FIG. 29 is an enlarged plan view (enlarged plan view of portion XXIX in FIG. 28) illustrating a perimeter of a mesh wiring portion according to the second modification of the second embodiment.

FIG. 30 is a plan view illustrating a wiring board according to a third modification of the second embodiment.

FIG. 31 is an enlarged plan view (enlarged plan view of portion XXXI in FIG. 30) illustrating a perimeter of a mesh wiring portion according to the third modification of the second embodiment.

FIG. 32 is an enlarged plan view illustrating a perimeter of a mesh wiring portion according to a third embodiment.

FIG. 33 is an enlarged plan view illustrating a perimeter of a mesh wiring portion according to a first modification of the third embodiment.

FIG. 34 is an enlarged plan view illustrating a perimeter of a mesh wiring portion according to a second modification of the third embodiment.

FIG. 35 is an enlarged plan view illustrating a perimeter of a mesh wiring portion according to a third modification of the third embodiment.

FIG. 36 is an enlarged plan view illustrating a perimeter of a mesh wiring portion according to a fourth modification of the third embodiment.

FIG. 37 is an enlarged plan view illustrating the perimeter of the mesh wiring portion according to the fourth modification of the third embodiment.

FIG. 38A is an enlarged plan view illustrating a perimeter of a mesh wiring portion according to a fifth modification of the third embodiment.

FIG. 38B is an enlarged plan view illustrating the perimeter of the mesh wiring portion according to the fifth modification of the third embodiment.

FIG. 39A is an enlarged plan view illustrating a perimeter of a mesh wiring portion according to a sixth modification of the third embodiment.

FIG. 39B is an enlarged plan view illustrating the perimeter of the mesh wiring portion according to the sixth modification of the third embodiment.

FIG. 40 is an enlarged plan view illustrating a perimeter of a mesh wiring portion according to a fourth embodiment.

### DESCRIPTION OF EMBODIMENTS

### First Embodiment

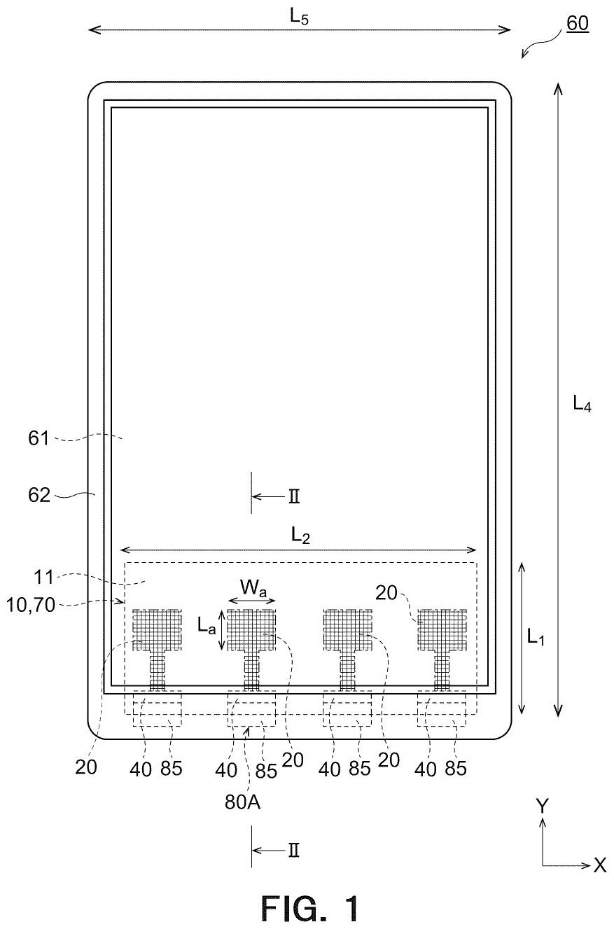

First, a first embodiment will be described by way of FIG. 1 to FIG. 12C. FIG. 1 to FIG. 12C are diagrams illustrating the present embodiment.

The diagrams described below are schematically illustrated diagrams. Accordingly, sizes and shapes of each of the portions are exaggerated as appropriate, in order to facilitate understanding. Also, implementation can be carried out modified as appropriate without departing from the technical spirit. Note that in the diagrams described below, parts that are the same are denoted by the same signs, and detailed description may be partly omitted. Also, numerical values, such as dimensions and so forth, and names of materials of the members described in the present specification are exemplary as embodiments, and can be selected as appropriate and used without being limited thereto. In the present specification, terms that identify shapes or geometrical conditions, such as for example, the terms parallel, orthogonal, perpendicular, and so forth, can be interpreted including, in addition to strict meanings thereof, states that are substantially the same.

Also, in the embodiment below, “X direction” is a direction parallel to one side of an image display device. “Y direction” is a direction that is perpendicular to the X direction and also parallel to the other side of the image display device. “Z direction” is a direction that is perpendicular to both the X direction and the Y direction, and also is parallel to a thickness direction of the image display device. “Front face” is a face on a plus side in the Z direction, which is a light-emitting face side of the image display device, and is a face that faces an observer side. “Rear face” is a face on a minus side in the Z direction, which is a face opposite to the light-emitting face of the image display device and to the face that faces the observer side. Note that in the present embodiment, an example will be described in which a mesh wiring portion 20 is a mesh wiring portion having radio wave transmission/reception functions (functions as an antenna), but the mesh wiring portion 20 does not have to have radio wave transmission/reception functions.

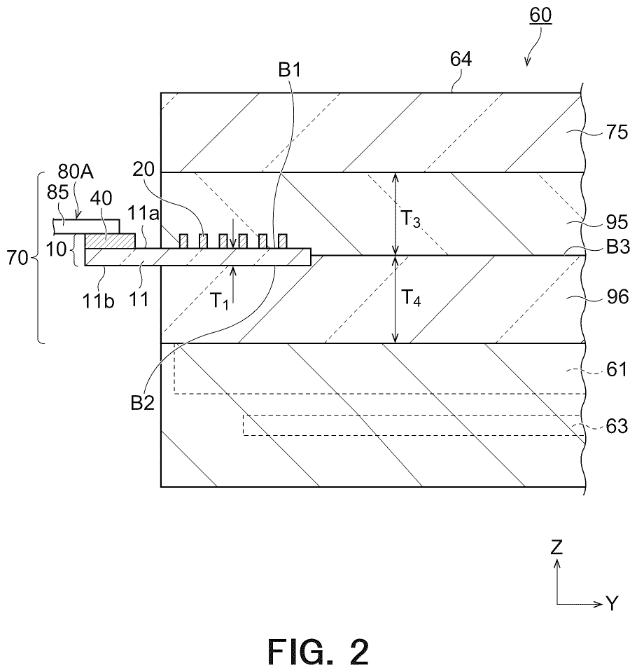

A configuration of the image display device according to the present embodiment will be described with reference to FIG. 1 and FIG. 2.

As illustrated in FIG. 1 and FIG. 2, an image display device 60 according to the present embodiment includes a module 80A, and a display device (display) 61 that is laminated on the module 80A. Of these, the module 80A includes a wiring board 10, and a power supply line 85 that is electrically connected to a power supply unit 40, which will be described later, of the wiring board 10. Also, an image display device laminate 70 is made up of the module 80A, a first transparent adhesive layer (first adhesive layer) 95 that will be described later, and a second transparent adhesive layer (second adhesive layer) 96 that will be described later.

The wiring board 10 of the module 80A has a substrate 11 the mesh wiring portion 20, and the power supply unit 40. As illustrated in FIG. 2, the substrate 11 includes a first face 11a, and a second face 11b situated on an opposite side from the first face 11a. A plurality of (two or more) mesh wiring portions 20 are disposed on the first face 11a of the substrate 11. Also, the mesh wiring portions 20 are each electrically connected to power supply units 40. Further, a communication module 63 is disposed on the minus side of the display device 61 in the Z direction. The image display device laminate 70, the display device 61, and the communication module 63 are accommodated in a housing 62.

In the image display device 60 illustrated in FIG. 1 and FIG. 2, radio waves of a predetermined frequency can be transmitted/received, and communication can be performed via the communication module 63. The communication module 63 may include one of a millimeter wave antenna, an antenna for telephone, an antenna for WiFi, an antenna for 3G, an antenna for 4G, an antenna for 5G, an antenna for LTE, an antenna for Bluetooth (registered trademark), an antenna for NFC, and so forth. Examples of such image display devices 60 include mobile terminal equipment such as smartphones, tablets, and so forth.

As illustrated in FIG. 2, the image display device 60 has a light-emitting face 64. The image display device 60 includes the wiring board 10 that is situated on the light-emitting face 64 side (plus side in Z direction) as to the display device 61, and the communication module 63 that is situated on the opposite side from the light-emitting face 64 (minus side in Z direction) as to the display device 61.

The display device 61 is made up of an organic EL (Electro Luminescence) display device, for example.

The display device 61 may include a metal layer, a support base material, a resin base material, a thin-film transistor (TFT), and an organic EL layer, which are not illustrated, for example. A touch sensor that is not illustrated may be disposed above the display device 61. Also, the wiring board 10 is disposed above the display device 61 with the second transparent adhesive layer 96 interposed therebetween. Note that the display device 61 is not limited to an organic EL display device. For example, the display device 61 may be another display device that has functions of light emission in itself, and may be a micro-LED display device including microscopic LED elements. Alternatively, the display device 61 may be a liquid crystal display device including liquid crystal.

A cover glass 75 is disposed above the wiring board 10 with the first transparent adhesive layer 95 interposed therebetween. Note that a decorative film and a polarizing plate, which are not illustrated, may be disposed between the first transparent adhesive layer 95 and the cover glass 75.

The first transparent adhesive layer 95 is an adhesive layer that directly or indirectly performs adhesion of the wiring board 10 to the cover glass 75. This first transparent adhesive layer 95 is situated in the first face 11a side of the substrate 11. The first transparent adhesive layer 95 has optical transparency, and may be an OCA (Optical Clear Adhesive) layer. The OCA layer is a layer that is fabricated as follows, for example. First, a curable adhesive layer composition that is in a liquid state and that includes a polymerizable compound is coated on a releasing film of polyethylene terephthalate (PET) or the like. This is then cured by using ultraviolet rays (UV) or the like, for example, thereby obtaining an OCA sheet. This OCA sheet is applied to an object, following which the releasing film is removed by separation, thereby obtaining the OCA layer. The material of the first transparent adhesive layer 95 may be an acrylic-based resin, a silicone-based resin, a urethane-based resin, or the like. In particular, the first transparent adhesive layer 95 may contain an acrylic-based resin. In this case, the second transparent adhesive layer 96 preferably contains acrylic-based resin. This substantially does away with difference in refractive index between the first transparent adhesive layer 95 and the second transparent adhesive layer 96, and reflection of visible light at an interface B3 between the first transparent adhesive layer 95 and the second transparent adhesive layer 96 can be suppressed in a more reliable manner.

Transmittance of visible light rays of the first transparent adhesive layer 95 may be 85% or more, and preferably is 90% or more. Note that there is no upper limit in particular to transmittance of visible light rays of the first transparent adhesive layer 95, but this may be, for example, 100% or less. Making transmittance of visible light rays of the first transparent adhesive layer 95 to be in the above range raises the transparency of the image display device laminate 70, thereby facilitating visibility of the display device 61 of the image display device 60. Note that the term visible light rays as used here means light rays of wavelengths 400 nm or more and 700 nm or less. Also, the term transmittance of visible light rays of 85% or more means that transmittance of the entire wavelength domain of 400 nm or higher and 700 nm or lower is 85% or more when light absorbance is measured for the member to be measured (e.g., first transparent adhesive layer 95) using a known spectrophotometer (e.g., spectrophotometer (UV-visible IR spectrophotometer) V-670 manufactured by JASCO Corporation). Also, transmittance of a predetermined region of the wiring board 10 can also be measured using the above UV-visible IR spectrophotometer “V-670”. In a case of measuring transmittance of a region where the mesh wiring portion 20 is present, measurement is performed such that the mesh wiring portion 20 is included in the entire measurement range (10 mm×3 mm range) of the above UV-visible IR spectrophotometer.

The wiring board 10 is disposed above the light-emitting face 64 side from the display device 61, as described above. In this case, the wiring board 10 is situated between the first transparent adhesive layer 95 and the second transparent adhesive layer 96. More specifically, a partial region of the substrate 11 of the wiring board 10 is disposed in a partial region between the first transparent adhesive layer 95 and the second transparent adhesive layer 96. In this case, the first transparent adhesive layer 95, the second transparent adhesive layer 96, the display device 61, and the cover glass 75 each have a greater area than that of the substrate 11 of the wiring board 10. Thus, disposing the substrate 11 of the wiring board 10 in not the entire area of the image display device 60 in plan view but in a partial region thereof enables the overall thickness of the image display device 60 to be reduced.

As described above, the wiring board 10 has the substrate 11 that has transparency, and the plurality of (two or more) mesh wiring portions 20 that are disposed away from each other, and a plurality of (two or more) the power supply units 40, on the first face 11a of the substrate 11. The power supply units 40 are electrically connected to the mesh wiring portions 20. In this case, each of the mesh wiring portions 20 and each of the power supply units 40 are independently connected to each other. The power supply units 40 are electrically connected to the communication module 63 via the power supply lines 85. Also, part of the wiring board 10 is not disposed between the first transparent adhesive layer 95 and the second transparent adhesive layer 96, but protrudes outward (minus side in Y direction) from between the first transparent adhesive layer 95 and the second transparent adhesive layer 96. Specifically, a region of the wiring board 10 in which the power supply unit 40 is provided protrudes outward. Accordingly, performing electrical connection between the power supply unit 40 and the communication module 63 is facilitated. On the other hand, a region of the wiring board 10 in which the mesh wiring portion 20 is provided is situated between the first transparent adhesive layer 95 and the second transparent adhesive layer 96. Note that details of the wiring board 10 and the power supply lines 85 will be described later.

The second transparent adhesive layer 96 is an adhesive layer that directly or indirectly performs adhesion of the display device 61 to the wiring board 10. This second transparent adhesive layer 96 is situated on the second face 11b side of the substrate 11. The second transparent adhesive layer 96 has optical transparency, and may be an OCA (Optical Clear Adhesive) layer, in the same way as the first transparent adhesive layer 95. The material of the second transparent adhesive layer 96 may be an acrylic-based resin, a silicone-based resin, a urethane-based resin, or the like. In particular, the second transparent adhesive layer 96 may contain an acrylic-based resin. This substantially does away with difference in refractive index between the first transparent adhesive layer 95 and the second transparent adhesive layer 96, and reflection of visible light at the interface B3 between the first transparent adhesive layer 95 and the second transparent adhesive layer 96 can be suppressed in a more reliable manner.

Also, transmittance of visible light rays (light rays of wavelengths 400 nm or more and 700 nm or less) of the second transparent adhesive layer 96 may be 85% or more, and preferably is 90% or more. Note that there is no upper limit in particular to transmittance of visible light rays of the second transparent adhesive layer 96, but this may be, for example, 100% or less. Making transmittance of visible light rays of the second transparent adhesive layer 96 to be in the above range raises the transparency of the image display device laminate 70, thereby facilitating visibility of the display device 61 of the image display device 60.

In such an image display device 60, difference between the refractive index of the substrate 11 and the refractive index of the first transparent adhesive layer 95 is 0.1 or less, and preferably is 0.05 or less. Also, difference between the refractive index of the substrate 11 and the refractive index of the second transparent adhesive layer 96 is 0.1 or less, and preferably is 0.05 or less. Further, the difference between the refractive index of the first transparent adhesive layer 95 and the refractive index of the second transparent adhesive layer 96 is preferably 0.1 or less, and more preferably is 0.05 or less. For example, in a case in which the material of the first transparent adhesive layer 95 and the material of the second transparent adhesive layer 96 are acrylic-based resin of which the refractive index is 1.49, the refractive index of the substrate 11 is 1.39 or more and 1.59 or less. Examples of such materials include fluororesins, silicone-based resins, polyolefin resins, polyester-based resins, acrylic-based resins, polycarbonate-based resins, polyimide-based resins, cellulose-based resins, and so forth.

Thus, by suppressing the difference between the refractive index of the substrate 11 and the refractive index of the first transparent adhesive layer 95 to 0.1 or less, reflection of visible light at an interface B1 between the substrate 11 and the first transparent adhesive layer 95 can be suppressed, and the substrate 11 can be made to be less readily visually recognizable by the bare eye of the observer. Also, by suppressing the difference between the refractive index of the substrate 11 and the refractive index of the second transparent adhesive layer 96 to 0.1 or less, reflection of visible light at an interface B2 between the substrate 11 and the second transparent adhesive layer 96 can be suppressed, and the substrate 11 can be made to be less readily visually recognizable by the bare eye of the observer. Further, by suppressing the difference between the refractive index of the first transparent adhesive layer 95 and the refractive index of the second transparent adhesive layer 96 to 0.1 or less, reflection of visible light at the interface B3 between the first transparent adhesive layer 95 and the second transparent adhesive layer 96 can be suppressed. Accordingly, the first transparent adhesive layer 95 and the second transparent adhesive layer 96 can be made to be less readily visually recognizable by the bare eye of the observer.

In particular, the material of the first transparent adhesive layer 95 and the material of the second transparent adhesive layer 96 are preferably the same material as each other. Accordingly, the difference in the refractive indices between the first transparent adhesive layer 95 and the second transparent adhesive layer 96 can be further reduced, and reflection of visible light at the interface B3 between the first transparent adhesive layer 95 and the second transparent adhesive layer 96 can be suppressed.

Also, in FIG. 2, at least one thickness of thickness T₃ of the first transparent adhesive layer 95 and thickness T₄ of the second transparent adhesive layer 96 may be 1.5 times thickness T₁ of the substrate 11 or more, preferably is 2 times thereof or more, and even more preferably is 2.5 times thereof or more. By making the thickness T₃ of the first transparent adhesive layer 95 or the thickness T₄ of the second transparent adhesive layer 96 to be sufficiently thick as to the thickness T₁ of the substrate 11 in this way, the first transparent adhesive layer 95 or the second transparent adhesive layer 96 deforms in the thickness direction in a region overlapping the substrate 11, and takes up the thickness of the substrate 11. Accordingly, stepped portions can be suppressed from being formed in the first transparent adhesive layer 95 or the second transparent adhesive layer 96 at a peripheral edge of the substrate 11, and the presence of the substrate 11 can be made to be less readily visually recognizable by the observer.

At least one thickness of the thickness T₃ of the first transparent adhesive layer 95 and the thickness T₄ of the second transparent adhesive layer 96 is preferably 10 times the thickness T₁ of the substrate 11 or less, and more preferably is five times thereof or less. Accordingly, the thickness T₃ of the first transparent adhesive layer 95 or the thickness T₄ of the second transparent adhesive layer 96 does not become too great, and the thickness of the overall image display device 60 can be reduced.

Also, in FIG. 2, the thickness T₃ of the first transparent adhesive layer 95 and the thickness T₄ of the second transparent adhesive layer 96 may be the same as each other. In this case, the thickness T₃ of the first transparent adhesive layer 95 and the thickness T₄ of the second transparent adhesive layer 96 may each be 1.5 times the thickness T₁ of the substrate 11 or more, and preferably 2.0 times thereof or more. That is to say, the total of the thickness T₃ of the first transparent adhesive layer 95 and the thickness T₄ of the second transparent adhesive layer 96 (T₃+T₄) is three times the thickness T₁ of the substrate 11 or more. Thus, by making the total of thicknesses T₃ and T₄ of the first transparent adhesive layer 95 and the second transparent adhesive layer 96 to be sufficiently thick with respect to the thickness T₁ of the substrate 11, the first transparent adhesive layer 95 and the second transparent adhesive layer 96 deform (contract) in the thickness direction in the region overlapping the substrate 11. Thus, the first transparent adhesive layer 95 and the second transparent adhesive layer 96 take up the thickness of the substrate 11. Thus, stepped portions can be suppressed from being formed in the first transparent adhesive layer 95 or the second transparent adhesive layer 96 at the peripheral edge of the substrate 11, and the presence of the substrate 11 can be made to be less readily visually recognizable by the observer.

In a case in which the thickness T₃ of the first transparent adhesive layer 95 and the thickness T₄ of the second transparent adhesive layer 96 are the same as each other, the thickness T₃ of the first transparent adhesive layer 95 and the thickness T₄ of the second transparent adhesive layer 96 may each be five times the thickness T₁ of the substrate 11 or less, and preferably three times thereof or less. Accordingly, the thicknesses T₃ and T₄ of both of the first transparent adhesive layer 95 and the second transparent adhesive layer 96 do not become too great, and the thickness of the overall image display device 60 can be reduced.

Specifically, the thickness T₁ of the substrate 11 may be, for example, 2 μm or more, may be 10 μm or more, and preferably is 15 μm or more. By making the thickness T₁ of the substrate 11 to be 2 μm or more, strength of the wiring board 10 can be maintained, such that first-direction wiring lines 21 and second-direction wiring lines 22, which will be described later, of the mesh wiring portions 20, are not readily deformed. Also, the thickness T₁ of the substrate 11 may be, for example, 200 μm or less, may be 50 μm or less, and preferably is 25 μm or less. By making the thickness T₁ of the substrate 11 to be 200 μm or less, stepped portions can be suppressed from being formed between the first transparent adhesive layer 95 and the second transparent adhesive layer 96 at the peripheral edge of the substrate 11, and the presence of the substrate 11 can be recognized less readily by the observer. Also, by making the thickness T₁ of the substrate 11 to be 50 μm or less, stepped portions can be further suppressed from being formed in the first transparent adhesive layer 95 and the second transparent adhesive layer 96 at the peripheral edge of the substrate 11, and the presence of the substrate 11 can be made to be even further less readily visually recognizable by the observer.

The thickness T₃ of the first transparent adhesive layer 95 may be 15 μm or more, for example, and preferably is 20 μm or more. The thickness T₃ of the first transparent adhesive layer 95 may be 500 μm or less, for example, preferably is 300 μm or less, and more preferably is 250 μm or less. The thickness T₄ of the second transparent adhesive layer 96 may be 15 μm or more, for example, and preferably is 20 μm or more. The thickness T₄ of the second transparent adhesive layer 96 may be 500 μm or less, for example, preferably is 300 μm or less, and more preferably is 250 μm or less.

Referencing FIG. 2 again, the cover glass 75 is directly or indirectly disposed on the first transparent adhesive layer 95. This cover glass 75 is a member made of glass that transmits light. The cover glass 75 is plate-like, and the shape of the cover glass 75 may be a rectangular shape in plan view. The thickness of the cover glass 75 may be 200 μm or more and 1000 μm or less for example, and preferably is 300 μm or more and 700 μm or less. The length of the cover glass 75 in a longitudinal direction (Y direction) may be 20 mm or more and 500 mm or less for example, and preferably 100 mm or more and 200 mm or less. The length of the cover glass 75 in a lateral direction (X direction) may be 20 mm or more and 500 mm or less, and preferably 50 mm or more and 100 mm or less.

As illustrated in FIG. 1, the shape of the image display device 60 is substantially rectangular overall in plan view, the longitudinal direction thereof is parallel to the Y direction, and the lateral direction thereof is parallel to the X direction. A length L₄ of the image display device 60 in the longitudinal direction (Y direction) can be selected from a range of 20 mm or more and 500 mm or less for example, and preferably 100 mm or more and 200 mm or less. A length L₅ of the image display device 60 in the lateral direction (X direction) can be selected from a range of 20 mm or more and 500 mm or less for example, and preferably 50 mm or more and 100 mm or less. Note the planar shape of the image display device 60 may be a rectangle of which corner portions are each rounded.

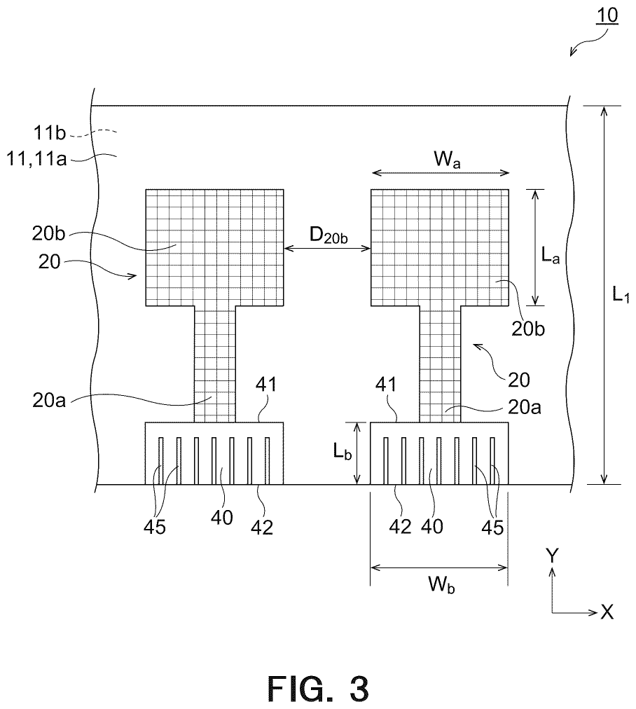

Next, a configuration of the wiring board will be described with reference to FIG. 3 to FIG. 6. FIG. 3 to FIG. 6 are diagrams illustrating the wiring board according to the present embodiment.

The wiring board 10 according to the present embodiment is a board used in the image display device 60 (see FIG. 1 and FIG. 2) described above. The wiring board 10 can be disposed between the first transparent adhesive layer 95 and the second transparent adhesive layer 96, closer to the light-emitting face 64 side than the display device 61. As illustrated in FIG. 3, such a wiring board 10 includes the substrate 11 that has transparency, the plurality of mesh wiring portions 20 disposed away from each other on the substrate 11, and the plurality of power supply units 40. Also, the power supply units 40 are electrically connected to the mesh wiring portions 20. Each of the mesh wiring portions 20 and each of the power supply units 40 are respectively individually connected.

The shape of the substrate 11 is substantially rectangular in plan view. In the example that is illustrated, a longitudinal direction thereof is parallel to the X direction, and a lateral direction thereof is parallel to the Y direction. The substrate 11 has transparency and also has a substantially plate-like shape, and the thickness thereof is substantially uniform overall. A length L₁ (see FIG. 1 and FIG. 3) of the substrate 11 in the longitudinal direction (Y direction) of the image display device 60 can be selected from a range of 10 mm or more and 200 mm or less, for example. A length L₂ (see FIG. 1) of the substrate 11 in the lateral direction (X direction) of the image display device 60 can be selected from a range of 3 mm or more and 100 mm or less, for example. Note that the planar shape of the substrate 11 may be a rectangle of which corner portions are each rounded.

It is sufficient for material of the substrate 11 to be a material that has transparency in the visible light domain, and electrical insulating properties. A polyester-based resin, an acrylic-based resin, a polycarbonate-based resin, a polyimide-based resin, polyolefin-based resin, cellulose-based resin, a fluororesin material, and like organic insulating materials, for example, are preferably used as the material of the substrate 11. The polyester-based resin may be polyethylene terephthalate or the like. The acrylic-based resin may be polymethyl methacrylate or the like. The polyolefin-based resin may be a cycloolefin polymer or the like. The cellulose-based resin may be triacetyl cellulose or the like. The fluororesin material may be PTFE, PFA, or the like. For example, an organic insulating material such as a cycloolefin polymer (e.g., ZF-16 manufactured by Zeon Corporation), or a polynorbornene polymer (manufactured by Sumitomo Bakelite Co. Ltd.), or the like may be used as the material of the substrate 11. Also, depending on the usage, glass or ceramics or the like may be selected as appropriate as the material of the substrate 11. Note that an example is illustrated in which the substrate 11 is made up of a single layer, but this is not restrictive, and a structure may be made in which a plurality of base materials or layers are laminated. Also, the substrate 11 may be a film-like member or may be a plate-like member.

Also, the dissipation factor of the substrate 11 may be 0.002 or less, and preferably is 0.001 or less. Note that while there is no particular lower limit, the dissipation factor of the substrate 11 may be greater than 0. Having the dissipation factor of the substrate 11 in the above range enables loss of gain (deteriorated sensitivity) in conjunction with transmission/reception of electromagnetic waves to be reduced, particularly in a case in which the electromagnetic waves transmitted/received by the mesh wiring portion 20 (e.g., millimeter waves) are radio frequency waves.

The relative permittivity of the substrate 11 preferably is 2 or more and 10 or less. A greater range of options is available as the material of the substrate 11 by the relative permittivity of the substrate 11 being 2 or more. Also, loss of gain in conjunction with transmission/reception of electromagnetic waves can be reduced by the relative permittivity of the substrate 11 being 10 or less. That is to say, in a case in which the relative permittivity of the substrate 11 is great, the effects of the thickness of the substrate 11 on propagation of electromagnetic waves increases. Also, in a case in having adverse effects on the propagation of electromagnetic waves, the dissipation factor of the substrate 11 increases, and loss of gain in conjunction with transmission/reception of electromagnetic waves can increase. Conversely, the relative permittivity of the substrate 11 being 10 or less can reduce the effects of the thickness of the substrate 11 on the propagation of electromagnetic waves. Accordingly, loss of gain in conjunction with transmission/reception of electromagnetic waves can be reduced. In particular, in a case in which the electromagnetic waves transmitted/received by the mesh wiring portion 20 (e.g., millimeter waves) are radio frequency waves, loss of gain in conjunction with transmission/reception of electromagnetic waves can be reduced.

The dissipation factor and the relative permittivity of the substrate 11 can be measured in conformance with IEC 62562. Specifically, first, a portion of the substrate 11 on which the mesh wiring portion 20 is not formed is cut out to prepare a test piece. The dimensions of the test piece are 10 mm or more and 20 mm or less in width and 50 mm or more and 100 mm or less in length. Next, the dissipation factor or the relative permittivity is measured in conformance with IEC 62562.

In the present embodiment, the substrate 11 has transparency. In the present specification, “has transparency” means transmittance of visible light rays (light rays having wavelength of 400 nm or higher and 700 nm or lower) being 85% or more. Transmittance of the substrate 11 regarding visible light rays may be 85% or more, and preferably is 90% or more. Note that there is no upper limit to the transmittance of visible light rays of the substrate 11 in particular, but may be 100% or less, for example. Having the transmittance of visible light rays of the substrate 11 in the above range raises the transparency of the wiring board 10, and facilitates visual recognition of the display device 61 of the image display device 60.

In the present embodiment, the mesh wiring portion 20 is made up of an antenna pattern having functions as an antenna. The mesh wiring portion 20 may be configured as an array antenna. In a case of configuring the mesh wiring portion 20 as an array antenna in this way, millimeter wave antenna performance of transmitting/receiving millimeter waves that have high straight-line propagation properties can be improved. Note that an array antenna is an antenna in which a plurality of antenna elements (radiating elements) are laid out with regularity, and the amplitudes and phases of excitation of the elements can be independently controlled.

As illustrated in FIG. 3, the plurality of mesh wiring portions 20 are formed on the substrate 11. Four or more mesh wiring portions 20 are preferably provided. In the example that is illustrated, four mesh wiring portions 20 are formed on the substrate 11 (see FIG. 1). Also, as illustrated in FIG. 3, the mesh wiring portion 20 may be present only on a partial region of the substrate 11, rather than being present over the entire face of the substrate 11. The mesh wiring portions 20 may each have the same shape as each other. In this case, error in length (distance in Y direction) Lₐ and error in width (distance in X direction) Wₐ of a distal side portion 20b which will be described later, in each of the mesh wiring portions 20, are preferably within 10%. Thus, millimeter wave antenna performance can be effectively improved.

The mesh wiring portion 20 has a basal side portion (transfer portion) 20a on the power supply unit 40 side, and the distal side portion (transmission/reception portion) 20b connected to the basal side portion 20a. The basal side portion 20a is connected to the power supply unit 40. The shape of the basal side portion 20a and the shape of the distal side portion 20b are each substantially rectangular in plan view. In this case, the length (Y-direction distance) of the distal side portion 20b is substantially the same as the length (Y-direction distance) of the basal side portion 20a, and the width (X-direction distance) of the distal side portion 20b is broader than the width (X-direction distance) of the basal side portion 20a.

This distal side portion 20b of the mesh wiring portion 20 corresponds to a predetermined frequency band. That is to say, the length (distance in Y direction) Lₐ of the distal side portion 20b has a length corresponding to a particular frequency band. Note that the lower frequency the corresponding frequency band is, the longer the length Lₐ of the distal side portion 20b becomes. The mesh wiring portion 20 may correspond to, besides an antenna for millimeter waves, one of an antenna for telephone, an antenna for WiFi, an antenna for 3G, an antenna for 4G, an antenna for 5G, an antenna for LTE, an antenna for Bluetooth (registered trademark), an antenna for NFC, and so forth. Note that lengths of a plurality of the distal side portions 20b may differ from each other, and may correspond to different frequency bands from each other. Alternatively, in a case in which the wiring board 10 does not have radio wave transmission/reception functions, each mesh wiring portion 20 may have functions such as, for example, a hovering function (a function enabling a user to perform operations even without directly touching the display), fingerprint authentication, heater, noise reduction (shielding), and so forth. Note that the hovering function is a function that enables the user to perform operations even without directly touching the display.

The longitudinal direction of the distal side portion 20b is parallel to the X direction, and the lateral direction thereof is parallel to the Y direction. The length Lₐ of the distal side portion 20b in the Y direction can be selected from a range of 1 mm or more and 100 mm or less, for example. The width Wₐ of the distal side portion 20b in the X direction can be selected from a range of 1 mm or more and 100 mm or less, for example. In particular, in a case in which the mesh wiring portion 20 is a millimeter wave antenna, the length Lₐ of the distal side portion 20b can be selected from a range of 1 mm or more, and more preferably 1.5 mm or more. In a case in which the mesh wiring portion 20 is a millimeter wave antenna, the length Lₐ of the distal side portion 20b can be selected from a range of 10 mm or less, and more preferably 5 mm or less.

The distance between mesh wiring portions 20 is preferably 1 mm or more and 5 mm or less. That is to say, a distance D_{20b} (see FIG. 3) between the distal side portions 20b is preferably 1 mm or more and 5 mm or less. Due to the distance D_{20b} between the distal side portions 20b being 1 mm or more, unintended interference of electromagnetic waves between the antenna elements can be suppressed. Due to the distance D_{20b} between the distal side portions 20b being 5 mm or less, the size of the overall array antenna made up of the mesh wiring portions 20 can be reduced. For example, in a case in which the mesh wiring portion 20 is a 28 GHz millimeter wave antenna, the distance D_{20b} between the distal side portions 20b may be 3.5 mm. Also, in a case in which the mesh wiring portion 20 is a 60 GHz millimeter wave antenna, the distance D_{20b} between the distal side portions 20b may be 1.6 mm.

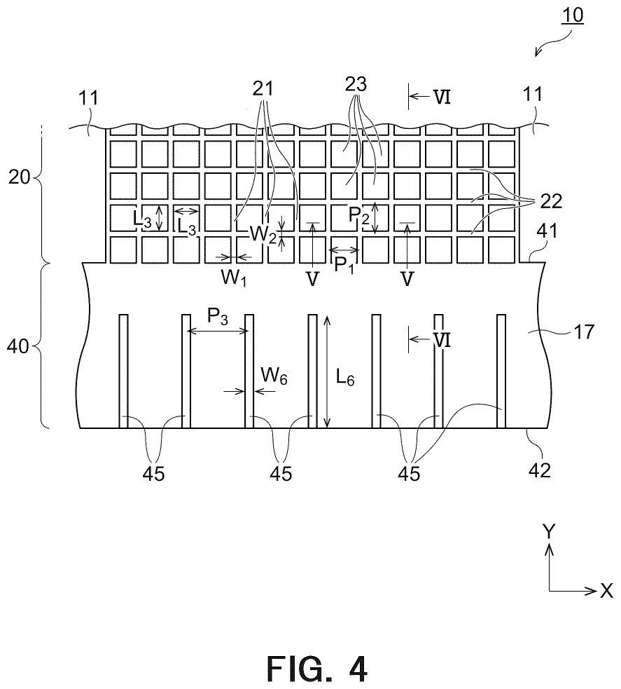

As illustrated in FIG. 4, the mesh wiring portion 20 has a pattern form in which respective metal lines are laid out in a grid-like or a fishnet-like form. This pattern form is repetitively laid out in the X direction and in the Y direction. That is to say, the mesh wiring portion 20 has a pattern form that is made up of portions extending in a first direction (e.g., Y direction) (first-direction wiring lines 21 described later), and portions extending in a second direction (e.g., X direction) (second-direction wiring lines 22 described later).

The mesh wiring portion 20 has a plurality of (two or more) wiring lines. Specifically, the mesh wiring portion 20 has a plurality of (two or more) the first-direction wiring lines 21, and a plurality of (two or more) the second-direction wiring lines 22 interconnecting the plurality of first-direction wiring lines 21. The plurality of first-direction wiring lines 21 and the plurality of second-direction wiring lines 22 overall and integrally form a grid-like or fishnet-like form. The first-direction wiring lines 21 extend in the longitudinal direction (Y direction) of the mesh wiring portion 20. The second-direction wiring lines extend in straight lines in a width direction of the mesh wiring portion 20 (X direction). Note that the first-direction wiring lines 21 and the second-direction wiring lines 22 may each extend in directions not parallel to either of the X direction or the Y direction.

In the mesh wiring portion 20, a plurality of openings 23 are formed by being surrounded by the first-direction wiring lines 21 adjacent to each other and the second-direction wiring lines 22 adjacent to each other. The planar shape of each opening 23 is a substantially rhombic shape in plan view. The substrate 11 that has transparency is exposed from the openings 23. Thus, the overall transparency of the wiring board 10 can be raised.

In the mesh wiring portion 20, the plurality of openings 23 are formed by being surrounded by the first-direction wiring lines 21 adjacent to each other and the second-direction wiring lines 22 adjacent to each other. Also, the first-direction wiring lines 21 and the second-direction wiring lines 22 are disposed equidistantly to each other. That is to say, the plurality of first-direction wiring lines 21 are disposed equidistantly to each other, and a pitch P₁ thereof can be in a range of 0.01 mm or more and 1 mm or less, for example. Also, the plurality of second-direction wiring lines 22 are disposed equidistantly to each other, and a pitch P₂ thereof can be in a range of 0.01 mm or more and 1 mm or less, for example. In this way, due to the plurality of first-direction wiring lines 21 and the plurality of second-direction wiring lines 22 being each disposed equidistantly, variance in the size of the openings 23 in the mesh wiring portion 20 is eliminated, and the mesh wiring portion 20 can be made to be less readily visually recognizable by the bare eye. Also, the pitch P₁ of the first-direction wiring lines 21 is equal to the pitch P₂ of the second-direction wiring lines 22. Accordingly, the openings 23 each have a substantially square shape in plan view, and the substrate 11 that has transparency is exposed from each of the openings 23. Thus, the transparency of the wiring board 10 overall can be increased by increasing the area of the openings 23. Note that a length L₃ of one side of the openings 23 can be in a range of 0.01 mm or more and 1 mm or less, for example. Note that while the first-direction wiring lines 21 and the second-direction wiring lines 22 are orthogonal to each other, this is not restrictive, and these may intersect each other at acute angles or obtuse angles. Also, the shapes of the openings 23 preferably are the same shape and the same size over the entire area, but do not have to be uniform over the entire area, with changes being made thereto depending on the location, or the like.

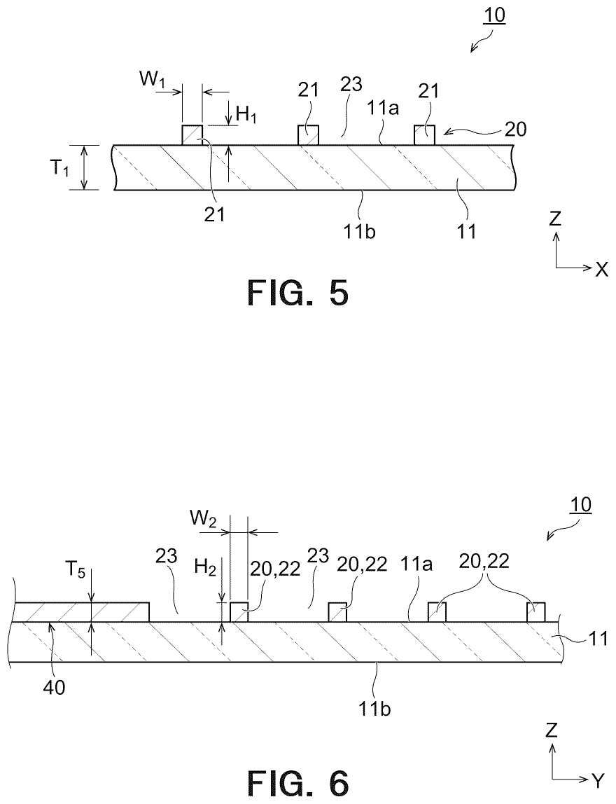

As illustrated in FIG. 5, the cross-section of each first-direction wiring line 21 perpendicular to the longitudinal direction (X-direction cross-section) has a shape that is substantially a rectangle or substantially a square. In this case, the cross-sectional shape of the first-direction wiring lines 21 is substantially uniform along the longitudinal direction (Y direction) of the first-direction wiring lines 21. As illustrated in FIG. 6, the cross-section of each second-direction wiring line 22 perpendicular to the longitudinal direction (Y-direction cross-section) thereof has a shape that is substantially a rectangle or substantially a square, and has substantially the same cross-sectional shape as the first-direction wiring lines 21 described above (X-direction cross-section). In this case, the cross-sectional shape of the second-direction wiring lines 22 is substantially uniform along the longitudinal direction (X direction) of the second-direction wiring lines 22. The cross-sectional shape of the first-direction wiring lines 21 and the cross-sectional shape of the second-direction wiring lines 22 do not necessarily have to be substantially rectangle shapes or substantially squares. For example, the cross-sectional shape of the first-direction wiring lines 21 and the cross-sectional shape of the second-direction wiring lines 22 may be substantially a trapezoid in which a front face side (plus side in the Z direction) is narrower than a rear face side (minus side in the Z direction), or a shape in which side faces situated on both sides in the longitudinal direction are curved.

In the present embodiment, a line width W₁ (see FIG. 5) of the first-direction wiring lines 21 and a line width W₂ (see FIG. 6) of the second-direction wiring lines 22 are not limited in particular, and can be selected as appropriate in accordance with the usage. Here, the line width W₁ of the first-direction wiring lines 21 is the width (X-direction distance) of a cross-section perpendicular to the longitudinal direction thereof, and the line width W₂ of the second-direction wiring lines 22 is the width (Y-direction distance) of a cross-section perpendicular to the longitudinal direction thereof. For example, the line width W₁ of the first-direction wiring lines 21 can be selected from a range of 0.1 μm or more and 5.0 μm or less, and preferably is 0.2 μm or more and 2.0 μm or less. Also, the line width W₂ of the second-direction wiring lines 22 can be selected from a range of 0.1 μm or more and 5.0 μm or less, and preferably is 0.2 μm or more and 2.0 μm or less.

A height H₁ (see FIG. 5) of the first-direction wiring lines 21 and a height H₂ (see FIG. 6) of the second-direction wiring lines 22 are not limited in particular and can be selected as appropriate in accordance with the usage. Here, the height H₁ of the first-direction wiring lines 21 and the height H₂ of the second-direction wiring lines 22 are each the length thereof in the Z direction. The height H₁ of the first-direction wiring lines 21 and the height H₂ of the second-direction wiring lines 22 can each be selected from a range of 0.1 μm or more, for example, and preferably are 0.2 μm or more. The height H₁ of the first-direction wiring lines 21 and the height H₂ of the second-direction wiring lines 22 can each be selected from a range of 5.0 μm or less, for example, and preferably are 2.0 μm or less.

It is sufficient for the material of the first-direction wiring lines 21 and the second-direction wiring lines 22 to be a metal material that has conductivity. The material of the first-direction wiring lines 21 and the second-direction wiring lines 22 is copper in the present embodiment, but is not limited thereto. Metal materials such as gold, silver, copper, platinum, tin, aluminum, iron, or nickel or the like, or alloys including these metals, for example, can be used as the material of the first-direction wiring lines 21 and the second-direction wiring lines 22. Also, the first-direction wiring lines 21 and the second-direction wiring lines 22 may be plating layers formed by electrolytic plating.

An overall aperture ratio At of the mesh wiring portion 20 may be, for example, in a range of 87% or more and less than 100%. By setting the overall aperture ratio At of the mesh wiring portion 20 to this range, conductivity and transparency of the wiring board 10 can be secured. The overall aperture ratio At of the mesh wiring portion 20 may be 87% or more, may be 90% or more, or may be 95% or more. The overall aperture ratio At of the mesh wiring portion 20 may be less than 100%, may be 98% or less, or may be 96% or less. By setting the overall aperture ratio At of the wiring board 10 to this range, transparency of the wiring board 10 can be raised while securing conductivity of the wiring board 10. Note that an aperture ratio is a ratio (%) of area of opening regions within a unit area of a predetermined region (e.g., the entire mesh wiring portion 20). The opening regions are regions where no metal portions, such as the first-direction wiring lines 21, the second-direction wiring lines 22, and so forth, are present, and the substrate 11 is exposed.

Note that a protective layer may be formed on the first face 11a of the substrate 11 so as to cover the mesh wiring portion 20, although not illustrated. The protective layer is to protect the mesh wiring portion 20, and is formed so as to cover at least the mesh wiring portion 20 out of the substrate 11. Acrylic resins such as polymethyl (meth)acrylate, polyethyl (meth)acrylate, and so forth, and denatured resins and copolymers thereof, polyvinyl resins such as polyester, polyvinyl alcohol, polyvinyl acetate, polyvinyl acetal, polyvinyl butyral, and so forth, and copolymers thereof, polyurethane, epoxy resin, polyamide, chlorinated polyolefin, and so forth, and like insulating resins that are colorless and transparent, can be used as the material of the protective layer.

Referencing FIG. 3 and FIG. 4 again, the power supply unit 40 is electrically connected to the mesh wiring portion 20. This power supply unit 40 is made of a thin-plate-like member that is substantially rectangular and conductive. The longitudinal direction of the power supply unit 40 is parallel to the X direction, and the lateral direction of the power supply unit 40 is parallel to the Y direction. The power supply unit 40 has a first end portion 41 that connects to the mesh wiring portion 20, and a second end portion 42 that is on an opposite side from the first end portion 41.

A length L_{b} (see FIG. 3) of the power supply unit 40 in the lateral direction (Y direction) can be selected from a range of 1 mm or more and 100 mm or less, for example. A width W_{b} (see FIG. 3) of the power supply unit 40 in the longitudinal direction (X direction) may be 0.2 mm or more, for example. Now, in a case in which the width W_{b} of the power supply unit 40 is a certain value or more, such as in a case in which the width W_{b} of the power supply unit 40 is 0.2 mm or more, current flowing through the power supply unit 40 only flows through a partial region of the power supply unit 40 on an outer face side thereof, due to the skin effect, which will be described later. On the other hand, first notch portions 45 are formed in the power supply unit 40 in the present embodiment, which will be described later. Accordingly, a region over which current flows in the power supply unit 40 can be broadened even in a case in which the width W_{b} of the power supply unit 40 is 0.2 mm or more. Accordingly, the current flowing through the power supply unit 40 can be dispersed. As a result, deterioration of the power supply unit 40 can be suppressed. The width W_{b} of this power supply unit 40 can be selected from a range of 0.2 mm or more and 100 mm or less, for example.

Also, the power supply unit 40 is disposed at a longitudinal-direction end portion (Y-direction minus-side end portion) of the substrate 11. Metal materials such as, for example, gold, silver, copper, platinum, tin, aluminum, iron, or nickel, or the like, or alloys including these metals, can be used as the material of the power supply unit 40.

When the wiring board 10 is assembled into the image display device 60 (see FIG. 1 and FIG. 2), this power supply unit 40 is electrically connected to the communication module 63 of the image display device 60 via the power supply line 85. Note that the power supply unit 40 is provided on the first face 11a of the substrate 11, but this is not restrictive, and part or all of the power supply unit 40 may be situated on an outer side from the peripheral edge of the substrate 11. Also, the power supply unit 40 may be configured to be flexible, so as to wrap the power supply unit 40 around to a side face or a rear face of the image display device 60. In this case, the power supply unit 40 may be capable of being electrically connected to the communication module 63 at the side face or the rear face side of the image display device 60.

As illustrated in FIG. 4, the plurality of first-direction wiring lines 21 are electrically connected to a Y-direction plus side of the power supply unit 40. In this case, the power supply unit 40 is integrally formed with the mesh wiring portion 20. A thickness T₅ of the power supply unit 40 (Z-direction distance, see FIG. 6) can be the same as the height H₁ of the first-direction wiring lines 21 (see FIG. 5) and the height H₂ of the second-direction wiring lines 22 (see FIG. 6), and can be selected from a range of, for example, 0.1 μm or more and 5.0 μm or less.

Now, a plurality of the first notch portions 45 that extend linearly are formed in the power supply unit 40. These first notch portions 45 serve a role to draw away resin material of a later-described anisotropic conductive film 85c of the power supply line 85 from between the power supply line 85 and the power supply unit 40 when attaching the power supply line 85 to the power supply unit 40. The first notch portions 45 also serve a role to draw away air that has entered between the power supply line 85 and the power supply unit 40, from between the power supply line 85 and the power supply unit 40 when attaching the power supply line 85 to the power supply unit 40. That is to say, by forming the first notch portions 45 in the power supply unit 40, the resin material of the anisotropic conductive film 85c, and the air that has entered between the power supply line 85 and the power supply unit 40, flow along the first notch portions 45 when pressure-bonding the power supply line 85 to the power supply unit 40. Accordingly, when attaching the power supply line 85 to the power supply unit 40, so-called bubble inclusion, in which air that enters between the resin material of the anisotropic conductive film 85c and the power supply unit 40, can be suppressed, and also adhesion of the power supply line 85 and the power supply unit 40 can be improved.

Also, part of the resin material of the power supply line 85 enters into the first notch portions 45 at the time of attaching the power supply line 85 to the power supply unit 40. Further, part of the resin material that has entered into the first notch portions 45 hardens within the first notch portions 45. The resin material that has hardened within the first notch portions 45 then serves a role as an anchor. Accordingly, the power supply line 85 firmly adheres to the power supply unit 40, and the power supply line 85 can be kept from peeling away from the power supply unit 40.

Also, deterioration of the power supply unit 40 can be suppressed by forming the first notch portions 45 in the power supply unit 40. That is to say, forming the first notch portions 45 in the power supply unit 40 makes the region where the current flows in the power supply unit 40 to be broader, due to the skin effect that will be described later. Accordingly, the current flowing through the power supply unit 40 can be dispersed. As a result, deterioration of the power supply unit 40 can be suppressed.

Generally, when an alternating current is made to flow through a conductor, the higher the frequency is, the more difficult it is for current to flow at the center portion of the conductor, and more the current flows on the outer face of the conductor. Such a phenomenon in which the current flows only on the outer face thereof, when an alternating current is made to flow through a conductor, is referred to as the skin effect. Also, a skin depth is a depth from the outer face of the conductor where current flowing through the conductor deteriorates to 1/e (approximately 0.37) times the current on the outer face of the conductor, where the current flows most readily. This skin depth δ can generally be found by the following Expression.

$$δ = \sqrt{\frac{2}{ωμσ}} \qquad [ Math 1 ]$$

Note that in the above Expression, ω represents angular frequency (=2πf), μ represents permeability (4π×10⁻⁷ [H/m] in a vacuum), and σ represents conductivity of the conductor (5.8×10⁷ [S/m] in the case of copper). In a case of frequency of 0.8 GHz, the skin depth δ of a copper conductor is such that δ=approximately 2.3 μm, in a case of frequency of 2.4 GHZ, δ=approximately 1.3 μm, in a case of frequency of 4.4 GHZ, δ=approximately 1.0 μm, and in a case of frequency of 6 GHZ, δ=approximately 0.85 μm. Also, radio waves (millimeter waves) that an antenna for 5G transmits/receives is higher frequency (28 GHz or higher and 39 GHz or lower) as compared to radio waves that an antenna for 4G transmits/receives, for example. In a case in which the frequency of the current is 28 GHz or higher and 39 GHz or lower, for example, δ=approximately 0.3 μm or more and approximately 0.4 μm or less.

In this way, the current flows between the outer face of the conductor and a depth equivalent to the skin depth δ therefrom. Accordingly, in a case in which the radio waves that the mesh wiring portion 20 transmits/receives in particular are radio frequency waves (e.g., 28 GHz or higher and 39 GHz or lower), the skin depth δ is smaller, and accordingly the outer face of the power supply unit 40 is preferably smooth. On the other hand, the power supply line 85 is connected to the power supply unit 40. Accordingly, improved adhesion force between the power supply unit 40 and the power supply line 85 is desirable. As described above, according to the present embodiment, the plurality of first notch portions 45 are formed in the power supply unit 40. Accordingly, the adhesion force between the power supply unit 40 and the power supply line 85 can be improved even in a case in which the outer face of the power supply unit 40 is made smooth.

Next, the first notch portions 45 will be described in detail. As illustrated in FIG. 3 and FIG. 4, seven first notch portions 45 are formed in the power supply unit 40 in the example that is illustrated. The first notch portions 45 pass through the power supply unit 40 in the thickness direction (Z direction), and the substrate 11 that has transparency is exposed through each of the first notch portions 45. Note that the number of first notch portions 45 formed in the power supply unit 40 is not limited thereto. For example, two or more and six or less first notch portions 45 may be formed in the power supply unit 40, or eight or more thereof may be formed.

The plurality of first notch portions 45 may extend along the longitudinal direction of the mesh wiring portion 20 (Y direction). In this case, the first notch portions 45 extend along the direction in which the current flows. Accordingly, the current flowing through the power supply unit 40 can be effectively dispersed. In this case, each of the first notch portions 45 may extend in a straight line. A length L₆ (see FIG. 4) of the first notch portions 45 the longitudinal direction of the mesh wiring portion 20 (Y direction) may be in a range of 0.5 mm or more and 99.9 mm or less, for example.

Also, a width W₆ (see FIG. 4) of the first notch portions 45 in the lateral direction of the mesh wiring portion 20 (X direction) is preferably 0.5 times or more and 1 times or less an average particle size of later-described conductive particles 85d of the power supply line 85. Accordingly, when the resin material of the anisotropic conductive film 85c, which will be described later, flows at the time of connecting the power supply line 85 to the power supply unit 40, the conductive particles 85d of the anisotropic conductive film 85c interfere with the first notch portions 45. Thus, the first notch portions 45 can suppress movement of the conductive particles 85d of the anisotropic conductive film 85c. The width W₆ of the first notch portions 45 can be in a range of 0.01 mm or more and 0.5 mm or less, for example.

The plurality of first notch portions 45 extend from the second end portion 42 along a direction from the second end portion 42 toward the first end portion 41 (longitudinal direction of mesh wiring portion 20 (Y direction)). Accordingly, when pressure-bonding the power supply line 85 to the power supply unit 40, the resin material of the anisotropic conductive film 85c, and the air that has entered between the power supply line 85 and the power supply unit 40, can be more readily drawn away from between the power supply line 85 and the power supply unit 40, via the second end portion 42. Also, forming the first notch portions 45 causes radio-frequency current such as millimeter waves or the like, in particular, to flow on both sides of the first notch portions 45 (both sides in the X direction) due to the skin effect. Accordingly, the current flowing through the power supply unit 40 can be dispersed as compared to a case in which no first notch portions 45 are formed. Accordingly, deterioration of edge portions of the power supply unit 40 can be suppressed. In the illustrated example, the first notch portions 45 are not formed on the entire region of the power supply unit 40 in the Y direction, but rather only in a partial region of the power supply unit 40 in the Y direction. Accordingly, the first notch portions 45 end partway along the power supply unit 40. Note that the first notch portions 45 may each be formed over the entire region of the power supply unit 40 in the Y direction.

The first notch portions 45 may be formed equidistantly from each other. A pitch P₃ of the first notch portions 45 can be in a range of 0.01 mm or more and 0.5 mm or less, for example. Thus, irregularity in current distribution in the power supply unit 40 can be suppressed due to the plurality of first notch portions 45 being formed equidistantly from each other.

Note that the first notch portions 45 may extend along the width direction of the mesh wiring portion 20 (X direction). Also, the first notch portions 45 may extend along a direction that is not parallel to either the X direction or the Y direction. Also, the first notch portions 45 may extend in a crooked line shape, or may extend in a curved line shape, or may extend in a wavy line shape. Also, the first notch portions 45 may extend in different directions from each other. In particular, the first notch portions 45 may extend radially from the center of the power supply unit 40. Accordingly, fluidity of the resin material of the anisotropic conductive film 85c that will be described later can be improved at the time of connecting the power supply line 85 to the power supply unit 40.

Also, the width W₆ may change in the first notch portions 45. In particular, the width W₆ of the first notch portions 45 may become broader from the center of the power supply unit 40 toward the outer side thereof. Making the width W₆ to be broader from the center of the power supply unit 40 toward the outer side thereof can further improve the fluidity of the resin material of the anisotropic conductive film 85c that will be described later at the time of connecting the power supply line 85 to the power supply unit 40.

The first notch portions 45 may have the same shape as each other, or may have different shapes from each other. For example, the width W₆ of each of the first notch portions 45 may be different from each other.

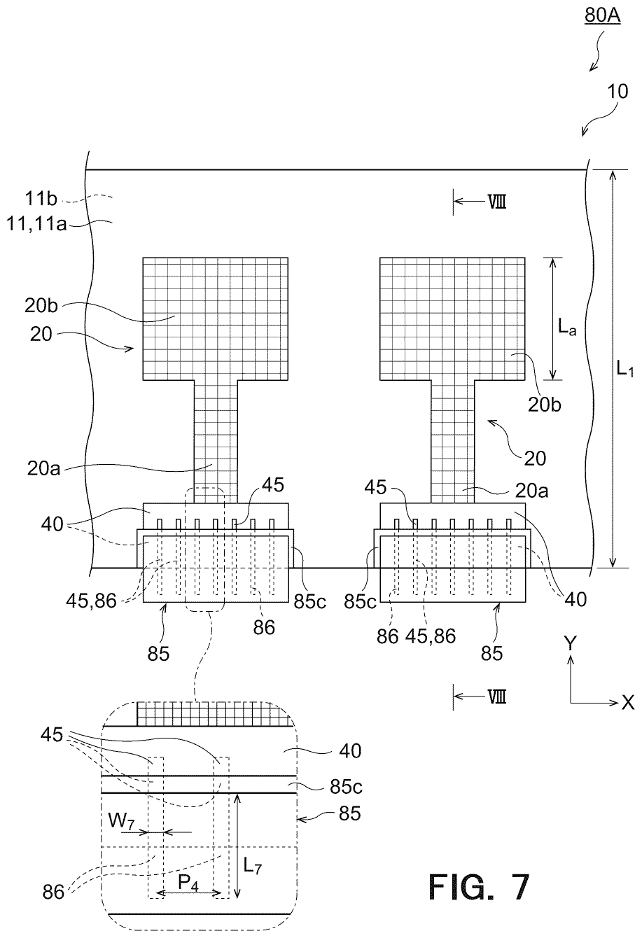

Next, the configuration of the module will be described with reference to FIG. 7 to FIG. 9. FIG. 7 to FIG. 9 are diagrams illustrating the module according to the present embodiment.

As illustrated in FIG. 7, the module 80A includes the wiring board 10 that is described above, and the power supply lines 85 that are electrically connected to the power supply units 40 via the anisotropic conductive film 85c. As described above, when the module 80A is assembled into the image display device 60 that has the display device 61, the power supply units 40 of the wiring board 10 are electrically connected to the communication module 63 of the image display device 60 via the power supply lines 85.

The power supply line 85 has a substantially rectangular shape in plan view. In this case, the width of the power supply line 85 (X-direction distance) may be substantially the same as the width of the power supply unit 40 (X-direction distance). Also, the area of the power supply line 85 may be substantially the same as the area of the power supply unit 40. Accordingly, electrical resistance of the power supply line 85 and electrical resistance of the power supply unit 40 can be brought close to each other. Accordingly, impedance matching between the power supply line 85 and the power supply unit 40 can be facilitated, and deterioration of electrical connectivity between the power supply line 85 and the power supply unit 40 can be suppressed.

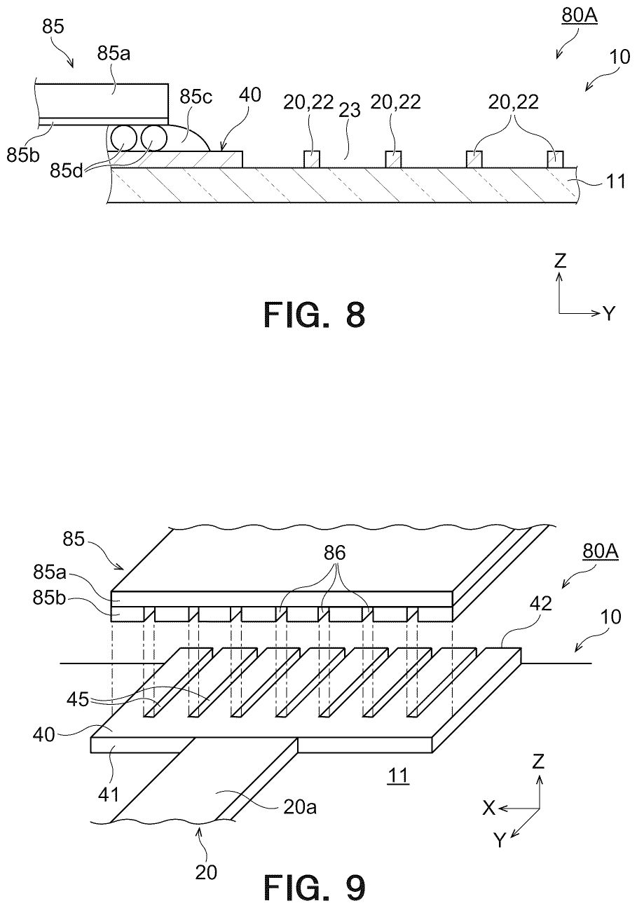

The power supply line 85 is pressure-bonded to the wiring board 10 with the anisotropic conductive film (ACF) 85c interposed therebetween. As illustrated in FIG. 8, the anisotropic conductive film 85c includes a resin material such as acrylic resin, epoxy resin, or the like, and the conductive particles 85d. In the example that is illustrated, the anisotropic conductive film 85c covers part of the power supply unit 40. Thus, corrosion and the like of the power supply unit 40 can be suppressed.

The anisotropic conductive film 85c is disposed so as to face the power supply unit 40. Some of the conductive particles 85d are in contact with the power supply unit 40. Accordingly, the power supply line 85 is electrically connected to the power supply unit 40. Note that part of the anisotropic conductive film 85c may dissolve out to the surroundings of the power supply line 85 when pressure-bonding the power supply line 85 to the wiring board 10. Also, the particle size of the conductive particles 85d may be 3 μm or more and 10 μm or less, and may be around 7 μm, for example. In a case of measuring the average particle size of the conductive particles 85d, first, the power supply line 85 is peeled away from the power supply unit 40, thereby exposing a plurality of the conductive particles 85d from the resin material of the anisotropic conductive film 85c. Next, the plurality of conductive particles 85d that are exposed are photographed using a scanning electron microscope (SEM). Subsequently, the particle sizes of the plurality of conductive particles 85d are measured from the image that is obtained. An average value of measured values is then taken as the average particle size of the conductive particles 85d. The number of the conductive particles 85d to be measured is 10 or more and 100 or less. Note that in a case in which the number of conductive particles 85d that can be measured in one power supply line 85 is nine or less, the average particle size of the conductive particles 85d is calculated using particle sizes of the conductive particles 85d of another power supply line 85. Also, in a case in which the conductive particles 85d are not exposed from the resin material of the anisotropic conductive film 85c, the shapes of the conductive particles 85d in the resin material of the anisotropic conductive film 85c are photographed using the scanning electron microscope.

The power supply line 85 may be a flexible printed board, for example. As illustrated in FIG. 8, the power supply line 85 includes a base material 85a, and a metal wiring portion 85b that is laminated on the base material 85a. Of these, the base material 85a may contain a resin material such as polyimide or the like, or a liquid-crystal polymer.

The metal wiring portion 85b may include copper, for example. This metal wiring portion 85b is electrically connected to the power supply unit 40 via the conductive particles 85d.

As illustrated in FIG. 9, a plurality of third notch portions 86 that extend linearly may be formed in the metal wiring portion 85b. Accordingly, the region where the current flows in the metal wiring portion 85b is broadened by the skin effect. Thus, the current flowing through the metal wiring portion 85b can be dispersed. As a result, deterioration of the metal wiring portion 85b can be suppressed. Note that illustration of the anisotropic conductive film 85c is omitted from FIG. 9, to clarify the drawing.

Also, a width W₇ (see FIG. 7) of the third notch portions 86 may be the width W₆ of the first notch portions 45 or less, and in plan view, the third notch portions 86 may extend along the first notch portions 45, and may overlap the first notch portions 45. Accordingly, even in a case in which the resin material of the anisotropic conductive film 85c flows when connecting the power supply line 85 to the power supply unit 40, the conductive particles 85d of the anisotropic conductive film 85c interfere with the first notch portions 45 and the third notch portions 86. Accordingly, the first notch portions 45 and the third notch portions 86 can suppress movement of the conductive particles 85d of the anisotropic conductive film 85c. The width W₇ of the third notch portions 86 may be in a range of 0.002 mm or more and 2 mm or less, for example.

In this case, seven third notch portions 86 are formed in the metal wiring portion 85b, as illustrated in FIG. 9. The third notch portions 86 pass through the metal wiring portion 85b in the thickness direction (Z direction), and the base material 85a is exposed through each of the third notch portions 86. Note that the number of third notch portions 86 formed in the metal wiring portion 85b is not limited thereto. For example, two or more and six or less third notch portions 86 may be formed in the metal wiring portion 85b, or eight or more thereof may be formed.

The plurality of third notch portions 86 may extend along the longitudinal direction of the mesh wiring portion 20 (Y direction). In this case, the third notch portions 86 extend along the direction in which the current flows. Accordingly, the current flowing through the metal wiring portion 85b can be effectively dispersed.

The third notch portions 86 may extend from, out of end portions of the metal wiring portion 85b, an end portion on a Y-direction plus side. In the illustrated example, the third notch portions 86 are not formed on the entire region of the metal wiring portion 85b, but rather only in a partial region of the metal wiring portion 85b in the Y direction, as illustrated in FIG. 7. Accordingly, the third notch portions 86 end partway along the metal wiring portion 85b. Note that the third notch portions 86 may each be formed over the entire region of the metal wiring portion 85b in the Y direction. Also, a length L₇, a pitch P₄, and the shape and so forth, of the third notch portions 86, may be the same as the length L₆, the pitch P₃, and the shape and so forth, of the first notch portions 45. That is to say, the third notch portions 86 may extend along the width direction of the mesh wiring portion 20 (X direction). Also, the third notch portions 86 may extend along a direction that is not parallel to either the X direction or the Y direction. Also, the third notch portions 86 may extend in a crooked line shape, or may extend in a curved line shape, or may extend in a wavy line shape. Also, the third notch portions 86 may extend in different directions from each other. In particular, the third notch portions 86 may be formed in the metal wiring portion 85b so as to extend radially from the center of the power supply unit 40 when the power supply line 85 is pressure-bonded to the power supply unit 40. Thus, the fluidity of the resin material of the anisotropic conductive film 85c can be improved at the time of connecting the power supply line 85 to the power supply unit 40.

Also, the width W₇ may change in the third notch portion 86. In particular, the third notch portion 86 may be formed on the metal wiring portion 85b such that the width W₇ of the third notch portions 86 become broader from the center of the power supply unit 40 toward the outer side thereof when the power supply line 85 is pressure-bonded to the power supply unit 40. Due to the width W₇ becoming broader from the center of the power supply unit 40 toward the outer side thereof, the fluidity of the resin material of the anisotropic conductive film 85c can be further improved at the time of connecting the power supply line 85 to the power supply unit 40.

The third notch portions 86 may have the same shape as each other, or may have different shapes from each other. For example, the width W₇ of each of the third notch portions 86 may be different from each other.

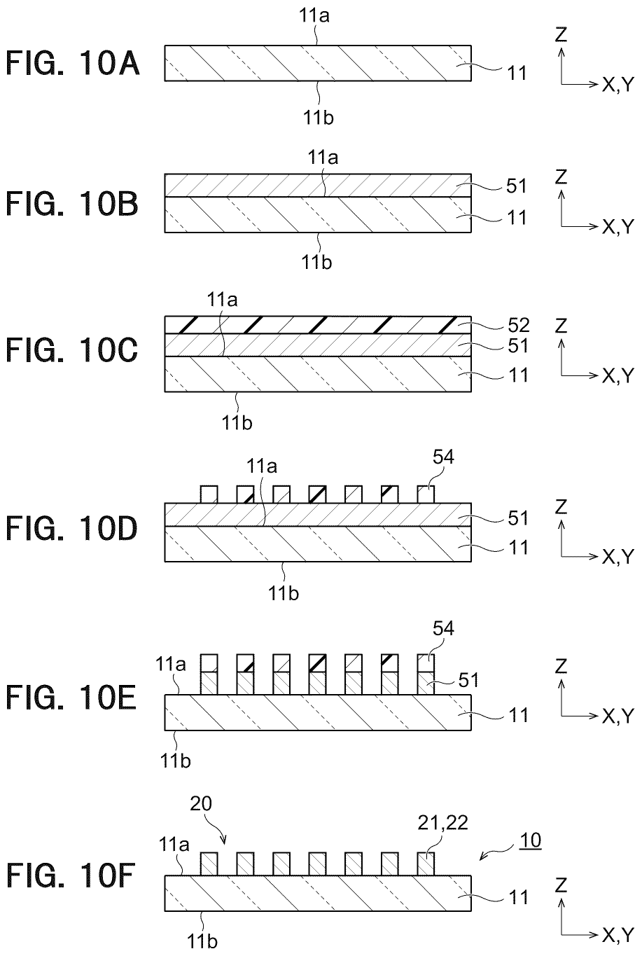

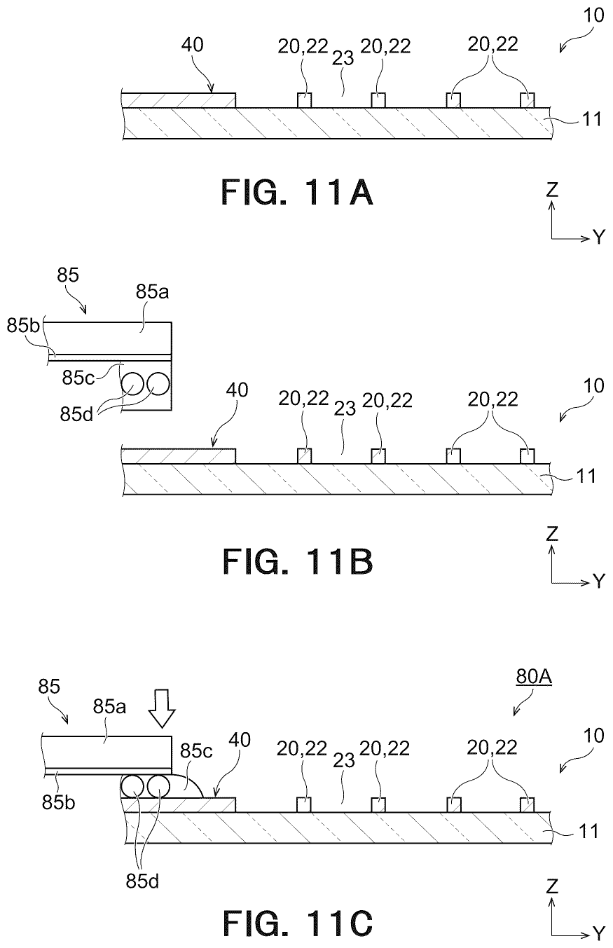

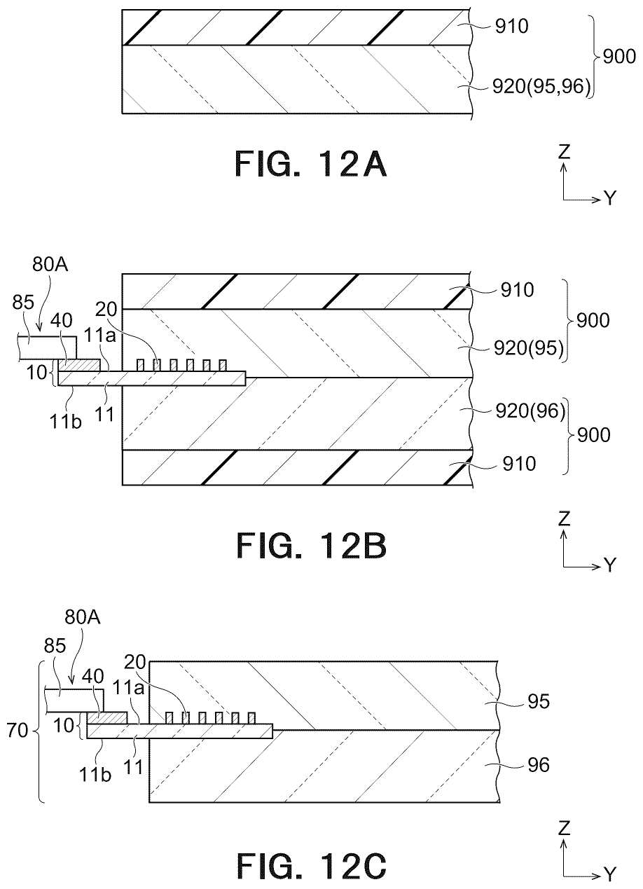

Next, a manufacturing method of the wiring board 10, a manufacturing method of the module 80A, and a manufacturing method of the image display device 60, according to the present embodiment, will be described with reference to FIG. 10A through FIG. 12C. FIG. 10A to FIG. 10F are cross-sectional views illustrating the manufacturing method of the wiring board 10 according to the present embodiment. FIG. 11A to FIG. 11C are cross-sectional views illustrating the manufacturing method of the module 80A according to the present embodiment. FIG. 12A to FIG. 12C are cross-sectional views illustrating the manufacturing method of the image display device 60 according to the present embodiment.

First, as illustrated in FIG. 10A, the substrate 11 that has the first face 11a and the second face 11b that is situated on the opposite side from the first face 11a is prepared. The substrate 11 has transparency.

Next, the mesh wiring portion 20, and the power supply unit 40 electrically connected to the mesh wiring portion 20, are formed on the first face 11a of the substrate 11.

At this time, first, a metal foil 51 is laminated on substantially the entire region of the first face 11a of the substrate 11, as illustrated in FIG. 10B. The thickness of the metal foil 51 according to the present embodiment may be 0.1 μm or more and 5.0 μm or less. The metal foil 51 according to the present embodiment may contain copper.

Next, as illustrated in FIG. 10C, a photo-curing insulating resist 52 is supplied to substantially the entire region of the surface of the metal foil 51. Examples of this photo-curing insulating resist 52 include organic resins such as acrylic resin, epoxy-based resin, and so forth.

Next, as illustrated in FIG. 10D, an insulating layer 54 is formed by photolithography. In this case, the photo-curing insulating resist 52 is patterned by photolithography, thereby forming the insulating layer 54 (resist pattern). At this time, the insulating layer 54 is formed such that the metal foil 51 corresponding to the first-direction wiring lines 21 and the second-direction wiring lines 22 is exposed.

Next, as illustrated in FIG. 10E, the metal foil 51 situated at portions on the first face 11a of the substrate 11 not covered by the insulating layer 54 is removed. At this time, the metal foil 51 is etched such that the first face 11a of the substrate 11 is exposed, by performing wet processing using such as ferric chloride, cupric chloride, strong acids such as sulfuric acid, hydrochloric acid, or the like, persulfate, hydrogen peroxide, or aqueous solutions thereof, or combinations of the above, or the like.

Next, as illustrated in FIG. 10F, the insulating layer 54 is removed. At this time, the insulating layer 54 on the metal foil 51 is removed by performing wet processing using a permanganate solution, N-methyl-2-pyrrolidone, acid or alkali solutions, or the like, or dry processing using oxygen plasma.

Thus, the wiring board 10 that has the substrate 11, and the mesh wiring portion 20 provided on the first face 11a of the substrate 11, is obtained. In this case, the mesh wiring portion 20 includes the first-direction wiring lines 21 and the second-direction wiring lines 22. The power supply unit 40 may be formed by part of the metal foil at this time. In this case, appropriately setting the shape of the insulating layer 54 at the time of forming the insulating layer 54 by photolithography enables the first notch portions 45 to be formed at desired positions. Alternatively, the power supply unit 40 that is plate-like may be separately prepared, and this power supply unit 40 may be electrically connected to the mesh wiring portion 20. In this case, the first notch portions 45 may be formed by machining, such as cutting or the like, for example.

Next, the manufacturing method of the module according to the present embodiment will be described with reference to FIG. 11A to FIG. 11C.

First, as illustrated in FIG. 11A, the wiring board 10 is prepared. At this time, the wiring board 10 is fabricated by the method illustrated in FIG. 10A to FIG. 10F, for example.

Next, the power supply line 85 is electrically connected to the power supply unit 40 via the anisotropic conductive film 85c containing the conductive particles 85d. At this time, first, the anisotropic conductive film 85c is positioned above the wiring board 10, as illustrated in FIG. 11B. At this time, the anisotropic conductive film 85c is positioned facing the power supply unit 40.

Next, as illustrated in FIG. 11C, the power supply line 85 is pressure-bonded to the wiring board 10. At this time, the power supply line 85 is pressure-bonded to the wiring board 10 by applying pressure and heat to the power supply line 85. Some of the conductive particles 85d thus come into contact with the power supply unit 40. In this way, the power supply line 85 is electrically connected to the power supply unit 40. At the time of pressure-bonding the power supply line 85 to the wiring board 10, the power supply line 85 is pressure-bonded to the wiring board 10 such that the anisotropic conductive film 85c covers at least part of the power supply unit 40. At this time, part of the anisotropic conductive film 85c may dissolve out to the surroundings of the power supply line 85.

Also, in the present embodiment, the plurality of first notch portions 45 that extend linearly are formed in the power supply unit 40. Accordingly, when pressure-bonding the power supply line 85 to the power supply unit 40, the resin material of the anisotropic conductive film 85c, and air that has entered between the power supply line 85 and the power supply unit 40, are drawn away from between the power supply line 85 and the power supply unit 40 along the first notch portions 45.

Also, at the time of attaching the power supply line 85 to the power supply unit 40, part of the resin material of the power supply line 85 enters into the first notch portions 45. Further, part of the resin material that has entered into the first notch portions 45 hardens within the first notch portions 45. Accordingly, the power supply line 85 is firmly adhered to the power supply unit 40.

In this way, the module 80A that includes the wiring board 10, and the power supply line 85 that is electrically connected to the power supply unit 40 via the anisotropic conductive film 85c containing the conductive particles 85d, is obtained.

Next, the manufacturing method of the image display device 60 according to the present embodiment will be described with reference to FIG. 12A to FIG. 12C.

Next, the first transparent adhesive layer 95, the wiring board 10 of the module 80A, and the second transparent adhesive layer 96 are laminated on each other. At this time, first, as illustrated in FIG. 12A, an OCA sheet 900 is prepared that includes, for example, a release film 910 made of polyethylene terephthalate (PET), and an OCA layer 920 (first transparent adhesive layer 95 or second transparent adhesive layer 96) laminated on the release film 910. At this time, the OCA layer 920 may be a layer obtained by coating a curable adhesive layer composition that is in a liquid state and that includes a polymerizable compound, on the releasing film 910, and cured by using ultraviolet rays (UV) or the like, for example. This curable adhesive layer composition contains a polar-group-containing monomer.

Next, as illustrated in FIG. 12B, the OCA layers 920 of the OCA sheets 900 are applied to the wiring board 10. Thus, the wiring board 10 is interposed between the OCA layers 920.

Thereafter, as illustrated in FIG. 12C, the release films 910 are removed by separation from the OCA layers 920 of the OCA sheets 900 applied to the wiring board 10, thereby obtaining the first transparent adhesive layer 95 (OCA layer 920), the wiring board 10, and the second transparent adhesive layer 96 (OCA layer 920), which are laminated on each other.

Thus, the image display device laminate 70, including the module 80A that includes the first transparent adhesive layer 95, the second transparent adhesive layer 96, and the wiring board 10, is obtained.

Thereafter, the display device 61 is laminated on the image display device laminate 70, thereby obtaining the image display device 60 including the module 80A and the display device 61 laminated on the wiring board 10 of the module 80A.

Next, the effects of the present embodiment having such a configuration will be described.

As illustrated in FIG. 1 and FIG. 2, the wiring board 10 is assembled into the image display device 60 that has the display device 61. At this time, the wiring board 10 is disposed above the display device 61. The mesh wiring portion 20 of the wiring board 10 is electrically connected to the communication module 63 of the image display device 60 via the power supply unit 40 and the power supply line 85. In this way, radio waves of the predetermined frequency can be transmitted/received via the mesh wiring portion 20, and communication can be performed by using the image display device 60.

In the present embodiment, the plurality of first notch portions 45 extending linearly are formed in the power supply unit 40. Accordingly, adhesion of the power supply line 85 and the power supply unit 40 can be improved.

Now, the power supply unit 40 that is made of metal and the resin material of the power supply line 85 are different materials, and accordingly adhesion force therebetween is not necessarily strong. Accordingly, in a case in which notch portions such as the first notch portions 45 are not formed in the power supply unit 40 and the surface of the power supply unit 40 is smooth, for example, adhesion of the power supply line 85 and the power supply unit 40 can deteriorate.

In order to deal with this, there are cases in which a plurality of through holes that pass through the power supply unit 40 in the thickness direction (Z direction) are formed in the power supply unit 40, to improve adhesion of the power supply line 85 and the power supply unit 40. In this case, part of the resin material of the anisotropic conductive film can be made to enter into the through holes. Accordingly, part of the resin material entering into the through holes serves as an anchor to strongly join the power supply line 85 to the power supply unit 40. On the other hand, in a case in which the plurality of through holes are formed in the power supply unit 40, there is a possibility that drawing away air that has entered between the power supply unit 40 and the power supply line 85, and resin material of the anisotropic conductive film, from between the power supply unit 40 and the power supply line 85 will be difficult.

Conversely, according to the present embodiment, the plurality of first notch portions 45 extending linearly are formed in the power supply unit 40. Accordingly, at the time of pressure-bonding the power supply line 85 to the power supply unit 40, resin material of the anisotropic conductive film 85c, and air that has entered between the power supply line 85 and the power supply unit 40, flow along the first notch portions 45. Thus, the resin material of the anisotropic conductive film 85c and the air that has entered between the power supply line 85 and the power supply unit 40 can be drawn away from between the power supply line 85 and the power supply unit 40. As a result, when attaching the power supply line 85 to the power supply unit 40, so-called bubble inclusion, in which air that enters between the resin material of the anisotropic conductive film 85c and the power supply unit 40, can be suppressed, and also adhesion of the power supply line 85 and the power supply unit 40 can be improved.

Also, when attaching the power supply line 85 to the power supply unit 40, part of the resin material of the power supply line 85 enters into the first notch portions 45. Further, part of the resin material that has entered into the first notch portion 45 hardens within the first notch portions 45. The resin material that has hardened in the first notch portion 45 serves a role as an anchor. Accordingly, the power supply line 85 firmly adheres to the power supply unit 40, and the power supply line 85 can be kept from peeling away from the power supply unit 40.

Also, deterioration of the power supply unit 40 can be suppressed by forming the first notch portions 45 in the power supply unit 40. That is to say, forming the first notch portions 45 in the power supply unit 40 broadens the region where the current flows in the power supply unit 40, due to the skin effect. Accordingly, the current flowing through the power supply unit 40 can be dispersed, and deterioration of the power supply unit 40 can be suppressed.

Also, the wiring board 10 has the substrate 11 and the mesh wiring portion 20 disposed on the substrate 11. Also, the substrate 11 has transparency. Further, the mesh wiring portion 20 has a mesh-like pattern made up of a conductor portion serving as a formation portion of a non-transparent conductor layer, and a great number of openings 23. Accordingly, transparency of the wiring board 10 is secured. Hence, when the wiring board 10 is disposed above the display device 61, the display device 61 can be visually recognized from the openings 23 of the mesh wiring portion 20, and visibility of the display device 61 is not impeded.

Also, according to the present embodiment, the plurality of first notch portions 45 extend along the longitudinal direction of the mesh wiring portion 20. In this case, the first notch portions 45 extend along the direction in which the current flows. Accordingly, the current flowing through the power supply unit 40 can be effectively dispersed.

Also, according to the present embodiment, the power supply unit 40 has the first end portion 41 that comes into contact with the mesh wiring portion 20, and the second end portion 42 on the opposite side from the first end portion 41. Also, the plurality of first notch portions 45 extend from the second end portion 42 along the direction from the second end portion 42 toward the first end portion 41 (longitudinal direction of the mesh wiring portion 20). Accordingly, resin material of the anisotropic conductive film 85c, and the air that has entered between the power supply line 85 and the power supply unit 40, can be readily drawn away from between the power supply line 85 and the power supply unit 40 via the second end portion 42, at the time of pressure-bonding the power supply line 85 to the power supply unit 40. Also, the first notch portions 45 can be suppressed from having adverse effects on the flow of the current.

Further, according to the present embodiment, the plurality of third notch portions 86 that extend linearly are formed in the metal wiring portion 85b of the power supply line 85. Accordingly, the region over which the current flows in the metal wiring portion 85b is made to be broader. Thus, the current flowing through the metal wiring portion 85b can be dispersed. As a result, deterioration of the metal wiring portion 85b can be suppressed. Also, the third notch portions 86 extend along the first notch portions 45 and also overlap the first notch portions 45 in plan view. Accordingly, even in a case in which the resin material of the anisotropic conductive film 85c flows at the time of connecting the power supply line 85 to the power supply unit 40, the conductive particles 85d of the anisotropic conductive film 85c interfere with the first notch portions 45 and the third notch portions 86. Accordingly, the first notch portions 45 can suppress movement of the conductive particles 85d of the anisotropic conductive film 85c.

Next, modifications of the wiring board will be described.

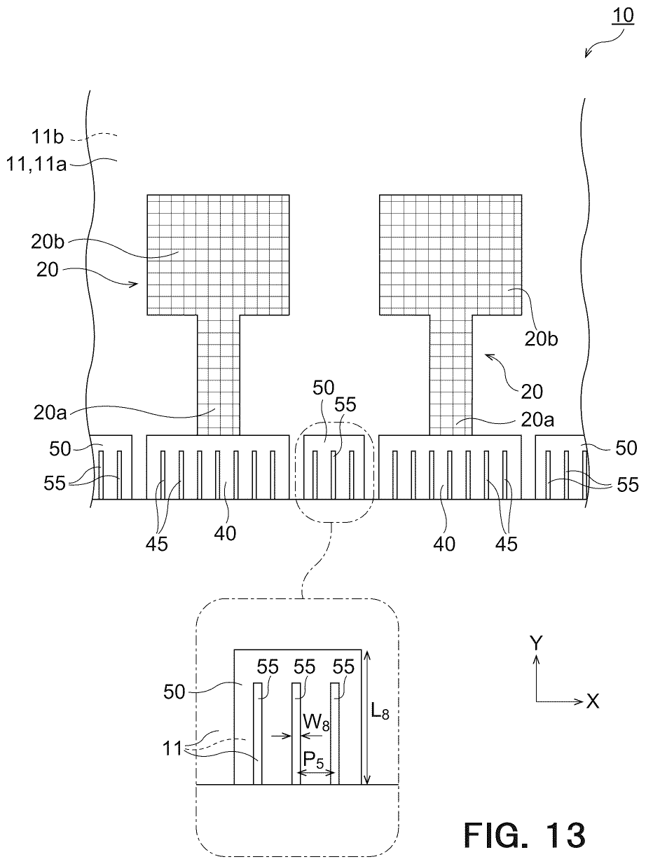

FIG. 13 illustrates a first modification of the wiring board. The modification illustrated in FIG. 13 differs with respect to the point of the wiring board 10 further having a ground portion 50, and other configurations are the substantially same as those in the form illustrated in the above-described FIG. 1 to FIG. 12C. Portions in FIG. 13 that are the same as those in the form illustrated in FIG. 1 to FIG. 12C are denoted by the same signs, and detailed description will be omitted.

In the wiring board 10 illustrated in FIG. 13, the wiring board 10 further has the ground portion (GND) 50 situated on the first face 11a of the substrate 11. In this case, a plurality of the ground portion 50 may be disposed on the first face 11a of the substrate 11 such that the mesh wiring portions 20 are interposed therebetween from both sides in the X direction.

The ground portion 50 is made up of a thin-plate-like material that is substantially rectangular and conductive, for example. The longitudinal direction of the ground portion 50 may be parallel to the X direction, or may be parallel to the Y direction. In the example that is illustrated, the longitudinal direction of the ground portion 50 is parallel to the Y direction.

Also, the ground portion 50 is disposed at a longitudinal-direction end portion (Y-direction minus-side end portion) of the substrate 11. Metal materials such as gold, silver, copper, platinum, tin, aluminum, iron, or nickel or the like, or alloys including these metals, for example, can be used as the material of the ground portion 50. The ground portion 50 may be formed by the same method as that of the power supply unit 40.

Now, a plurality of second notch portions 55 that extend linearly are formed in the ground portion 50. Accordingly, the region where the current flows can be mad to be broader in the ground portion 50, due to the skin effect. Accordingly, the current flowing through the ground portion 50 can be disposed. As a result, deterioration of the ground portion 50 can be suppressed.

As illustrated in FIG. 13, in the example that is illustrated, three each of the second notch portions 55 are formed in each ground portion 50. The first notch portions 45 pass through the ground portion 50 in the thickness direction (Z direction), and the substrate 11 that has transparency is exposed from the second notch portions 55. Note that the number of the second notch portions 55 formed in the ground portion 50 is not limited to this. For example, two of the second notch portions 55 may be formed in each ground portion 50, or four or more each may be formed.

The plurality of second notch portions 55 may extend along the longitudinal direction of the mesh wiring portion 20 (Y direction).

The second notch portions 55 may extend from, out of end portions of the ground portion 50, the Y-direction minus-side end portion. In the illustrated example, the second notch portions 55 are not formed on the entire region of the ground portion 50 in the Y direction, but rather only in a partial region of the ground portion 50 in the Y direction. Accordingly, the second notch portions 55 end partway along the ground portion 50. Note that the second notch portions 55 may each be formed over the entire region of the ground portion 50 in the Y direction. A length L₈, a width W₈, a pitch P₅, the shape, and so forth, of the second notch portions 55 may be the same as the length L₆, width W₆, pitch P₃, shape, and so forth, of the first notch portions 45. That is to say, the second notch portions 55 may extend along the width direction of the mesh wiring portion 20 (X direction). Also, the second notch portions 55 may extend along a direction that is not parallel to either the X direction or the Y direction. Also, the second notch portions 55 may extend in a crooked line shape, or may extend in a curved line shape, or may extend in a wavy line shape. Also, the second notch portions 55 may extend in different directions from each other.

Also, the width W₈ may change in the second notch portion 55. Further, the second notch portions 55 may have the same shape as each other, or may have different shapes from each other. For example, the width W₈ of each of the second notch portions 55 may be different from each other.

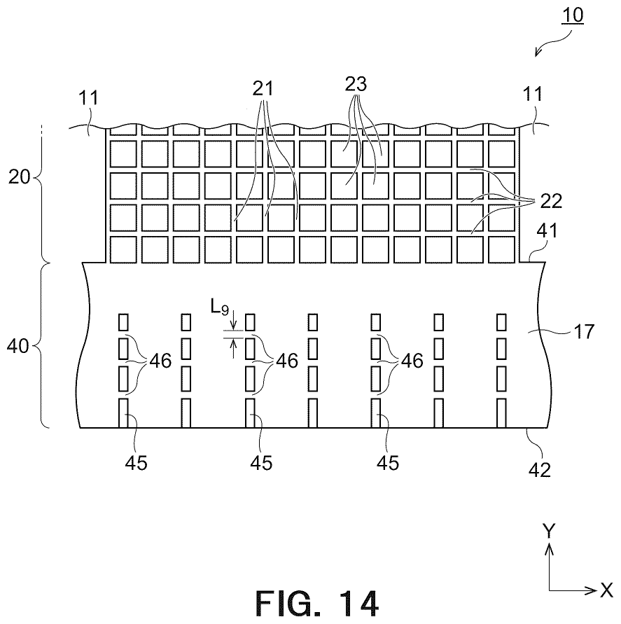

FIG. 14 illustrates a second modification of the wiring board. The modification illustrated in FIG. 14 differs with respect to the point of separating portions 46 that separate the first notch portions 45 being formed in the first notch portions 45, and other configurations are the substantially same as the form illustrated in the above-described FIG. 1 to FIG. 13. Portions in FIG. 14 that are the same as those in the form illustrated in FIG. 1 to FIG. 13 are denoted with the same signs, and detailed description will be omitted.

In the wiring board 10 illustrated in FIG. 14, the separating portions 46 that separate the first notch portions 45 are formed in the first notch portions 45. In this case, current flowing through the power supply unit 40 flows through the separating portions 46 as well. Accordingly, irregularity in current distribution in the power supply unit 40 can be suppressed. These separating portions 46 can be formed by setting the shape of the insulating layer 54 described above (see FIG. 10D) as appropriate, for example, when forming the first notch portions 45. The thickness of the separating portions 46 may be equal to the thickness T₅ (see FIG. 6) of the power supply unit 40.

Also, a length Ly of the separating portions 46 in the longitudinal direction of the mesh wiring portion 20 (Y direction) may be 0.5 μm or more and 100 μm or less, and as one example, may be 1 μm. Due to the length L₉ of the separating portions 46 being 100 μm or less, air that has entered into between the power supply unit 40 and the power supply line 85, and resin material of the anisotropic conductive film, can be readily drawn away from between the power supply unit 40 and the power supply line 85.

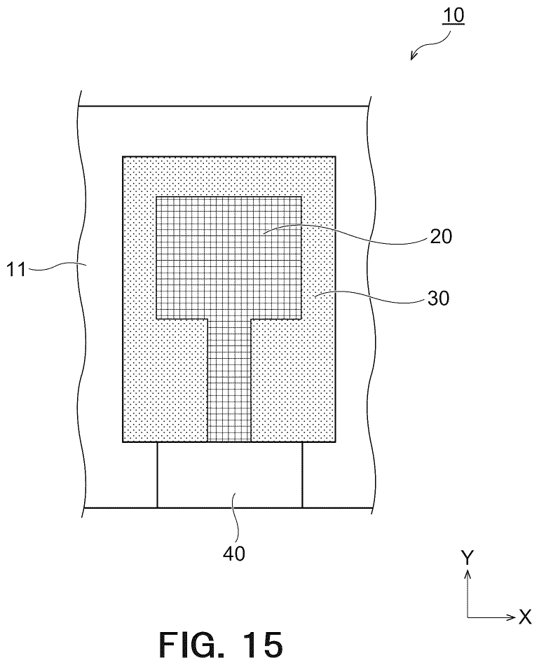

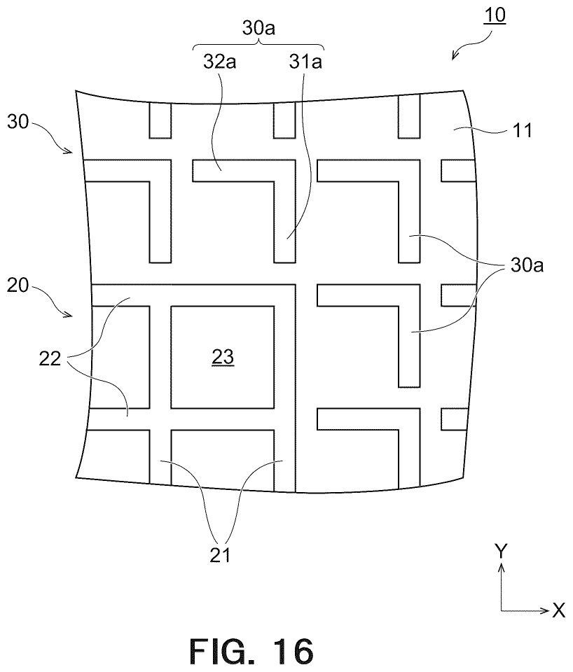

FIG. 15 and FIG. 16 illustrate a third modification of the wiring board. The modification illustrated in FIG. 15 and FIG. 16 differs with respect to the point of a dummy wiring portion 30 being provided around the mesh wiring portion 20, and other configurations are the substantially same as the form illustrated in the above-described FIG. 1 to FIG. 14. Portions in FIG. 15 and FIG. 16 that are the same as those in the form illustrated in FIG. 1 to FIG. 14 are denoted with the same signs, and detailed description will be omitted.

In the wiring board 10 illustrated in FIG. 15, the dummy wiring portion 30 is provided so as to follow around the mesh wiring portion 20. Unlike the mesh wiring portion 20, this dummy wiring portion 30 does not substantially function as an antenna.

As illustrated in FIG. 16, the dummy wiring portion 30 is made up of a repetition of the dummy wiring lines 30a having a predetermined pattern shape. That is to say, the dummy wiring portion 30 includes a plurality of the dummy wiring lines 30a, and each dummy wiring line 30a is electrically isolated from each of the mesh wiring portions 20 (first-direction wiring lines 21 and second-direction wiring lines 22). Also, the plurality of dummy wiring lines 30a are disposed with regularity over the entire region within the dummy wiring portion 30. The plurality of dummy wiring lines 30a are distanced from each other in a planar direction, and are also disposed so as to protrude on the substrate 11. That is to say, each dummy wiring line 30a is electrically isolated from the mesh wiring portion 20, the power supply unit 40, and other dummy wiring lines 30a. The shapes of the dummy wiring lines 30a are each substantially L-shaped in plan view.

In this case, the dummy wiring lines 30a have a shape in which part of the pattern shape of the mesh wiring portion 20 described above is missing. Thus, difference between the mesh wiring portion 20 and the dummy wiring portion 30 can be made to be less readily visually recognized, and the mesh wiring portion 20 disposed on the substrate 11 can be made to be difficult to see. As illustrated in FIG. 16, the dummy wiring lines 30a extend in parallel to the first-direction wiring lines 21 or the second-direction wiring lines 22. Specifically, the dummy wiring lines 30a include a first portion 31a that extends in parallel with the first-direction wiring lines 21, and a second portion 32a that extends in parallel with the second-direction wiring lines 22. In this way, due to the dummy wiring lines 30a extending in parallel to the first-direction wiring lines 21 or the second-direction wiring lines 22, the mesh wiring portions 20 disposed on the substrate 11 can be made to be further less readily visually recognized. An aperture ratio of the dummy wiring portion 30 may be the same as the aperture ratio of the mesh wiring portion 20, or may be different, but preferably is near the aperture ratio of the mesh wiring portion 20.

By providing the dummy wiring portion 30 that is electrically isolated from the mesh wiring portion 20 around the mesh wiring portion 20, as in the present modification, an outer edge of the mesh wiring portion 20 can be made obscure. Accordingly, the mesh wiring portion 20 can be made to be difficult to see on the front face of the image display device 60, and the mesh wiring portion 20 can be made to be less readily visually recognizable by the bare eye of the user of the image display device 60.

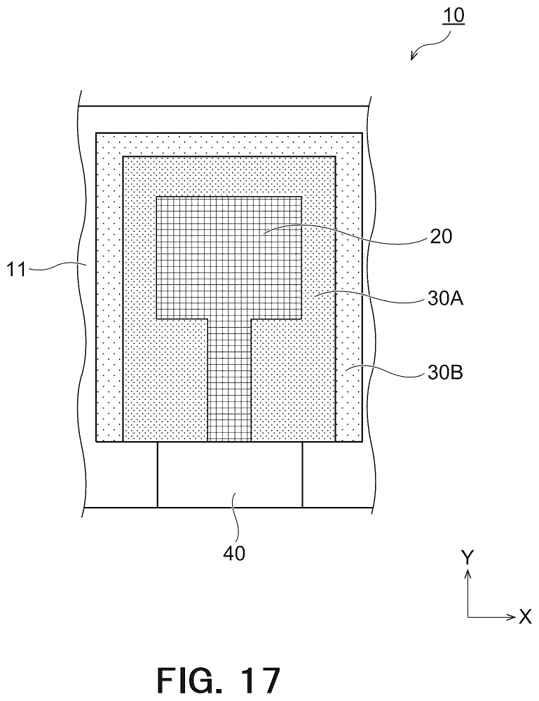

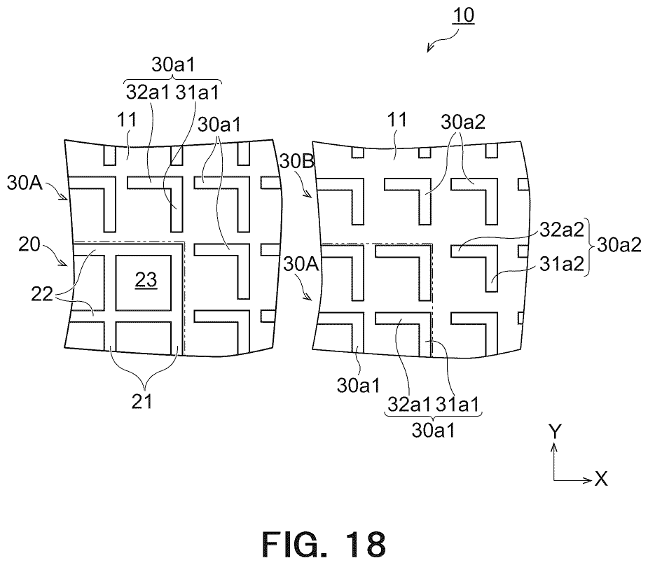

FIG. 17 and FIG. 18 illustrate a fourth modification of the wiring board. The modification illustrated in FIG. 17 and FIG. 18 differs with respect to the point that a plurality of dummy wiring portions 30A and 30B that have different aperture ratios from each other are provided around the mesh wiring portion 20, and other configurations are substantially the same as the forms illustrated in FIG. 1 to FIG. 16 described above. In FIG. 17 and FIG. 18, portions that are the same as in the forms illustrated in FIG. 1 to FIG. 16 are denoted by the same signs, and detailed description will be omitted.

In the wiring board 10 illustrated in FIG. 17, the plurality of (two in this case) of dummy wiring portions 30A and 30B (first dummy wiring portion 30A and second dummy wiring portion 30B) that have different aperture ratios from each other are provided so as to follow around the mesh wiring portion 20. Specifically, the first dummy wiring portion 30A is disposed so as to follow around the mesh wiring portion 20, and the second dummy wiring portion 30B is disposed so as to follow around the first dummy wiring portion 30A. Unlike the mesh wiring portion 20, these dummy wiring portions 30A and 30B do not substantially function as an antenna.

As illustrated in FIG. 18, the first dummy wiring portion 30A is made up of a repetition of dummy wiring lines 30a1 that have a predetermined pattern form. Also, the second dummy wiring portion 30B is made up of a repetition of dummy wiring lines 30a2 that have a predetermined pattern form. That is to say, the dummy wiring portions 30A and 30B include a plurality of the dummy wiring lines 30a1 and 30a2, respectively, and each of the dummy wiring lines 30a1 and 30a2 is electrically isolated from the mesh wiring portion 20. Also, each of the dummy wiring lines 30a1 and 30a2 is disposed with regularity over the entire region of the respective dummy wiring portions 30A and 30B. The dummy wiring lines 30a1 and 30a2 are each distanced from each other in the planar direction, and are also disposed so as to protrude on the substrate 11. The dummy wiring lines 30a1 and 30a2 are each electrically isolated from the mesh wiring portion 20, the power supply unit 40, and other dummy wiring lines 30a1 and 30a2. The shapes of the dummy wiring lines 30a1 and 30a2 are each substantially L-shaped in plan view.

In this case, the dummy wiring lines 30a1 and 30a2 have shapes in which part of the pattern shape of the mesh wiring portion 20 described above is missing. Thus, difference between the mesh wiring portion 20 and the first dummy wiring portion 30A, and difference between the first dummy wiring portion 30A and the second dummy wiring portion 30B can be made to be less readily visually recognized, and the mesh wiring portion 20 disposed on the substrate 11 can be made to be difficult to see. As illustrated in FIG. 18, the dummy wiring lines 30a1 and 30a2 extend in parallel with the first-direction wiring lines 21 or the second-direction wiring lines 22. Specifically, each dummy wiring line 30a1 includes a first portion 31a1 that extends in parallel with the first-direction wiring lines 21 and a second portion 32a1 that extends in parallel with the second-direction wiring lines 22. Each dummy wiring line 30a2 includes a first portion 31a2 that extends in parallel with the first-direction wiring lines 21 and a second portion 32a2 that extends in parallel with the second-direction wiring lines 22.

Note that the area of each dummy wiring line 30a1 of the first dummy wiring portion 30A is greater than the area of each dummy wiring line 30a2 of the second dummy wiring portion 30B. In this case, a line width of each dummy wiring line 30a1 is the same as a line width of each dummy wiring line 30a2, but this is not restrictive, and the line width of each dummy wiring line 30a1 may be wider than the line width of each dummy wiring line 30a2. Note that other configurations of the dummy wiring lines 30a1 and 30a2 are the same as the configurations of the dummy wiring lines 30a in the third modification, and accordingly detailed description will be omitted here.

In the present embodiment, the aperture ratio of the mesh wiring portion 20 and the plurality of dummy wiring portions 30A and 30B preferably increase stepwise from the mesh wiring portion 20 to the dummy wiring portions 30A and 30B far from the mesh wiring portion 20. In other words, the aperture ratio of the dummy wiring portions preferably gradually increases from those close to the mesh wiring portion 20 toward those far away. In this case, the aperture ratio of the first dummy wiring portions 30A is preferably larger than the aperture ratio of the mesh wiring portion 20. The aperture ratio of the second dummy wiring portions 30B is preferably larger than the aperture ratio of the first dummy wiring portions 30A. Thus, the outer edges of the mesh wiring portion 20 and the dummy wiring portions 30A and 30B can be made to be further obscure. Accordingly, the mesh wiring portion 20 on the surface of the image display device 60 can be made to be more difficult to see.

Thus, by disposing the dummy wiring portions 30A and 30B that are electrically isolated from the mesh wiring portion 20, the outer edge of the mesh wiring portion 20 can be made to be further obscure. Accordingly, the mesh wiring portion 20 can be made difficult to see on the front face of the image display device 60, and the mesh wiring portion 20 can be made to be less readily visually recognizable by the bare eye of the user of the image display device 60. Note that three or more dummy wiring portions with aperture ratios that differ from each other may be provided around the mesh wiring portion 20.

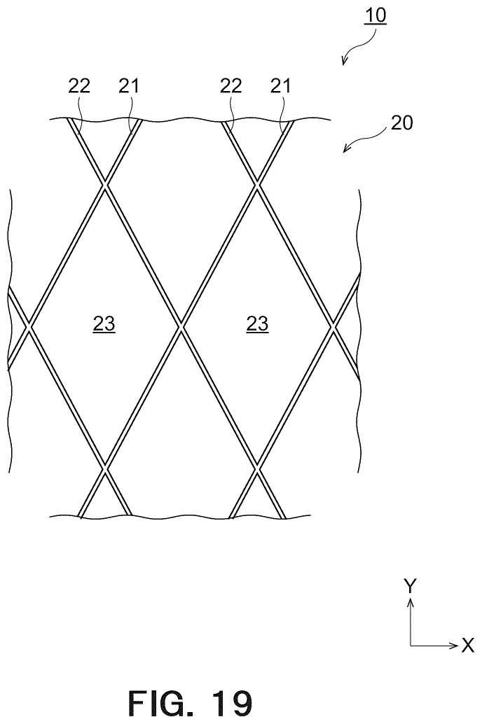

FIG. 19 illustrates a fifth modification of the wiring board. The modification illustrated in FIG. 19 differs in the planar form of the mesh wiring portion 20, and other configurations are substantially the same as the forms illustrated in FIG. 1 to FIG. 18 described above. In FIG. 19, portions that are the same as in the forms illustrated in FIG. 1 to FIG. 18 are denoted by the same signs, and detailed description will be omitted.

In FIG. 19, the first-direction wiring lines 21 and the second-direction wiring lines 22 intersect obliquely (non-orthogonally), and each opening 23 is formed as a rhombus shape in plan view. The first-direction wiring lines 21 and the second-direction wiring lines 22 are each not parallel to either of the X direction and the Y direction, but one of the first-direction wiring lines 21 and the second-direction wiring lines 22 may be parallel to the X direction or the Y direction.

### Second Embodiment

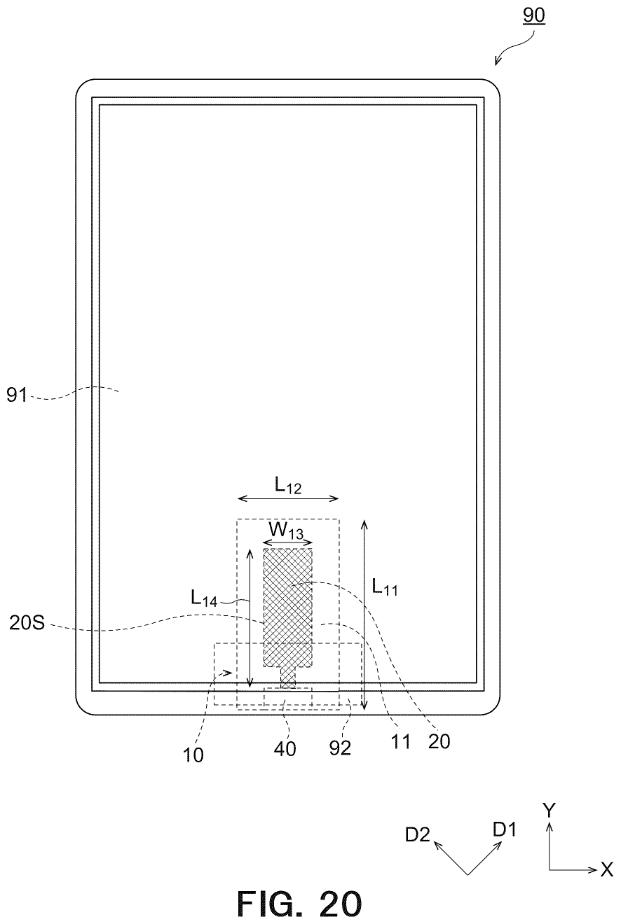

Next, a second embodiment will be described with reference to FIG. 20 to FIG. 25F. FIG. 20 to FIG. 25F are diagrams illustrating the second embodiment. In FIG. 20 to FIG. 25F, portions that are the same as those in the first embodiment illustrated in FIG. 1 to FIG. 19 are denoted with the same signs, and detailed description may be omitted.

Also, in the following embodiment, “X direction” is a direction perpendicular to the longitudinal direction of the mesh wiring portion, and is a direction perpendicular to the length direction that corresponds to the frequency band of the mesh wiring portion. “Y direction” is a direction that is perpendicular to the X direction and also parallel to the longitudinal direction of the mesh wiring portion, and is a direction parallel to the length direction that corresponds to the frequency band of the mesh wiring portion. “Z direction” is a direction that is perpendicular to both the X direction and the Y direction, and is parallel to the thickness direction of the wiring board. Also, “front face” is a face on the plus side in the Z direction, which is a face on which the mesh wiring portion is provided on the substrate. “Rear face” is a face on the minus side in the Z direction, which is a face opposite to the face on which the mesh wiring portion is provided on the substrate. Note that in the present embodiment, an example will be described regarding a case in which the mesh wiring portion is a mesh wiring portion having radio wave transmission/reception functions (functions as an antenna), but the mesh wiring portion 20 does not have to have radio wave transmission/reception functions (functions as an antenna).

### [Configuration of Wiring Board]

A configuration of the wiring board according to the present embodiment will be described with reference to FIG. 20 to FIG. 24. FIG. 20 to FIG. 24 are drawings illustrating the wiring board according to the present embodiment.

As illustrated in FIG. 20, the wiring board 10 according to the present embodiment is disposed on a display device (display) 91 of an image display device 90, for example. Such a wiring board 10 includes the substrate 11 that has transparency, and the mesh wiring portion 20 that is disposed on the substrate 11 and has conductivity. Also, the power supply unit 40 is electrically connected to the mesh wiring portion 20.

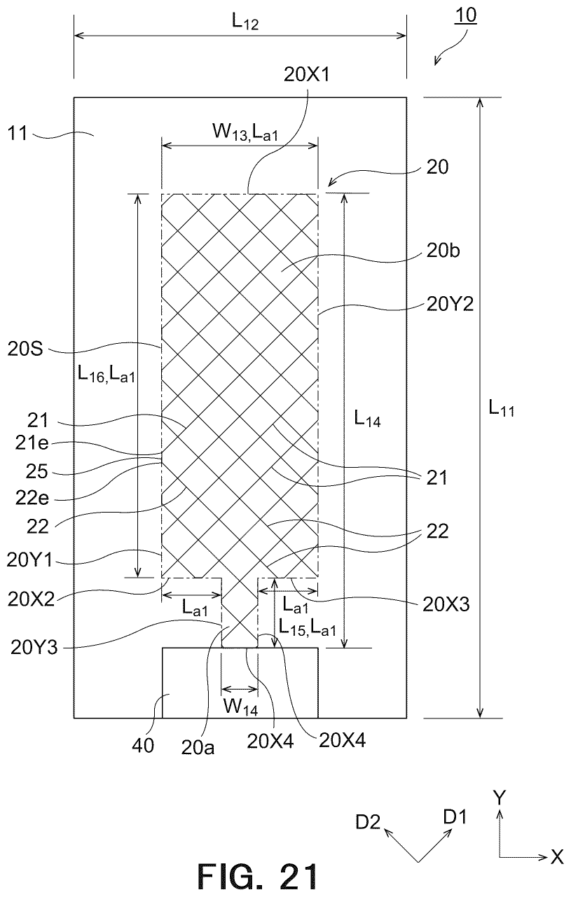

As illustrated in FIG. 21, the mesh wiring portion 20 includes the plurality of first-direction wiring lines 21 and the plurality of second-direction wiring lines 22. The plurality of first-direction wiring lines 21 are each parallel to a first direction D1, and the plurality of second-direction wiring lines 22 are each parallel to a second direction D2. With a perimeter of a region in which the mesh wiring portion 20 is disposed as an imaginary peripheral line 20S, the imaginary peripheral line 20S is made up of sides 20X1 to 20X4 and 20Y1 to 20Y4, which are a plurality of straight-line-like sides. The imaginary peripheral line 20S forms an enclosed shape. Part of the imaginary peripheral line 20S extends along a third direction (X direction or Y direction). The first direction D1 and the second direction D2 are each non-parallel to the third direction (X direction or Y direction). In part of the imaginary peripheral line 20S, end portions 21e of the first-direction wiring lines 21 and end portions 22e of the second-direction wiring lines 22 are each interconnected by end-portion interconnecting wiring lines 25. The total length of one side of the imaginary peripheral line of the mesh wiring portion 20 in the third direction (X direction or Y direction) is represented by Lₐ₁, and the summed length between both ends of the end-portion interconnecting wiring lines 25 included in the total length Lₐ₁ is represented by Lp. At this time, a relation of 0.1 Lₐ₁≤Lp≤0.5 Lₐ₁ holds.

The substrate 11 has a substantially rectangular shape in plan view. The longitudinal direction of the substrate 11 is parallel to the Y direction, and the lateral direction of the substrate 11 is parallel to the X direction. The substrate 11 has transparency and also has a substantially plate-like shape, and the thickness thereof is substantially uniform overall. A length L₁₁ of the substrate 11 in the longitudinal direction (Y direction) may be in a range of 20 mm or more and 300 mm or less, for example, and may be in a range of 100 mm or more and 200 mm or less. A length L₁₂ of the substrate 11 in the lateral direction (X direction) may be in a range of 2 mm or more and 300 mm or less, for example, and may be in a range of 3 mm or more and 100 mm or less. Also, the length L₁₂ of the substrate 11 in the lateral direction (X direction) may be in a range of 20 mm or more and 500 mm or less, for example, and may be in a range of 50 mm or more and 100 mm or less.

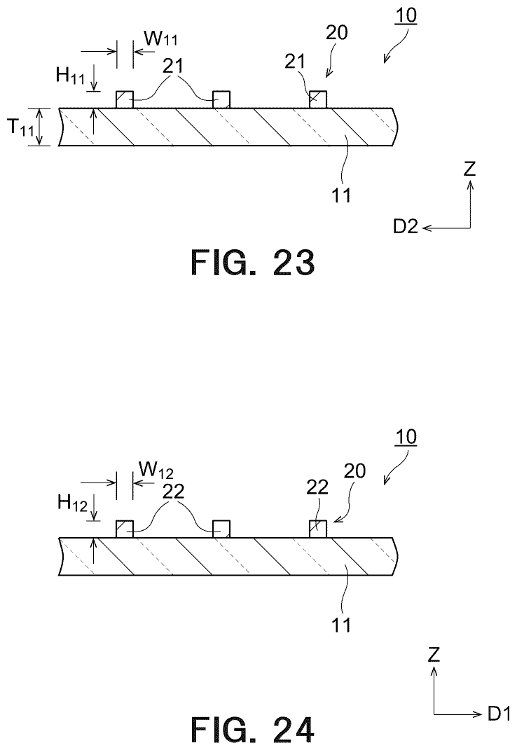

The material of the substrate 11 is a material that has transparency in the visible light domain, and electrical insulating properties. The material of the substrate 11 is polyethylene terephthalate in the present embodiment, but this is not restrictive. There is no limit to the thickness of the substrate 11 in particular, and can be selected as appropriate in accordance with the usage. As one example, a thickness T₁₁ of the substrate 11 (length in Z direction, see FIG. 23) may be in a range of 10 μm or more and 200 μm or less, for example.

In the present embodiment, the mesh wiring portion 20 is made up of an antenna pattern having a function as an antenna. In FIG. 21, one mesh wiring portion 20 is formed on the substrate 11. This mesh wiring portion 20 corresponds to a predetermined frequency band. That is to say, a length (direction in Y direction) L₁₄ of the mesh wiring portion 20 is a length corresponding to a particular frequency band. Note that the lower frequency the corresponding frequency band is, the longer the length L₁₄ of the mesh wiring portion 20 is. In a case in which the wiring board 10 is disposed on the display device 91 (see FIG. 20) of the image display device 90, for example, in each mesh wiring portion 20, the wiring board 10 may have radio wave transmission/reception functions. Note that a plurality of the mesh wiring portions 20 may be formed on the substrate 11. In this case, the plurality of mesh wiring portions 20 may differ in length from one another, and correspond to different frequency bands from one another.

The longitudinal direction of the mesh wiring portion 20 is parallel to the Y direction, and the lateral direction thereof is parallel to the X direction. The imaginary peripheral line 20S of this mesh wiring portion 20 is made up of sides 20X1 to 20X4 and 20Y1 to 20Y4, which are eight straight-line-like sides. Of these, sides 20X1 to 20X4 are each parallel to the X direction, and sides 20Y1 to 20Y4 are each parallel to the Y direction. The imaginary peripheral line 20S forms an enclosed shape. In the present embodiment, the imaginary peripheral line 20S makes up an outline of a shape in which two rectangles, which are different in size from each other, are connected. In the present specification, the “third direction” is a direction in which part of the imaginary peripheral line 20S extends. In the case of the present embodiment, the “third direction” means one of the X direction or Y direction. At least part of the imaginary peripheral line 20S extends along the third direction. Specifically, part of the imaginary peripheral line 20S extends in the X direction, the other part extends in the Y direction.

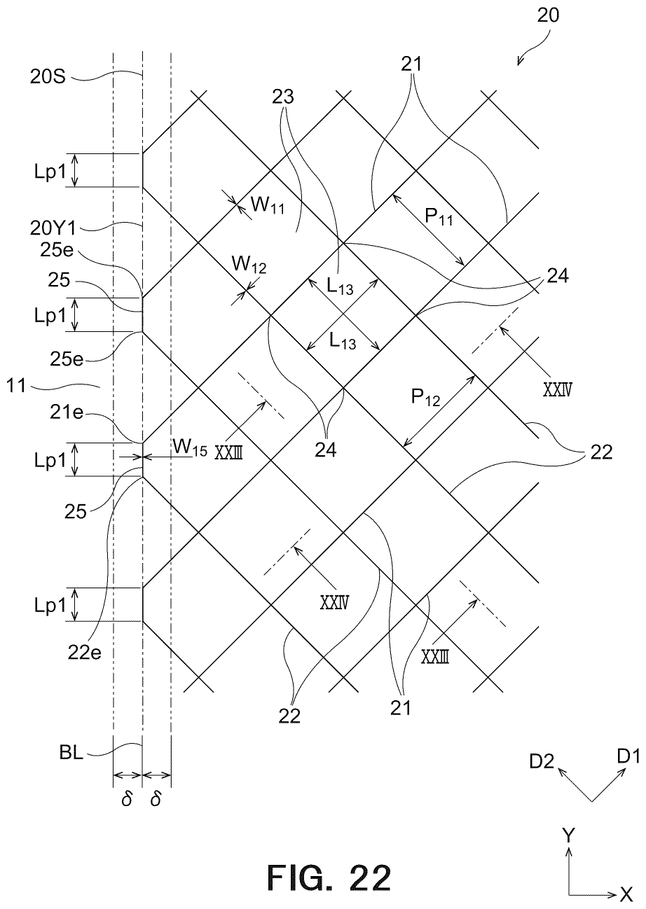

In the present specification, “imaginary peripheral line 20S” is, in macroscopic view, a boundary line making up the outer edge of the mesh wiring portion 20. Also, “part of the imaginary peripheral line 20S” is a region of the imaginary peripheral line 20S having at least a certain length or more (1 mm or more). For example, the eight sides 20X1 to 20X4 and 20Y1 to 20Y4 each make up part of the imaginary peripheral line 20S. Note that, as illustrated in FIG. 22, “part of imaginary peripheral line 20S” does not have to exist on a straight line BL making up the boundary line in a strict sense, and is a region situated within δ=10 μm in either direction orthogonal to the straight line BL serving as a reference making up the boundary line. Also, “at least part of imaginary peripheral line 20S” may be the entire imaginary peripheral line 20S, or may be only part of the imaginary peripheral line 20S.

As illustrated in FIG. 21, the length L₁₄ in the longitudinal direction of the mesh wiring portion 20 (Y direction) may be in a range of 3 mm or more and 100 mm or less, for example. A width W₁₃ in the lateral direction of the mesh wiring portion 20 (distal side portion 20b) (X direction) may be in a range of 1 mm or more and 10 mm or less, for example. In particular, the mesh wiring portion 20 may be a millimeter wave antenna. In a case in which the mesh wiring portion 20 is a millimeter wave antenna, the length L₁₄ of the mesh wiring portion 20 can be selected from a range of 1 mm or more and 10 mm or less, more preferably 1.5 mm or more and 5 mm or less. Note that while FIG. 21 illustrates a form of a case in which the mesh wiring portion 20 functions as a monopole antenna, this is not restrictive, and forms may be used such as a dipole antenna, a loop antenna, a slot antenna, a microstrip antenna, a patch antenna, and so forth.

The mesh wiring portion 20 has the basal side portion 20a on the power supply unit 40 side, and the distal side portion 20b connected to the basal side portion 20a. The basal side portion 20a and the distal side portion 20b each have substantially rectangular shapes in plan view. The basal side portion 20a is surrounded by three sides, which are 20Y3, 20X4, and 20Y4. The distal side portion 20b is surrounded by five sides, which are 20X2, 20Y1, 20X1, 20Y2, and 20X3. In this case, the length of the distal side portion 20b (Y-direction distance) is longer than the length of the basal side portion 20a (Y-direction distance). Also, the width of the distal side portion 20b (X-direction distance) is broader than the width of the basal side portion 20a (X-direction distance). A length (Y-direction length) L₁₅ of the basal side portion 20a may be 0.1 mm or more and 5 mm or less. A width (Y-direction length) W₁₄ of the basal side portion 20a may be 0.1 mm or more and 5 mm or less. A length (Y-direction length) L₁₆ of the distal side portion 20b may be 1 mm or more and 100 mm or less.

The mesh wiring portion 20 has a pattern in which respective metal lines are laid out in a grid-like or fishnet-like form, repeating in the X direction and the Y direction. That is to say, the mesh wiring portion 20 has a pattern form made up of portions extending in the first direction D1 (first-direction wiring lines 21) and portions extending in the second direction D2 (second-direction wiring lines 22). In this case, the first direction D1 and the second direction D2 are each non-parallel with respect to the third direction. That is to say, the first direction D1 is parallel to neither the X direction nor the Y direction, and the second direction D2 is parallel to neither the X direction nor the Y direction. Note that in the present embodiment, the first direction D1 is inclined by 45° with respect to each of the X direction and the Y direction, and the second direction D2 is inclined by 45° with respect to each of the X direction and the Y direction. The first direction D1 and the second direction D2 are orthogonal to each other.

As illustrated in FIG. 22, the mesh wiring portion 20 includes the plurality of first-direction wiring lines 21, and the plurality of second-direction wiring lines 22 that are interconnected to the plurality of first-direction wiring lines 21. Specifically, the plurality of first-direction wiring lines 21 and the plurality of second-direction wiring lines 22 overall and integrally form a grid-like form or a fishnet-like form. The first-direction wiring lines 21 extend in the first direction D1. The second-direction wiring lines 22 extend in the second direction D2 that is orthogonal to the first-direction wiring lines 21. The first-direction wiring lines 21 and the second-direction wiring lines 22 exhibit functions as an antenna by having, overall, the length L₁₄ (length of mesh wiring portion 20 described above, see FIG. 21) corresponding to a predetermined frequency band. Note that the first-direction wiring lines 21 and the second-direction wiring line 22 may intersect each other such that a smaller angle is greater than 0° and less than 90°.

In the mesh wiring portion 20, the plurality of openings 23 are formed by being surrounded by the first-direction wiring lines 21 adjacent to each other and the second-direction wiring lines 22 adjacent to each other. Also, the first-direction wiring lines 21 and the second-direction wiring lines 22 are disposed equidistantly from each other. That is to say, the plurality of first-direction wiring lines 21 are disposed equidistantly from each other. A pitch P₁₁ of the plurality of first-direction wiring lines 21 may be in a range of, for example, 0.01 mm or more and 1 mm or less, and preferably in a range of 0.05 mm or more and 0.5 mm or less. Also, the plurality of second-direction wiring lines 22 are disposed equidistantly from each other. A pitch P₁₂ of the plurality of second-direction wiring lines 22 may be in a range of, for example, 0.01 mm or more and 1 mm or less, and preferably in a range of 0.05 mm or more and 0.5 mm or less. Due to the plurality of first-direction wiring lines 21 and the plurality of second-direction wiring lines 22 each being laid out equidistantly in this way, variance in the size of the openings 23 in the mesh wiring portion 20 is done away with, and the mesh wiring portion 20 can be made to be not readily visually recognized by the bare eye. Also, the pitch P₁₁ of the first-direction wiring lines 21 is equal to the pitch P₂ of the second-direction wiring lines 22. Accordingly, the openings 23 are each a substantially square shape in plan view, and the substrate 11 that has transparency is exposed from the openings 23. Accordingly, making the area of the openings 23 to be large enables the transparency of the wiring board 10 overall to be raised. Note that a length L₁₃ of one side of the openings 23 may be in a range of, for example, 0.01 mm or more and 1 mm or less, and preferably is in a range of 0.05 mm or more and 0.5 mm or less. Also, the shape of the openings 23 preferably is the same shape and the same size over the entire face except for near the imaginary peripheral line 20S, but may not be uniform over the entire face due to being changed depending on locations, or the like.

Each opening 23 is surrounded by a pair of first-direction wiring lines 21 and a pair of second-direction wiring lines 22. The first-direction wiring lines 21 and the second-direction wiring lines 22 each intersect at points of intersection 24. There are a plurality of (four in this case) points of intersection 24 each situated around each opening 23.

As illustrated in FIG. 22, in the present embodiment, the end portions 21e of the first-direction wiring lines 21 and the end portions 22e of the second-direction wiring lines 22 are each interconnected by the end-portion interconnecting wiring lines 25 at part of the imaginary peripheral line 20S. Specifically, as illustrated in FIG. 22, each first-direction wiring line 21 has an end portion 21e and each second-direction wiring line 22 has an end portion 22e, at a side 20Y1 making up the imaginary peripheral line 20S. The end portions 21e of the first-direction wiring lines 21 and the end portions 22e of the second-direction wiring lines 22 are distanced from each other in the Y direction (third direction). The end-portion interconnecting wiring lines 25 interconnect the end portions 21e of the first-direction wiring lines 21 and the end portions 22e of the second-direction wiring lines 22 that are adjacent to each other. Specifically, the end portions 21e of the first-direction wiring lines 21 and the end portions 22e of the second-direction wiring lines 22 that are nearer to the end portions 21e are interconnected by the end-portion interconnecting wiring lines 25. A plurality of end-portion interconnecting wiring lines 25 are preferably disposed along the Y direction (third direction) on the imaginary peripheral line 20S, in a form of a dotted line. That is to say, the end-portion interconnecting wiring lines 25 are preferably intermittently present along the Y direction (third direction). The end-portion interconnecting wiring lines 25 extend linearly in parallel to the Y direction. Note that the end-portion interconnecting wiring lines 25 may be inclined with respect to the Y direction (third direction) by more than 0° and 10° or less. The end-portion interconnecting wiring lines 25 do not have to be present on the straight line BL making up the imaginary peripheral line 20S, and may be situated in a region within δ=10 μm in either way in the X direction with respect to the straight line BL.

As illustrated in FIG. 21, the total length of one side of the imaginary peripheral line 20S in the Y direction (third direction) is represented by Lₐ₁. The total length Lₐ₁ here is the length of one of the sides 20X1 to 20X4 and 20Y1 to 20Y4 of the imaginary peripheral line 20S in the X direction or the Y direction (third direction), and in this case is the total length of the side 20Y1. Also, as illustrated in FIG. 22, the summed length between both ends 25e and 25e of the end-portion interconnecting wiring lines 25 along the Y direction (third direction) on the side 20Y1 is represented by Lp. Note that the ends 25e and 25e of the end-portion interconnecting wiring lines 25 agree with the end portions 21e of the first-direction wiring lines 21 and the end portions 22e of the second-direction wiring lines 22. Now, the summed length Lp is a length obtained by adding lengths Lp1 between both ends 25e and 25e of individual end-portion interconnecting wiring lines 25 over the entire portion of the imaginary peripheral line 20S (side 20Y1) (Lp=ΣLp1). The length Lp1 of the end-portion interconnecting wiring lines 25 is a length along the Y direction (third direction) between the center in a line-width direction of one end portion 25e of each end-portion interconnecting wiring line 25 and the center in the line-width direction of the other end portion 25e of the end-portion interconnecting wiring line 25. Note that the length Lp1 of the end-portion interconnecting wiring lines 25 is found as a length along the Y direction, even in cases in which the end-portion interconnecting wiring lines 25 are inclined with respect to the Y direction (third direction).

In this case, a relation of 0.1 Lₐ₁≤Lp≤0.5 Lₐ₁ holds between the total length Lₐ₁ of part of the imaginary peripheral line 20S, and the summed length Lp of between both ends 25e and 25e of the end-portion interconnecting wiring lines 25 along the Y direction (third direction). That is to say, the end-portion interconnecting wiring lines 25 are present in a region of 10% or more and 50% or less of the part of the imaginary peripheral line 20S (e.g., side 20Y1). Due to the relation of 0.1 Lₐ₁≤Lp holding between the total length Lₐ₁ and the summed length Lp, the first-direction wiring lines 21 and the second-direction wiring lines 22 are not broken at the part of the imaginary peripheral line 20S (e.g., side 20Y1). Thus, deterioration in electrical characteristics of the mesh wiring portion 20 can be suppressed. Due to the relation of Lp≤0.5 Lₐ₁ holding between the total length Lₐ₁ and the summed length Lp, part of the imaginary peripheral line 20S (side 20Y1) can be suppressed from being readily visually recognized by the bare eye, and deterioration in non-visibility can be kept within a tolerance range. Note that a relation of 0.15 Lₐ₁≤Lp preferably holds between the total length Lₐ₁ and the summed length Lp, and a relation of 0.2 Lₐ₁≤Lp even more preferably holds. Also, a relation of Lp≤0.45 Lₐ₁ preferably holds between the total length Lₐ₁ and the summed length Lp, and a relation of Lp≤0.4 Lₐ₁ even more preferably holds.

Note that the end portions 21e of part of first-direction wiring lines 21 and the end portions 22e of part of second-direction wiring lines 22 do not have to be interconnected by the end-portion interconnecting wiring lines 25, as long as the relation of 0.1 Lₐ₁≤Lp≤0.5 Lₐ₁ holds. Also, the end portions 21e of part of the first-direction wiring lines 21 and the end portions 22e of the second-direction wiring lines 22 farther away from the end portions 21e may be interconnected by the end-portion interconnecting wiring lines 25. The end portions 21e and 22e that are not interconnected by the end-portion interconnecting wiring lines 25 may be present at part of the side 20Y1.

Note that although not illustrated, the end portions 21e of the first-direction wiring lines 21 and the end portions 22e of the second-direction wiring lines 22 may each be interconnected by the end-portion interconnecting wiring lines 25 in the same way at all or part of the other sides 20X1, 20X2, 20X3, 20Y2, 20Y3, and 20Y4, excluding the side 20X4 on the power supply unit 40 side. In this case, the relation of 0.1 Lₐ₁≤Lp≤0.5 Lₐ₁ preferably holds for each of the sides 20X1, 20X2, 20X3, 20Y2, 20Y3, and 20Y4. Also, the total length of the entire perimeter of the mesh wiring portion 20 excluding the side 20X4 on the power supply unit 40 side is represented by Lₐt, and the summed length between both ends 25e and 25e of the end-portion interconnecting wiring lines 25 of the entire perimeter of the mesh wiring portion 20 excluding the side 20X4 is represented by Lpt. In this case, a relation of 0.1 Lₐt≤Lpt≤0.5 Lₐt preferably holds.

Also, the end portions 21e of the first-direction wiring lines 21 and the end portions 22e of the second-direction wiring lines 22 may each be interconnected by the end-portion interconnecting wiring lines 25 with regard to only part of the sides 20X1, 20X2, 20X3, 20Y1, 20Y2, 20Y3, and 20Y4. In this case, a relation of 0.1 Lₐ₁≤Lp≤0.5 Lₐ₁ preferably holds regarding this part.

A line width W₁₅ of the end-portion interconnecting wiring lines 25 may be in a range of 0.1 μm or more and 5.0 μm or less, or may be 0.5 μm or more and 3.0 μm or less. Also, the line width W₁₅ of the end-portion interconnecting wiring lines 25 may be narrower than a line width W₁₁ of the first-direction wiring lines 21 and a line width W₁₂ of the second-direction wiring lines 22, which will be described later. In this case, the line width W₁₅ of the end-portion interconnecting wiring lines 25 may be in a range of 0.08 μm or more and 4.0 μm or less, or may be 0.4 μm or more and 2.4 μm or less. By making the line width W₁₅ of the end-portion interconnecting wiring lines 25 to be narrower than the line width W₁₁ of the first-direction wiring lines 21 and the line width W₁₂ of the second-direction wiring lines 22, the presence of the end-portion interconnecting wiring lines 25 can be made to be less readily visually recognized, while maintaining electrical characteristics of the mesh wiring portion 20.

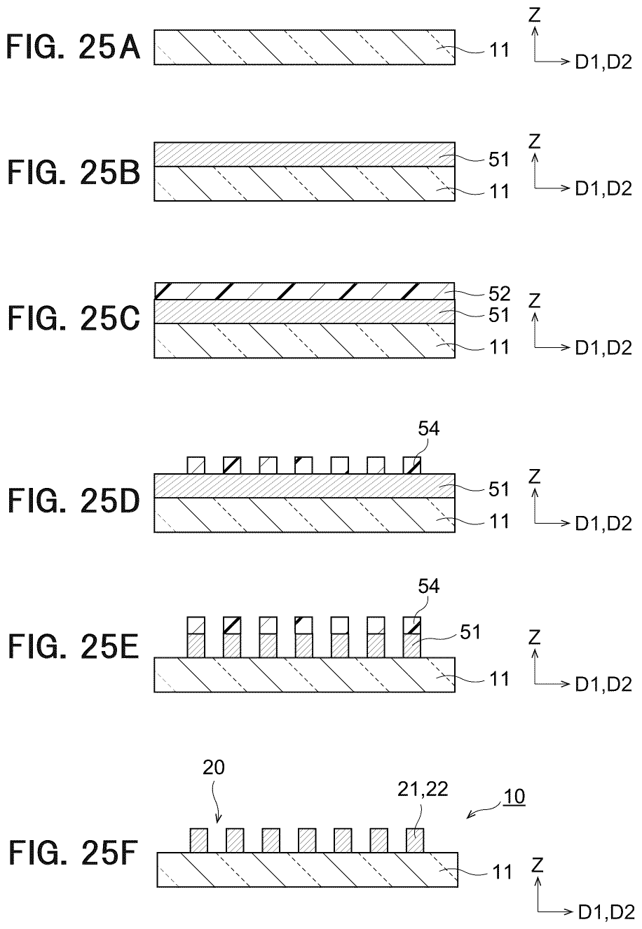

As illustrated in FIG. 23, the first-direction wiring lines 21 each have a cross-section perpendicular to the longitudinal direction thereof (cross section in second direction D2) that is a substantially rectangular shape or a substantially square shape. In this case, the cross-sectional shape of the first-direction wiring lines 21 is substantially uniform along the longitudinal direction of the first-direction wiring lines 21 (first direction D1). Also, as illustrated in FIG. 24, the second-direction wiring lines 22 each have a cross-sectional shape perpendicular to the longitudinal direction thereof (cross-section in first direction D1) that is a substantially rectangular shape or a substantially square shape, and is substantially the same as the cross-sectional shape of the first-direction wiring lines 21 (cross-section in second direction D2) described above. In this case, the cross-sectional shape of the second-direction wiring line 22 is substantially uniform along the longitudinal direction of the second-direction wiring line 22 (second direction D2).

In the present embodiment, the line width W₁₁ of the first-direction wiring lines 21 (length in second direction D2, see FIG. 23) and the line width W₁₂ of the second-direction wiring lines 22 (length in first direction D1, see FIG. 24) are not limited in particular, and can be selected as appropriate in accordance with usage. For example, the line width W₁₁ of the first-direction wiring lines 21 may be in a range of 0.1 μm or more and 5.0 μm or less, or may be 0.5 μm or more and 3.0 μm or less. Also, the line width W₁₂ of the second-direction wiring lines 22 may be in a range of 0.1 μm or more and 5.0 μm or less, or may be 0.5 μm or more and 3.0 μm or less. Further, a height H₁₁ of the first-direction wiring lines 21 (length in Z direction, see FIG. 23) and a height H₁₂ of the second-direction wiring lines 22 (length in Z direction, see FIG. 24) are not limited in particular, and may be selected as appropriate in accordance with usage. For example, the height H₁₁ of the first-direction wiring lines 21 and the height H₁₂ of the second-direction wiring lines 22 may each be in a range of 0.1 μm or more and 5.0 μm or less, or may be 0.2 μm or more and 2.0 μm or less.

A sheet resistance value of the mesh wiring portion 20 may be 5 ohms per square or less, or may be 4 ohms per square or less. Sheet resistance value in the above range for the mesh wiring portion 20 enables the performance of the mesh wiring portion 20 to be maintained. Specifically, radiation efficiency of the mesh wiring portion 20 serving as an antenna (a proportion indicating how much of the electric power input to the mesh wiring portion 20 itself has been radiated) can be improved. The sheet resistance value (ohms per square) of the mesh wiring portion 20 can be found as follows. That is to say, actual measurement of a resistance value R between both end portions in the longitudinal direction (Y direction) of the mesh wiring portion 20 is performed. Next, this resistance value R is divided by a ratio (L₁₄/W₁₃) of the length L₁₄ and width W₁₃ of the mesh wiring portion 20, whereby a sheet resistance value Rₛ (ohms per square) of the mesh wiring portion 20 can be found. That is to say, sheet resistance value Rₛ=R×W₁₃/L₁₃ holds.

Note that a protective layer may be formed on the surface of the substrate 11 so as to cover the mesh wiring portion 20, although not illustrated. The protective layer is to protect the mesh wiring portion 20, and is formed so as to cover at least the mesh wiring portion 20 on the substrate 11. Acrylic resins such as polymethyl (meth)acrylate, polyethyl (meth)acrylate, and so forth, and denatured resins and copolymers thereof, polyvinyl resins such as polyester, polyvinyl alcohol, polyvinyl acetate, polyvinyl acetal, polyvinyl butyral, and so forth, and copolymers thereof, polyurethane, epoxy resin, polyamide, chlorinated polyolefin, and so forth, and like insulating resins that are colorless and transparent, can be used as the material of the protective layer.

A primer layer that is not illustrated may be formed between the substrate 11 and the mesh wiring portion 20. The primer layer improves adhesion of the mesh wiring portion 20 and the substrate 11. The primer layer may be provided on substantially the entire region of the surface of the substrate 11. The primer layer may be uncolored and transparent. Also, the primer layer may include a polymer material. Thus, adhesion between the mesh wiring portion 20 and the substrate 11 can be effectively improved. The primer layer preferably contains an acrylic-based resin or a polyester-based resin. Accordingly, adhesion as to the mesh wiring portion 20 can be effectively improved. A thickness of the primer layer may be 0.05 μm or more and 0.5 μm or less. Due to the thickness of the primer layer being in the above range, adhesion between the mesh wiring portion 20 and the substrate 11 can be improved, and also transparency of the wiring board 10 can be secured.

Referencing FIG. 21 again, the power supply unit 40 is electrically connected to the mesh wiring portion 20. When the wiring board 10 is assembled into the image display device 90 (see FIG. 20), this power supply unit 40 is electrically connected to a wireless communication circuit 92 of the image display device 90. Note that the power supply unit 40 may be formed to be flexible, so as to wrap the power supply unit 40 around to a side face or a rear face of the image display device 90, so as to be capable of being electrically connected at the side face or the rear face side.

### [Manufacturing Method of Wiring Board]

Next, a manufacturing method of the wiring board according to the present embodiment will be described with reference to FIG. 25A to FIG. 25F. FIG. 25A to FIG. 25F are cross-sectional views illustrating the manufacturing method of the wiring board according to the present embodiment.

As illustrated in FIG. 25A, the substrate 11 that has transparency is prepared.

Next, the mesh wiring portion 20 including the plurality of first-direction wiring lines 21, and the plurality of second-direction wiring lines 22 interconnecting the plurality of first-direction wiring lines 21 is formed on the substrate 11.

At this time, first, as illustrated in FIG. 25B, metal foil 51 is laminated on substantially the entire region of the surface of the substrate 11.

Next, as illustrated in FIG. 25C, photo-curing insulating resist 52 is supplied to substantially the entire region of the surface of the metal foil 51.

Next, as illustrated in FIG. 25D, an insulating layer 54 is formed by photolithography.

Next, as illustrated in FIG. 25E, the metal foil 51 situated at portions on the surface of the substrate 11 not covered by the insulating layer 54 is removed.

Next, as illustrated in FIG. 25F, the insulating layer 54 is removed.

Thus, the wiring board 10 that has the substrate 11, and the mesh wiring portion 20 provided on the substrate 11, is obtained. In this case, the mesh wiring portion 20 includes the first-direction wiring lines 21, the second-direction wiring lines 22, and the end-portion interconnecting wiring lines 25.

### Effects of Present Embodiment

Next, the effects of the present embodiment having such a configuration will be described.

As illustrated in FIG. 20, the wiring board 10 according to the present embodiment is assembled into the image display device 90. The image display device 90 has the display device (display) 91. The display device 91 may be an organic EL (Electro Luminescence) display device, for example. The display device 91 may include a metal layer, a support base material, a resin base material, a thin-film transistor (TFT), and an organic EL layer, which are not illustrated, for example. A touch sensor that is not illustrated may be disposed above the display device 91. Note that the display device 91 is not limited to an organic EL display device. For example, the display device 91 may be another display device that has functions of light emission in itself. The display device 91 may be a micro-LED display device including microscopic LED elements (light emitters). Alternatively, the display device 91 may be a liquid crystal display device including liquid crystal. The wiring board 10 is disposed directly or indirectly above the display device 91. Examples of such an image display device 90 include mobile terminal equipment such as smartphones, tablets, and so forth. The mesh wiring portion 20 of the wiring board 10 is electrically connected to the wireless communication circuit 92 of the image display device 90 via the power supply unit 40. Thus, radio waves of a predetermined frequency can be transmitted/received via the mesh wiring portion 20, and communication can be performed using the image display device 90. In the present embodiment, such an image display device 90 that includes the display device 91, and the wiring board 10 disposed on the display device 91, is also provided.

In the present embodiment, at part of the imaginary peripheral line 20S of the mesh wiring portion 20, the end portions 21e of the first-direction wiring lines 21 and the end portions 22e of the second-direction wiring lines 22 are each interconnected by the end-portion interconnecting wiring lines 25. Also, the total length of one side of the imaginary peripheral line 20S in the third direction (X direction or Y direction) is represented by Lₐ₁, and the summed length between both ends 25e and 25e of the end-portion interconnecting wiring lines 25 in the third direction (X direction or Y direction) is represented by Lp. At this time, the relation of 0.1 Lₐ₁≤Lp≤0.5 Lₐ₁ holds. Accordingly, even in a case in which the imaginary peripheral line 20S does not agree with the points of intersection 24 of the mesh wiring portion 20, a state in which the end portions 21e of the first-direction wiring lines 21 and the end portions 22e of the second-direction wiring lines 22 are broken does not occur. Thus, deterioration in electrical characteristics at the perimeter of the mesh wiring portion 20 can be suppressed. On the other hand, in a case in which the end portions 21e of the first-direction wiring lines 21 and the end portions 22e of the second-direction wiring lines 22 are not interconnected and are broken at the perimeter of the mesh wiring portion 20, radiation of radio waves can occur from such portions, and there is concern that this may cause noise of unwanted frequencies.

Also, according to the present embodiment, the end-portion interconnecting wiring lines 25 are not provided on the entirety of the imaginary peripheral line 20S. Accordingly, the end-portion interconnecting wiring lines 25 that are oriented in a different direction from the directions of the first-direction wiring lines 21 and the second-direction wiring lines 22 are less conspicuous. As a result, the perimeter of the mesh wiring portion 20 can be made to be not readily visually recognized by the bare eye of the observer, and the observer can be kept from recognizing the presence of the mesh wiring portion 20.

In this way, according to the present embodiment, deterioration in non-visibility of the mesh wiring portion 20 can be suppressed while improving electrical characteristics of the mesh wiring portion 20.

Also, according to the present embodiment, the plurality of end-portion interconnecting wiring lines 25 are disposed in the form of a dotted line on the perimeter of the mesh wiring portion 20, along the third direction (X direction or Y direction). Accordingly, the end-portion interconnecting wiring lines 25 are uniformly disposed along the third direction (X direction or Y direction). As a result, the end-portion interconnecting wiring lines 25 are less conspicuous on the perimeter of the mesh wiring portion 20, and the perimeter of the mesh wiring portion 20 can be made to be not readily visually recognized by the bare eye of the observer.

Also, according to the present embodiment, the wiring board 10 includes the substrate 11 that has transparency, and the mesh wiring portion 20 disposed on the substrate 11. This mesh wiring portion 20 has a mesh-like pattern made up of a conductor portion serving as a formation portion of a non-transparent conductor layer, and a great number of openings, and accordingly, the transparency of the wiring board 10 is secured. Thus, when the wiring board 10 is disposed on the display device 91, the display device 91 can be visually recognized from the openings 23 of the mesh wiring portion 20, and visibility of the display device 91 is not impeded.

### [Modifications]

Next, modifications of the wiring board according to the present embodiment will be described.

### (First Modification)

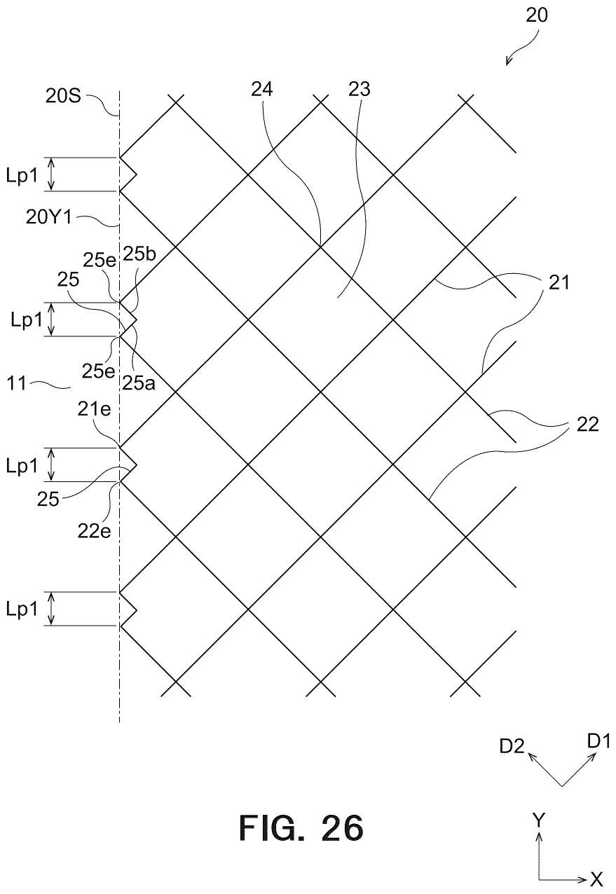

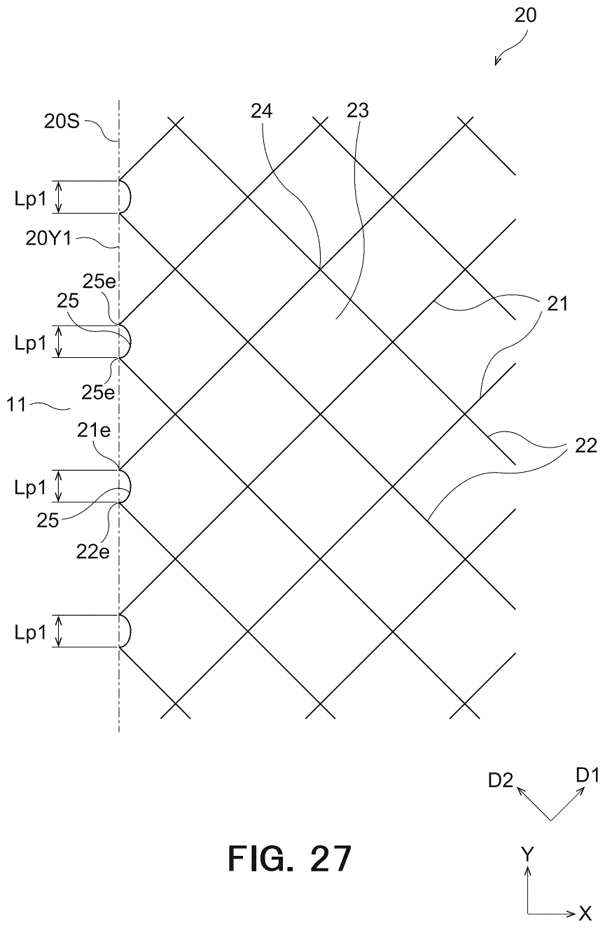

FIG. 26 and FIG. 27 illustrate a first modification of the wiring board. The modification illustrated in FIG. 26 and FIG. 27 differ with respect to the configuration of the end-portion interconnecting wiring lines 25, and other configurations are substantially the same as those in the embodiment illustrated in FIG. 20 to FIG. 25F described above. Portions in FIG. 26 and FIG. 27 that are the same as in the form illustrated in FIG. 1 to FIG. 25F are denoted by the same signs, and detailed description will be omitted.

In the wiring board 10 illustrated in FIG. 26 and FIG. 27, the end portions 21e of the first-direction wiring lines 21 and the end portions 22e of the second-direction wiring lines 22 are each interconnected by the end-portion interconnecting wiring lines 25 at the side 20Y1 making up the imaginary peripheral line 20S. In this case, the end-portion interconnecting wiring lines 25 extend non-linearly.

As illustrated in FIG. 26, the end-portion interconnecting wiring lines 25 may have crooked line shapes. Specifically, the end-portion interconnecting wiring lines 25 may be V-shaped in plan view. The end-portion interconnecting wiring lines 25 are situated on the inner side of the mesh wiring portion 20 from the side 20Y1. The end-portion interconnecting wiring lines 25 include first wiring line portions 25a and second wiring line portions 25b. The first wiring line portions 25a may be parallel to the first-direction wiring lines 21. The second wiring line portions 25b may be parallel to the second-direction wiring lines 22.By the end-portion interconnecting wiring lines 25 having crooked line shapes in this way, the extending direction of the end-portion interconnecting wiring lines 25 is closer to the extending directions of the first-direction wiring lines 21 or the second-direction wiring line 22, and accordingly the presence of the end-portion interconnecting wiring lines 25 can be made to be less readily visually recognized.

As illustrated in FIG. 27, the end-portion interconnecting wiring lines 25 may have curved shapes. Specifically, the end-portion interconnecting wiring lines 25 may have semicircle shapes or semi-ellipse shapes in plan view. The end-portion interconnecting wiring lines 25 are situated on the inner side of the mesh wiring portion 20 from the side 20Y1. By the end-portion interconnecting wiring lines 25 having curved shapes in this way, the extending direction of the end-portion interconnecting wiring lines 25 faces various directions, and accordingly the presence of the end-portion interconnecting wiring lines 25 can be made to be further less readily visually recognized.

In the present modification as well, the relation of 0.1 Lₐ₁≤Lp≤0.5 Lₐ₁ holds between the total length Lₐ₁ of one side of the imaginary peripheral line 20S (FIG. 21), and the summed length Lp of both ends 25e and 25e of the end-portion interconnecting wiring lines 25 along the Y direction (third direction). In this case, the length Lp1 of the end-portion interconnecting wiring lines 25 is a length along the Y direction (third direction) between the center in a line-width direction of one end portion 25e of each end-portion interconnecting wiring line 25 and the center in the line-width direction of the other end portion 25e of the end-portion interconnecting wiring line 25.

### (Second Modification)

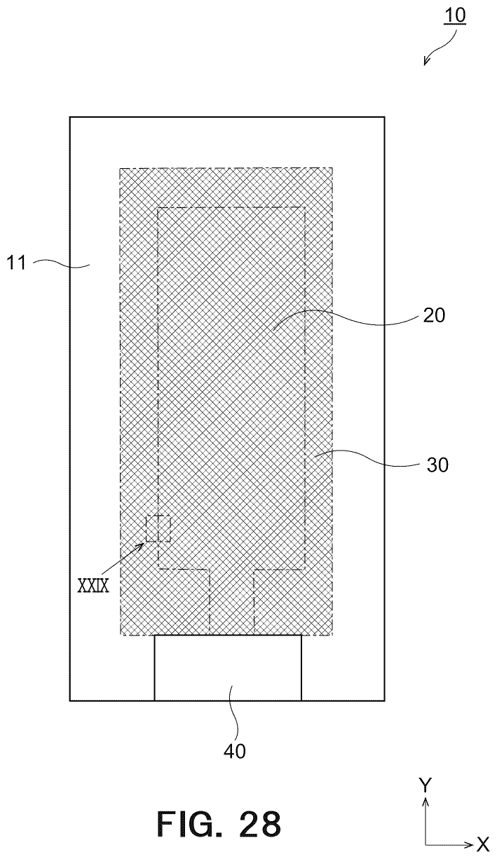

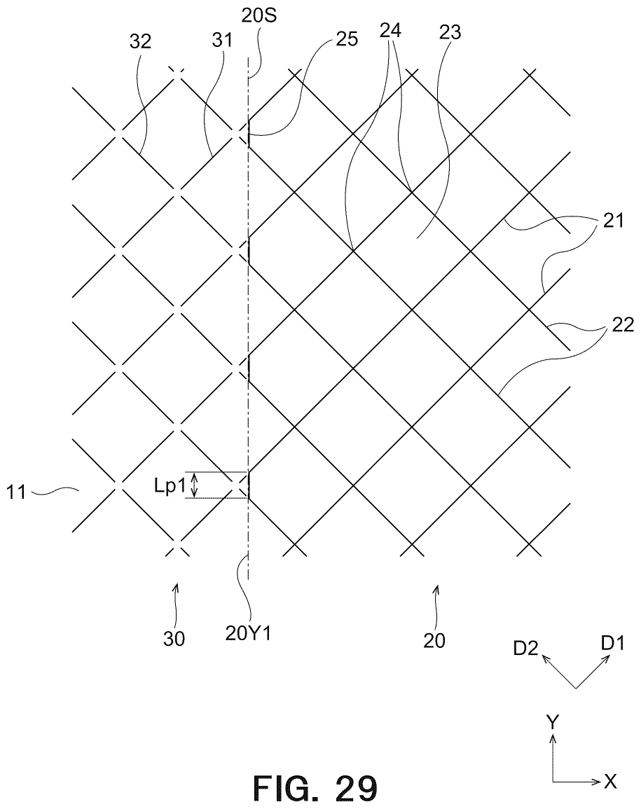

FIG. 28 and FIG. 29 illustrate a second modification of the wiring board. The modification illustrated in FIG. 28 and FIG. 29 differs with respect to the point of the dummy wiring portion 30 being provided around the mesh wiring portion 20, and other configurations are the substantially same as the form illustrated in the above-described FIG. 20 to FIG. 27. Portions in FIG. 28 and FIG. 29 that are the same as those in the form illustrated in FIG. 20 to FIG. 27 are denoted with the same signs, and detailed description will be omitted.

In the wiring board 10 illustrated in FIG. 28, the dummy wiring portion 30 is provided so as to follow around the mesh wiring portion 20. Unlike the mesh wiring portion 20, this dummy wiring portion 30 does not substantially function as an antenna.

As illustrated in FIG. 29, the dummy wiring portion 30 includes a plurality of first-direction dummy wiring lines 31 and a plurality of second-direction dummy wiring lines 32. The first-direction dummy wiring lines 31 and the second-direction dummy wiring lines 32 are each electrically isolated from each of the mesh wiring portions 20 (first-direction wiring lines 21 and second-direction wiring lines 22). Also, the first-direction dummy wiring lines 31 and the second-direction dummy wiring lines 32 are disposed with regularity over the entire region within the dummy wiring portion 30. The first-direction dummy wiring lines 31 are parallel to the first direction D1, and are situated on extension lines of the first-direction wiring lines 21. The second-direction dummy wiring lines 32 are parallel to the second direction D2, and are situated on extension lines of the second-direction wiring lines 22. The plurality of first-direction dummy wiring lines 31 are distanced from each other in the planar direction, and also are disposed protruding on the substrate 11. The plurality of second-direction dummy wiring lines 32 are distanced from each other in the planar direction, and also are disposed protruding on the substrate 11. The first-direction dummy wiring lines 31 and the second-direction dummy wiring lines 32 are each electrically isolated from the mesh wiring portion 20, the power supply unit 40, other first-direction dummy wiring lines 31, and other second-direction dummy wiring lines 32. The first-direction dummy wiring lines 31 and the second-direction dummy wiring lines 32 are each straight lines in plan view. Note that the dummy wiring portion 30 may have additional dummy wiring lines extending in the same direction as the end-portion interconnecting wiring lines 25. These additional dummy wiring lines may extend in the third direction (X direction or Y direction). Alternatively, the additional dummy wiring lines may extend in the first direction D1 or the second direction D2.

In this case, the first-direction dummy wiring lines 31 and the second-direction dummy wiring lines 32 do not intersect each other. That is to say, the dummy wiring portion 30 has a shape in which regions of the mesh wiring portion 20 corresponding to the points of intersection 24 are missing. Accordingly, difference between the mesh wiring portion 20 and the dummy wiring portion 30 can be made to be less readily visually recognized, and the mesh wiring portion 20 disposed on the substrate 11 can be made to be difficult to see. The aperture ratio of the dummy wiring portion 30 may be the same as the aperture ratio of the mesh wiring portion 20, or may be different, but preferably is close to the aperture ratio of the mesh wiring portion 20.

In this way, the dummy wiring portion 30 that is electrically isolated from the mesh wiring portion 20 is disposed around the mesh wiring portion 20, whereby the outer edge of the mesh wiring portion 20 can be made obscure. Thus, the mesh wiring portion 20 can be made difficult to see on the surface of the image display device 90, and the user of the image display device 90 can be made not to readily visually recognize the mesh wiring portion 20 by the bare eye.

### (Third Modification)

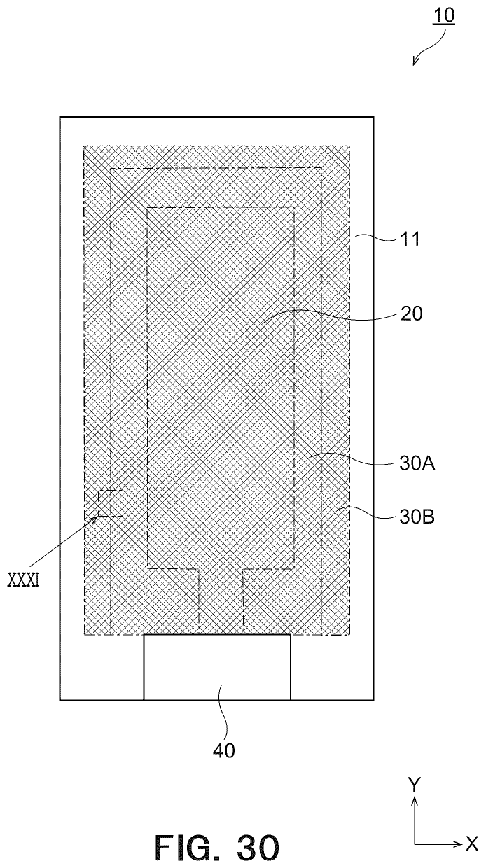

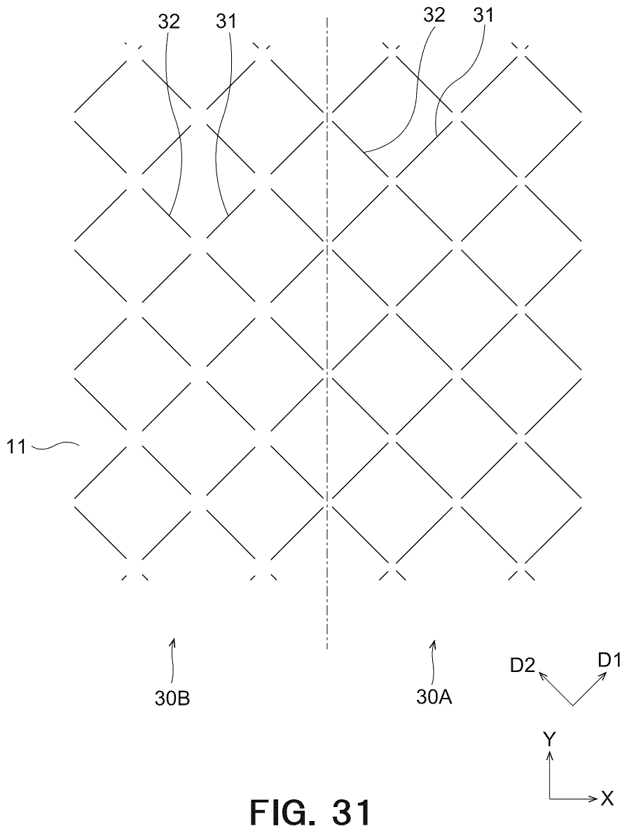

FIG. 30 and FIG. 31 illustrate a third modification of the wiring board. The modification illustrated in FIG. 30 and FIG. 31 differs with respect to the point of a plurality of dummy wiring portions 30A and 30B that have different aperture ratios from each other being provided around the mesh wiring portion 20, and other configurations are the substantially same as the form illustrated in FIG. 20 to FIG. 29. Portions in FIG. 30 and FIG. 31 that are the same as those in the form illustrated in FIG. 20 to FIG. 29 are denoted with the same signs, and detailed description will be omitted.

In the wiring board 10 illustrated in FIG. 30, the plurality of (two in this case) of dummy wiring portions 30A and 30B (first dummy wiring portion 30A and second dummy wiring portion 30B) that have different aperture ratios from each other are provided so as to follow around the mesh wiring portion 20. Specifically, the first dummy wiring portion 30A is disposed so as to follow around the mesh wiring portion 20, and the second dummy wiring portion 30B is disposed so as to follow around the first dummy wiring portion 30A. Note that the configuration of the first dummy wiring portion 30A may be the same as the configuration of the dummy wiring portion 30 illustrated in FIG. 28 and FIG. 29. Unlike the mesh wiring portion 20, these dummy wiring portions 30A and 30B do not substantially function as an antenna.

As illustrated in FIG. 31, the dummy wiring portions 30A and 30B each include the plurality of first-direction dummy wiring lines 31 and the plurality of second-direction dummy wiring lines 32. The first-direction dummy wiring lines 31 are parallel to the first direction D1, and are situated on extension lines of the first-direction wiring lines 21. The second-direction dummy wiring lines 32 are parallel to the second direction D2, and are situated on extension lines of the second-direction wiring lines 22. The first-direction dummy wiring lines 31 and the second-direction dummy wiring lines 32 are each straight lines in plan view. Accordingly, difference between the mesh wiring portion 20 and the first dummy wiring portion 30A, and difference between the first dummy wiring portion 30A and the second dummy wiring portion 30B can be made to be less readily visually recognized by eye, and the mesh wiring portion 20 disposed on the substrate 11 can be made to be difficult to see.

In this case, the length of the first-direction dummy wiring lines 31 of the second dummy wiring portion 30B are shorter than the length of the first-direction dummy wiring lines 31 of the first dummy wiring portion 30A. In the same way, the length of the second-direction dummy wiring lines 32 of the second dummy wiring portion 30B are shorter than the length of the second-direction dummy wiring lines 32 of the first dummy wiring portion 30A. Thus, the aperture ratio of the first dummy wiring portion 30A is larger than the aperture ratio of the mesh wiring portion 20, and the aperture ratio of the first dummy wiring portion 30A is larger than the aperture ratio of the second dummy wiring portion 30B. Also, three or more dummy wiring portions with different aperture ratios from each other may be provided. In this case, the aperture ratios of the dummy wiring portions preferably are such that the aperture ratio gradually increases from those near the mesh wiring portion 20 to those far away therefrom.

In this way, the dummy wiring portions 30A and 30B that are electrically isolated from the mesh wiring portion 20 are disposed, whereby the outer edge of the mesh wiring portion 20 can be made obscure. Thus, the mesh wiring portion 20 can be made difficult to see on the surface of the image display device 90, and the user of the image display device 90 can be made not to readily visually recognize the mesh wiring portion 20 by the bare eye.

### Third Embodiment

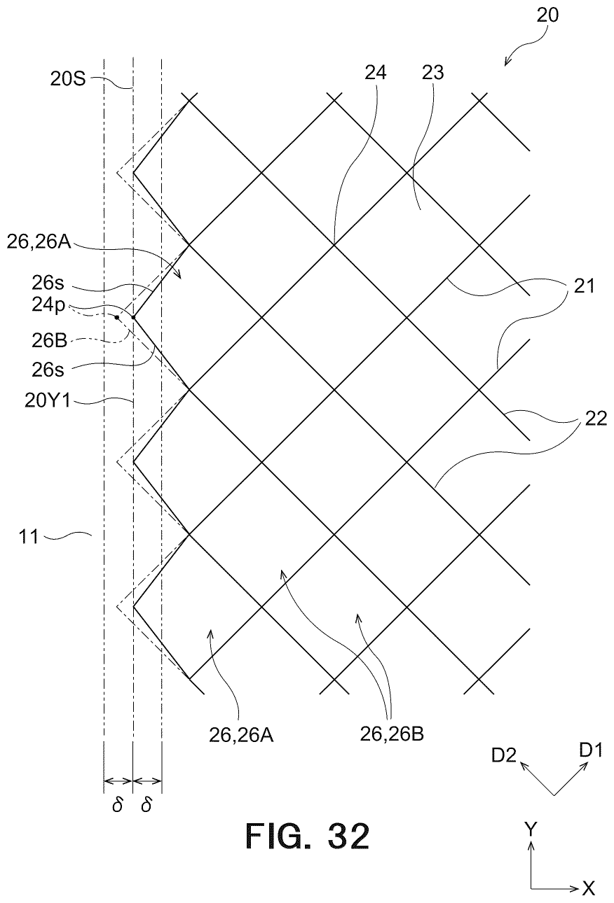

Next, a third embodiment will be described with reference to FIG. 32 to FIG. 39B. FIG. 32 to FIG. 39B are diagrams illustrating the third embodiment. In FIG. 32 to FIG. 39B, portions that are the same as those in the first embodiment illustrated in FIG. 1 to FIG. 19 or in the second embodiment illustrated in FIG. 20 to FIG. 31 are denoted with the same signs, and detailed description will be omitted.

The wiring board 10 according to the present embodiment includes the substrate 11 that has transparency, and the mesh wiring portion 20 disposed on the substrate 11. The mesh wiring portion 20 includes a plurality of closed shapes 26 that are disposed with regularity. Each closed shape 26 is enclosed by wiring lines 21 and 22 of two or more directions. The closed shapes 26 that are situated on the perimeter of the mesh wiring portion 20 (on the imaginary peripheral line 20S) have shapes in which part or all of the closed shapes 26 situated at other than the perimeter of the mesh wiring portion 20 (on the imaginary peripheral line 20S) are enlarged or reduced. Accordingly, the closed shapes 26 situated on the perimeter of the mesh wiring portion 20 are situated on the inner side of the perimeter of the mesh wiring portion 20 (imaginary peripheral line 20S).

As illustrated in FIG. 32, the mesh wiring portion 20 includes the plurality of closed shapes 26 that are disposed with regularity. In this case, the closed shapes 26 are each polygons, and more specifically are quadrangles such as squares, parallelograms, or the like. The closed shapes 26 are each made up of the pair of first-direction wiring lines 21 and the pair of second-direction wiring lines 22 that are disposed so as to surround the perimeter of an opening 23. In the present specification, “closed shape” means a shape that is closed by being surrounded by wiring made up of straight lines and/or curves on the substrate 11. The mesh wiring portion 20 may be made up of one type of the closed shape 26, or may be made up of a plurality of types of the closed shapes 26.

As illustrated in FIG. 32, at the side 20Y1 making up the imaginary peripheral line 20S, one row of closed shapes 26 closest to this side 20Y1 (hereinafter also referred to as perimeter closed shapes 26A) have shapes different from closed shapes 26 in other rows (hereinafter also referred to as standard closed shapes 26B). That is to say, the perimeter closed shapes 26A have shapes in which part of the shapes of the standard closed shapes 26B are reduced. Specifically, in the perimeter closed shapes 26A, a pair of sides 26s and 26s that are situated on the side closer to the side 20Y1 are deformed toward the inner side of the mesh wiring portion 20. Points of intersection 24p of the pairs of sides 26s and 26s are present on the side 20Y1 that makes up the imaginary peripheral line 20S. Note that the points of intersection 24p each may be situated in a region within δ=10 μm in either way in the X direction with respect to the side 20Y1.

In FIG. 32, assumption will be made that the closed shapes 26 closest to the side 20Y1 are standard closed shapes 26B (see imaginary lines in FIG. 32). In a case in which the points of intersection 24p of the standard closed shapes 26B that are closest to the side 20Y1 are situated on the outer side from the side 20Y1, these points of intersection 24p may be moved onto the side 20Y1, thereby reducing part of these standard closed shapes 26B to form the perimeter closed shapes 26A.

Other configurations of the wiring board 10 may be the same as in the case of the first embodiment described above.

In the present embodiment as well, the dummy wiring portions 30, 30A, and 30B that are electrically isolated from the mesh wiring portion 20 may be provided around the mesh wiring portion 20 (see FIG. 28 to FIG. 31).

In the present embodiment, the perimeter closed shapes 26A situated on the perimeter of the mesh wiring portion 20 have shapes in which part of the standard closed shapes 26B situated at other than the perimeter of the mesh wiring portion 20 are reduced. In this case, the first-direction wiring lines 21 and the second-direction wiring line 22 are not broken at the perimeter of the mesh wiring portion 20. Accordingly, deterioration of electrical characteristics at the perimeter of the mesh wiring portion 20 can be suppressed. Also, the perimeter closed shapes 26A situated on the perimeter of the mesh wiring portion 20 have shapes that are close to the standard closed shapes 26B. Accordingly, the perimeter of the mesh wiring portion 20 can be made to be not readily visually recognized by the bare eye of the observer, and the observer can be kept from recognizing the presence of the mesh wiring portion 20.

### [Modifications]

Next, modifications of the wiring board according to the present embodiment will be described.

### (First Modification)

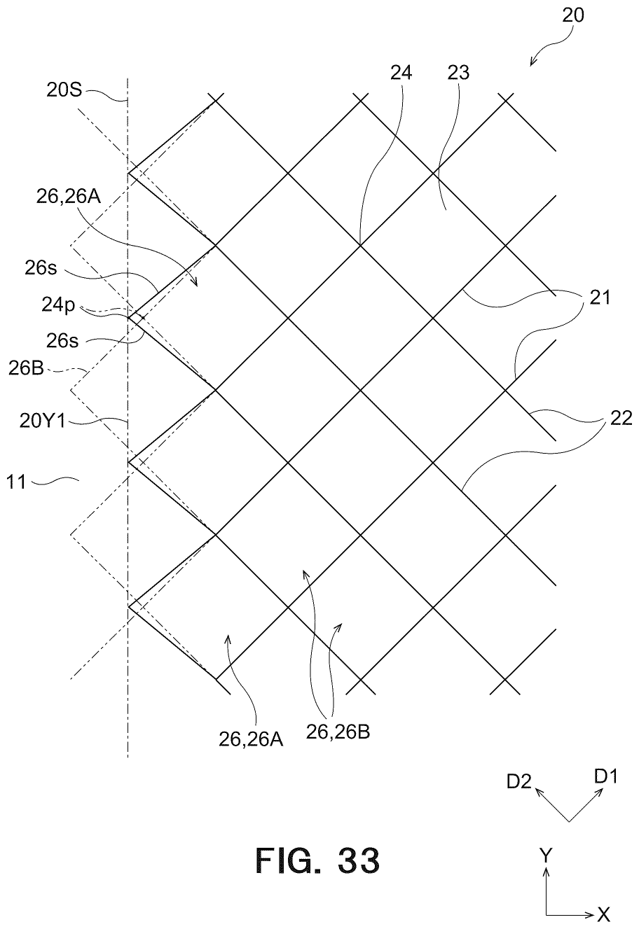

FIG. 33 illustrates a first modification of the wiring board. In FIG. 33, portions that are the same as in the form illustrated in FIG. 32 are denoted with the same signs, and detailed description will be omitted.

In FIG. 33, the mesh wiring portion 20 includes the plurality of closed shapes 26 that are disposed with regularity. At the side 20Y1 making up the imaginary peripheral line 20S, one row of perimeter closed shapes 26A the closest to this side 20Y1 have shapes different from those in the standard closed shapes 26B in other rows. That is to say, the perimeter closed shapes 26A have shapes in which part of the shapes of the standard closed shapes 26B are expanded. Specifically, of the perimeter closed shapes 26A, the pair of sides 26s and 26s situated on the side closer to the side 20Y1 are deformed toward the outer side of the mesh wiring portion 20. The points of intersection 24p of the pair of sides 26s and 26s are present on the side 20Y1 making up the imaginary peripheral line 20S. Note that the points of intersection 24p may each be situated at a position in a region within 10 μm in either way in the X direction with respect to the side 20Y1.

In FIG. 33, assumption will be made that the closed shapes 26 closest to the side 20Y1 are the standard closed shapes 26B (see imaginary lines in FIG. 33). In a case in which the points of intersection 24p of the standard closed shapes 26B that are closest to the side 20Y1 are situated on the inner side from the side 20Y1 here, these points of intersection 24p may be moved onto the side 20Y1, thereby expanding part of these standard closed shapes 26B to form the perimeter closed shapes 26A.

### (Second Modification)

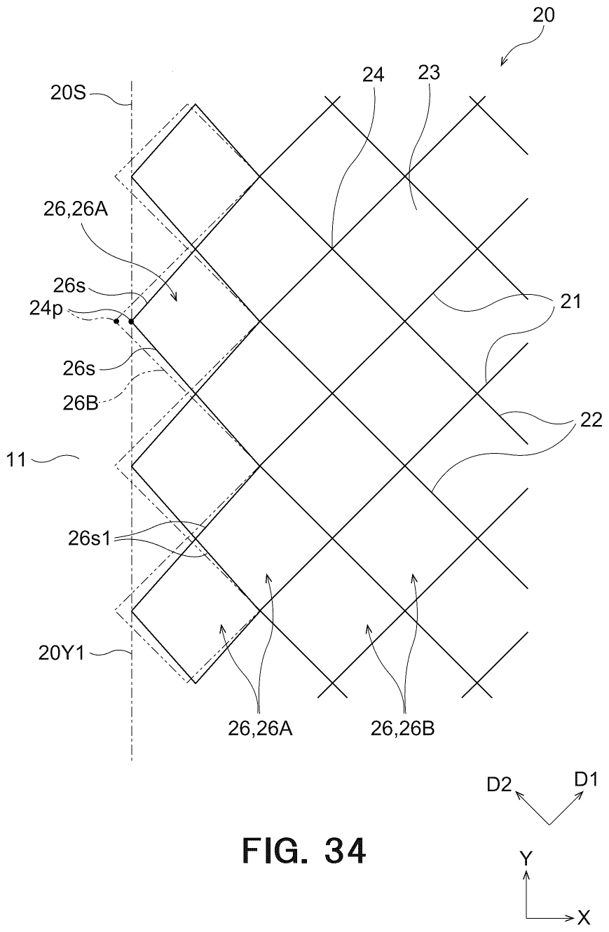

FIG. 34 illustrates a second modification of the wiring board. In FIG. 34, portions that are the same as those in the form illustrated in FIG. 32 are denoted with the same signs, and detailed description will be omitted.

In FIG. 34, the mesh wiring portion 20 includes the plurality of closed shapes 26 that are disposed with regularity. As illustrated in FIG. 34, at the side 20Y1 making up the imaginary peripheral line 20S, one row of perimeter closed shapes 26A the closest to the side 20Y1 have shapes different from the standard closed shapes 26B in other rows. That is to say, the perimeter closed shapes 26A have shapes in which the entirety of the shapes of the standard closed shapes 26B are reduced. Specifically, in the perimeter closed shapes 26A the closest to the side 20Y1, the entirety thereof is reduced in the X direction with respect to the standard closed shapes 26B. One of the points of intersection 24p of the perimeter closed shapes 26A is present on the side 20Y1 making up the imaginary peripheral line 20S. The points of intersection 24p may each be situated in a region within 10 μm in either way in the X direction with respect to the side 20Y1. Note that pairs of sides 26s1 and 26s1 of the perimeter closed shapes 26A second closest to the side 20Y1 are deformed toward the inner side of the mesh wiring portion 20.

In FIG. 34, assumption will be made that the closed shapes 26 closest to the side 20Y1 are the standard closed shapes 26B (see imaginary lines in FIG. 34). In a case in which the points of intersection 24p of the standard closed shapes 26B that are closest to the side 20Y1 are situated on the outer side from the side 20Y1 here, these points of intersection 24p may be moved onto the side 20Y1, thereby reducing the entirety of these standard closed shapes 26B to form the perimeter closed shapes 26A.

### (Third Modification)

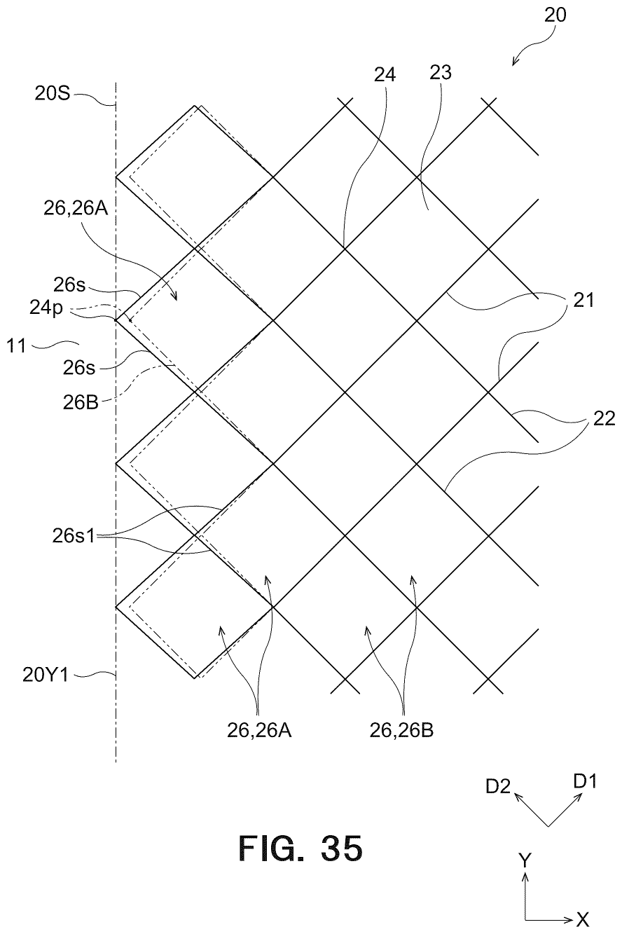

FIG. 35 illustrates a third modification of the wiring board. In FIG. 35, portions that are the same as those in the form illustrated in FIG. 32 are denoted with the same signs, and detailed description will be omitted.

In FIG. 35, the mesh wiring portion 20 includes the plurality of closed shapes 26 that are disposed with regularity. At the side 20Y1 making up the imaginary peripheral line 20S, one row of perimeter closed shapes 26A the closest to the side 20Y1 have shapes different from the standard closed shapes 26B in other rows. That is to say, the perimeter closed shapes 26A have shapes in which the entirety of the shapes of the standard closed shapes 26B are expanded. Specifically, in the perimeter closed shapes 26A the closest to the side 20Y1, the entirety thereof is expanded in the X direction with respect to the standard closed shapes 26B. One of the points of intersection 24p of the perimeter closed shapes 26A is present on the side 20Y1 making up the imaginary peripheral line 20S. The points of intersection 24p may each be situated in a region within 10 μm in either way in the X direction with respect to the side 20Y1. Note that pairs of the sides 26s1 and 26s1 of the perimeter closed shapes 26A second closest to the side 20Y1 are deformed toward the outer side of the mesh wiring portion 20.

In FIG. 35, assumption will be made that the closed shapes 26 closest to the side 20Y1 are the standard closed shapes 26B (see imaginary lines in FIG. 35). In a case in which the points of intersection 24p of the standard closed shapes 26B that are closest to the side 20Y1 are situated on the inner side from the side 20Y1 here, these points of intersection 24p may be moved onto the side 20Y1, thereby expanding the entirety of these standard closed shapes 26B to form the perimeter closed shapes 26A.

### (Fourth Modification)

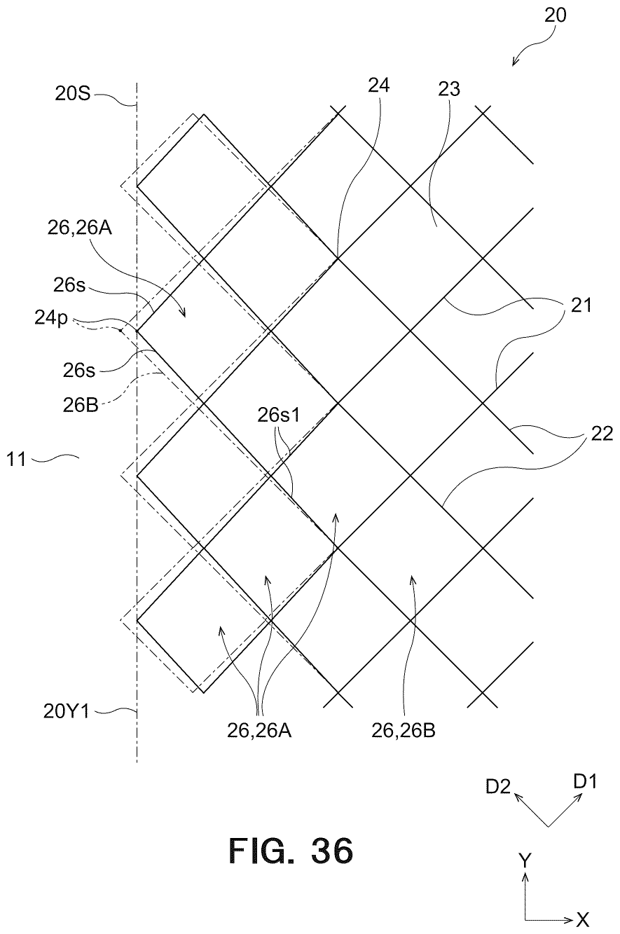

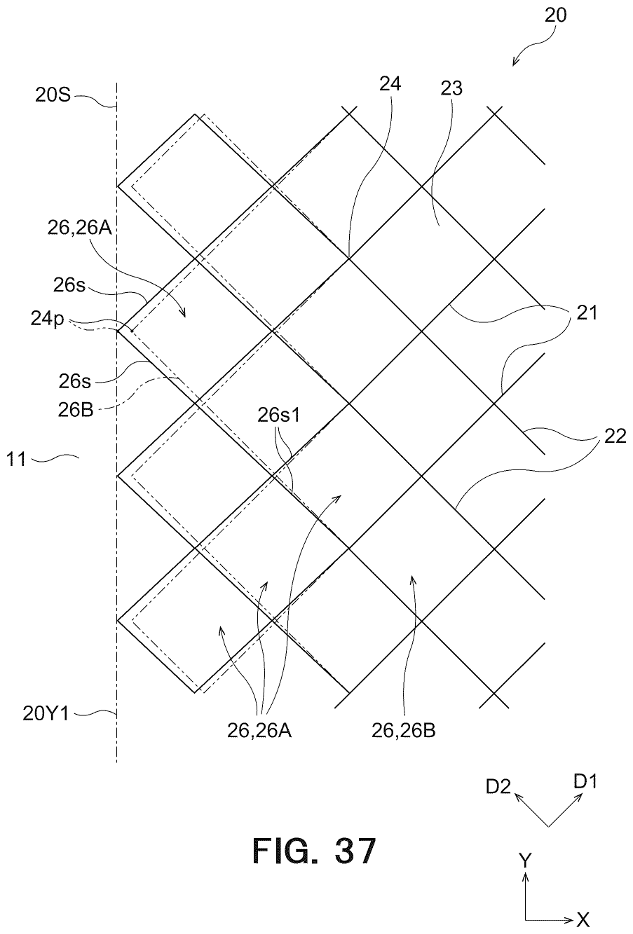

FIG. 36 and FIG. 37 illustrate a fourth modification of the wiring board. In FIG. 36 and FIG. 37, portions that are the same as those in the form illustrated in FIG. 32 are denoted with the same signs, and detailed description will be omitted.

In FIG. 36 and FIG. 37, the mesh wiring portion 20 includes the plurality of closed shapes 26 that are disposed with regularity. At the side 20Y1 making up the imaginary peripheral line 20S, two (two rows of) perimeter closed shapes 26A from the perimeter side (imaginary peripheral line 20S side) have shapes different from the standard closed shapes 26B in other rows. That is to say, two perimeter closed shapes 26A from the perimeter side have shapes in which the entirety of the shapes of the standard closed shapes 26B are reduced (FIG. 36) or shapes that are expanded (FIG. 37). Specifically, the two rows of perimeter closed shapes 26A from the side 20Y1 have shapes in which the entirety thereof are reduced (FIG. 36) or shapes that are expanded (FIG. 37) in the X direction with respect to the standard closed shapes 26B. One of the points of intersection 24p of the perimeter closed shapes 26A closest to the side 20Y1 is present on the side 20Y1. The points of intersection 24p may each be situated in a region within 10 μm in either way in the X direction with respect to the side 20Y1 making up the imaginary peripheral line 20S. Note that the pairs of sides 26s1 and 26s1 of the perimeter closed shapes 26A third closest to the side 20Y1 are deformed toward the inner side (FIG. 36) or the outer side (FIG. 37) of the mesh wiring portion 20.

In FIG. 36 and FIG. 37, assumption will be made that the closed shapes 26 closest to the side 20Y1 are the standard closed shapes 26B (see imaginary lines in FIG. 36 and FIG. 37). In a case in which the points of intersection 24p of the standard closed shapes 26B that are closest to the side 20Y1 are situated on the outer side from the side 20Y1 (FIG. 36) here, these points of intersection 24p are moved onto the side 20Y1. Thus, the entirety of the first and second perimeter closed shapes 26A from the perimeter side may be reduced. Alternatively, in a case in which the points of intersection 24p of the standard closed shapes 26B that are closest to the side 20Y1 are situated on the inner side from the side 20Y1 (FIG. 37), these points of intersection 24p are moved onto the side 20Y1. Thus, the entirety of the first and second perimeter closed shapes 26A from the perimeter side may be expanded.

Note that in the present modification, three to five perimeter closed shapes 26A from the perimeter side may have shapes in which the entirety of the standard closed shapes 26B are reduced or enlarged. Reducing or enlarging two or more closed shapes 26 from the perimeter side in this way can suppress the amount of deformation of individual closed shapes 26. Thus, deterioration in non-visibility of the mesh wiring portion 20 can be suppressed, and the observer can be made to less readily visually recognize the presence of the mesh wiring portion 20. Also, by reducing or enlarging five or less closed shapes 26 from the perimeter side, the number of perimeter closed shapes 26A of which the shapes differ from the standard closed shapes 26B can be suppressed, whereby deterioration of electrical characteristics of the mesh wiring portion 20 can be suppressed.

### (Fifth Modification)

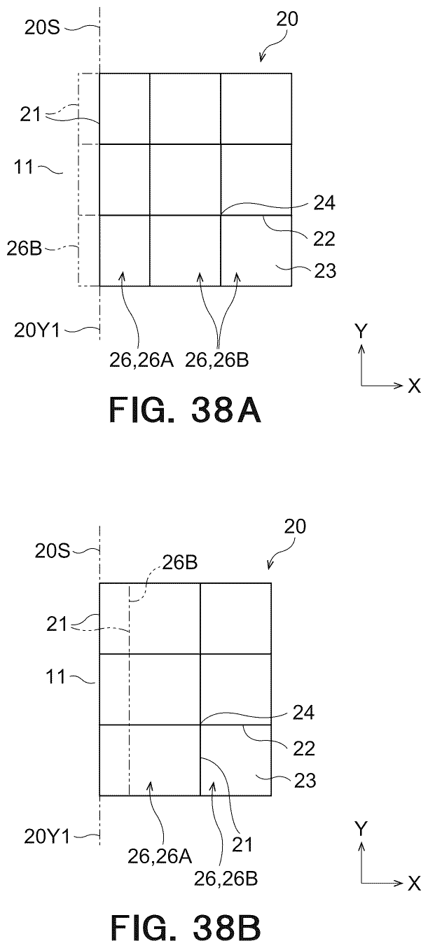

FIG. 38A and FIG. 38B illustrate a fifth modification of the wiring board. In FIG. 38A and FIG. 38B, portions that are the same as those in the form illustrated in FIG. 32 are denoted with the same signs, and detailed description will be omitted.

In FIG. 38A and FIG. 38B, the mesh wiring portion 20 includes the plurality of closed shapes 26 that are disposed with regularity. The closed shapes 26 are rectangles or squares. In this case, the first-direction wiring lines 21 extend parallel to the Y direction, and the second-direction wiring lines 22 extend parallel to the X direction. At the side 20Y1 making up the imaginary peripheral line 20S, one row of perimeter closed shapes 26A the closest to the side 20Y1 have shapes different from the standard closed shapes 26B in other rows. That is to say, the perimeter closed shapes 26A have shapes in which the entirety of the shapes of the standard closed shapes 26B are reduced (FIG. 38A) or shapes that are expanded (FIG. 38B). Specifically, of the perimeter closed shapes 26A, one first-direction wiring line 21 situated on a side closer to the side 20Y1 is present on the side 20y1 making up the imaginary peripheral line 20S. Note that this first-direction wiring line 21 may each be situated in a region within 10 μm in either way in the X direction with respect to the side 20Y1.

In FIG. 38A and FIG. 38B, assumption will be made that the closed shapes 26 closest to the side 20Y1 are the standard closed shapes 26B (see imaginary lines in FIG. 38A and FIG. 38B). In a case in which the first-direction wiring line 21 closest to the side 20Y1 is situated on the outer side from the side 20Y1 (FIG. 38A) here, this first-direction wiring line 21 may be moved onto the side 20Y1, thereby reducing the entirety of the standard closed shapes 26B including this first-direction wiring line 21 to form perimeter closed shapes 26A. Alternatively, in a case in which the first-direction wiring line 21 closest to the side 20Y1 is situated on the inner side from the side 20Y1 (FIG. 38B), this first-direction wiring line 21 may be moved onto the side 20Y1, thereby expanding the entirety of the standard closed shapes 26B including this first-direction wiring line 21 to form perimeter closed shapes 26A.

### (Sixth Modification)

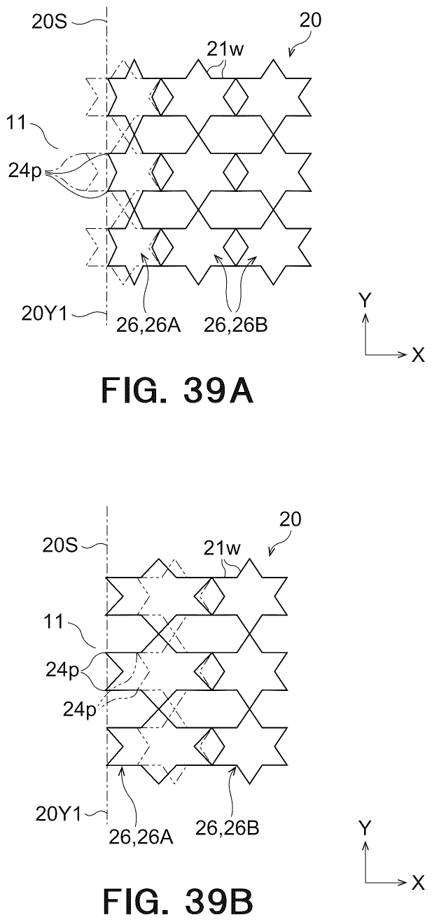

FIG. 39A and FIG. 39B illustrate a sixth modification of the wiring board. In FIG. 39A and FIG. 39B, portions that are the same as those in the form illustrated in FIG. 32 are denoted with the same signs, and detailed description will be omitted.

In FIG. 39A and FIG. 39B, the mesh wiring portion 20 includes the plurality of closed shapes 26 that are disposed with regularity. The closed shapes 26 are polygons, and more specifically are dodecagonal concave polygons. In this case, the closed shapes 26 are each surrounded by 12 wiring lines 21w. At the side 20Y1 making up the imaginary peripheral line 20S, one row of perimeter closed shapes 26A closest to this line 20Y1 have shapes different from the standard closed shapes 26B in other rows. That is to say, the perimeter closed shapes 26A have shapes in which the entirety of the shapes of the standard closed shapes 26B are reduced (FIG. 39A) or shapes that are expanded (FIG. 39B). Specifically, two points of intersection 24p of the perimeter closed shapes 26A are present on the side 20Y1 making up the imaginary peripheral line 20S. Note that the points of intersection 24p may each be situated in a region within 10 μm in either way in the X direction with respect to the side 20Y1.

In FIG. 39A and FIG. 39B, assumption will be made that the closed shapes 26 closest to the side 20Y1 are the standard closed shapes 26B (see imaginary lines in FIG. 39A and FIG. 39B). In a case in which the points of intersection 24p closest to the side 20Y1 are situated on the outer side from the side 20Y1 (FIG. 39A) here, the points of intersection 24p may be moved onto the side 20Y1, thereby reducing the entirety of the standard closed shapes 26B including these points of intersection 24p to form the perimeter closed shapes 26A. Alternatively, in a case in which the points of intersection 24p closest to the side 20Y1 are situated on the inner side from the side 20Y1 (FIG. 39B), the points of intersection 24p may be moved onto the side 20Y1, thereby expanding the entirety of the standard closed shapes 26B including these points of intersection 24p to form the perimeter closed shapes 26A.

### Fourth Embodiment

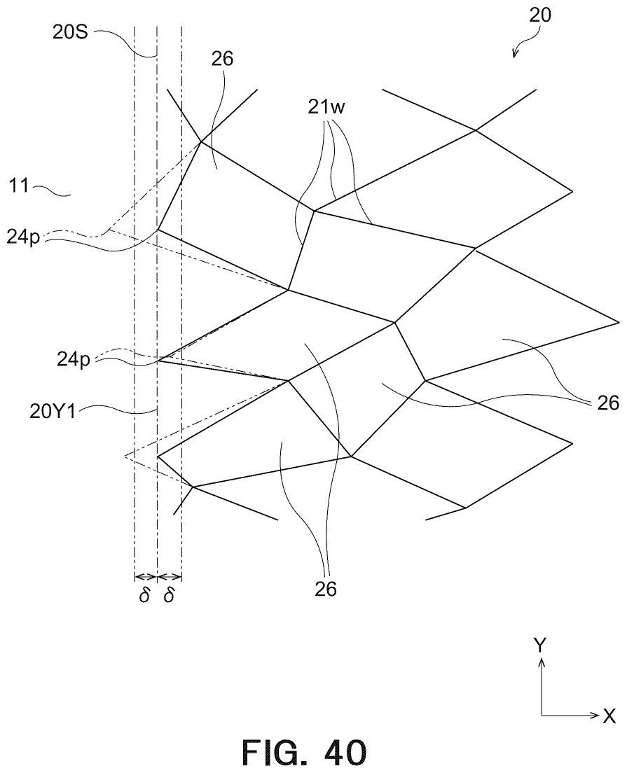

Next, a fourth embodiment will be described with reference to FIG. 40. FIG. 40 is a diagram illustrating the perimeter of the mesh wiring portion according to the fourth embodiment. In FIG. 40, portions that are the same as those in the first embodiment illustrated in FIG. 1 to FIG. 19, the second embodiment illustrated in FIG. 20 to FIG. 31, or the third embodiment illustrated in FIG. 32 to FIG. 39B are denoted with the same signs, and detailed description will be omitted.

The wiring board 10 according to the present embodiment includes the substrate 11 that has transparency, and the mesh wiring portion 20 disposed on the substrate 11. The mesh wiring portion 20 includes the plurality of closed shapes 26 that are disposed with irregularity. Each closed shape 26 is enclosed by the wiring lines 21w of two or more directions. The closed shapes 26 that are situated on the perimeter of the mesh wiring portion 20 (on the imaginary peripheral line 20S) are situated on the inner side of the perimeter of the mesh wiring portion 20 (imaginary peripheral line 20S).

As illustrated in FIG. 40, the mesh wiring portion 20 includes the plurality of closed shapes 26 that are disposed with irregularity. In this case, the closed shapes 26 are each polygons, and more specifically are each irregular quadrangles. The closed shapes 26 may be polygons other than quadrangles. The closed shapes 26 are each made up of a plurality of the wiring lines 21w that are disposed so as to surround the perimeter of the openings 23.

As illustrated in FIG. 40, at the side 20Y1 making up the imaginary peripheral line 20S, the points of intersection 24p of the closed shapes 26 closest to this side 20Y1 are present on the straight line BL making up the imaginary peripheral line 20S. Note that the points of intersection 24p may each be situated in a region within δ=10 μm in either way in the X direction with respect to the side 20Y1.

Other configurations of the wiring board 10 may be the same as in the case of the first embodiment and the second embodiment described above.

In the present embodiment, the closed shapes 26 situated on the perimeter of the mesh wiring portion 20 are situated on the inner side from the perimeter of the mesh wiring portion 20. In this case, a state in which the wiring lines 21w are broken at the perimeter of the mesh wiring portion 20 does not occur. Accordingly, deterioration of electrical characteristics at the perimeter of the mesh wiring portion 20 can be suppressed. Also, the plurality of closed shapes 26 situated on the perimeter of the mesh wiring portion 20 have irregular shapes. Accordingly, the perimeter of the mesh wiring portion 20 can be made to be not readily visually recognized by the bare eye of the observer, and the observer can be kept from recognizing the presence of the mesh wiring portion 20.

The plurality of components disclosed in the embodiments and the modifications described above can be appropriately combined as necessary. Alternatively, some components may be omitted from all components disclosed in the embodiments and the modifications described above.

1. A wiring board, comprising:
a substrate that includes a first face, and a second face situated on an opposite side from the first face;
two or more mesh wiring portions that are disposed on the first face of the substrate, and that are distanced from each other; and
two or more power supply units that are electrically connected to the mesh wiring portions, wherein
the wiring board has an electromagnetic wave transmission/reception function,
the substrate has transparency, the mesh wiring portions are configured as antennas,
each of the mesh wiring portions and each of the power supply units are individually connected, and
two or more first notch portions that extend linearly are formed in the power supply units.

2. The wiring board according to claim 1, wherein the wiring board has a millimeter wave transmission/reception function, and the mesh wiring portions are configured as array antennas.

3. The wiring board according to claim 1, wherein the power supply units have a first end portion that connects to the mesh wiring portions, and a second end portion on an opposite side from the first end portion, and the first notch portions extend from the second end portion along a direction from the second end portion toward the first end portion.

4. The wiring board according to claim 1, further comprising:
a ground portion that is disposed on the first face of the substrate, wherein
two or more second notch portions that extend linearly are formed in the ground portion.

5. The wiring board according to claim 1, wherein a separating portion that separates the first notch portions is formed in the first notch portions.

6. The wiring board according to claim 1, wherein a distance between the mesh wiring portions is 1 mm or more and 5 mm or less.

7. The wiring board according to claim 1, wherein a dummy wiring portion that is electrically isolated from the mesh wiring portions is provided around the mesh wiring portions.

8. The wiring board according to claim 7, wherein two or more of the dummy wiring portions are provided, and an aperture ratio of the mesh wiring portions and the dummy wiring portions becomes larger stepwise from the mesh wiring portions toward the dummy wiring portions that are far from the mesh wiring portions.

9. A module, comprising:
the wiring board according to claim 1; and
a power supply line that is electrically connected to the power supply units of the wiring board.

10. The module according to claim 9, wherein the power supply line has a base material and a metal wiring portion that is laminated on the base material, two or more third notch portions that extend linearly are formed in the metal wiring portion, a width of the third notch portions is a width of the first notch portions or less, and in plan view the third notch portions extend along the first notch portions and also overlap the first notch portions.

11. The module according to claim 9, wherein the power supply line is electrically connected to the power supply units via an anisotropic conductive film that contains conductive particles, and the width of the first notch portions is 0.5 times or more and 1 times or less an average particle size of the conductive particles.

12. An image display device, comprising:
the module according to claim 9; and
a display device that is laminated on the wiring board of the module.

13-32. (canceled)
